(19) United States
(12) Patent Application Publication
(10) Pub. No.: US 2006/0219294 A1
(43) Pub. Date: Oct. 5, 2006

(54) Oxide semiconductor electrode, dye-sensitized solar cell, and, method of producing the same

(75) Inventors: Yosuke Yabuuchi, Tokyo (JP); Hiroki Nakagawa, Tokyo (JP); Hiroyuki Kobori, Tokyo (JP)

Correspondence Address: SEYFARTH SHAW LLP, 55 E. MONROE STREET, SUITE 4200, CHICAGO, IL, 60603-5803, US

(73) Assignee: Dai Nippon Printing Co., Ltd.

(21) Appl. No.: 11/393,610

(22) Filed: Mar. 30, 2006

(30) Foreign Application Priority Data
Mar. 30, 2005 (JP) 2005-100265
Mar. 30, 2005 (JP) 2005-100267
Sep. 29, 2005 (JP) 2005-285323
Sep. 29, 2005 (JP) 2005-285339

(51) Int. Cl. H01L 31/00

(52) U.S. Cl. 136/263

(57) ABSTRACT

An oxide semiconductor electrode is provided with a bonding layer with excellent temporal stability of adhesive force and excellent productivity in a transfer method including a dye-sensitized solar cell with the oxide semiconductor electrode; a method of producing an oxide semiconductor electrode that can produce an oxide semiconductor electrode excellent in the energy conversion efficiency at the high productivity is also provided. The oxide semiconductor electrode and method for making the same are disclosed noting that the oxide semiconductor electrode includes: a base material; a bonding layer formed on the base material made of a thermoplastic resin; a first electrode layer formed on the bonding layer made of a metal oxide; and a porous layer formed on the first electrode and made of the fine particle of a metal oxide semiconductor, wherein the thermoplastic resin includes a silane-modified resin.

### BACKGROUND OF THE INVENTION

1. Field of the Invention

The present invention relates to an oxide semiconductor electrode and a dye-sensitized-solar cell therewith, and furthermore a method of producing the same.

2. Description of the Related Art

Recently, environmental problems such as global warming due to an increase of carbon dioxide are becoming critical and countermeasures are world-widely being forwarded. Among these, as an energy source that is low in the environmental burden and clean, solar cells that make use of solar energy are under active researches and developments. As such solar cells, monocrystal silicon solar cells, polycrystalline silicon solar cells, amorphous silicon solar cells and compound semiconductor solar cells are already in practical use. However, there are problems in that the producing cost of these solar cells is high and so on. In this connection, as a solar cell that is low in the environmental burden and can reduce the producing cost, dye-sensitized solar cells are gathering attention and under research and development.

In such a dye-sensitized solar cell, an oxide semiconductor electrode having a porous layer containing fine particle of a metal oxide semiconductor is used.

A general configuration of the dye-sensitized solar cell is shown in FIG. 1. As shown in FIG. 1, a general dye-sensitized solar cell 11 has the following configuration; x an oxide semiconductor electrode 13 comprises a first electrode layer 2 and the porous layer 3 that contains dye-sensitizer-supported fine particle of a metal oxide semiconductor are layered on a base material 1 in this order; and on a porous layer 3 of the electrode 13, an electrolyte layer 4 having an redox couple, a second electrode layer 5 and an counter base material 6 are layered in this order. In the solar cell, a sensitizing dye adsorbed on a surface of a fine particle of an oxide semiconductor is excited when sun-light is received from a base material 1 side, excited electrons are conducted to the first electrode layer, and further conducted through an external circuit to the second electrode layer. Thereafter, through a redox couple, an electron returns to a ground level of the sensitizing dye to generate electricity. As such a dye-sensitized solar cell, a Gratzel cell where the porous layer is formed of porous titanium dioxide and a content of a dye sensitizer is increased is a typical one. This is under study at large as a dye-sensitized solar cell high in the electricity generation efficiency.

In order to form a porous layer of a porous material characteristic to the Gratzel cell, in general, a sintering process has to be applied to a porous layer forming composition at a temperature in the range of 300 to 700° C. Accordingly, as the base material, since a material having the heat resistance that can endure the sintering process has to be used, there is a problem in that a general polymer film cannot be used.

Japanese Patent Application Laid-Open (JP-A) No. 2002-184475 discloses a method of producing a semiconductor electrode. The method is characterized in that a layer including an oxide semiconductor and/or a precursor thereof is formed on a heat-resistant substrate and an oxide semiconductor membrane obtained by heating and sintering and sintering the layer is transferred on a base material for receiving the transfer. According to such a transfer method, when an oxide semiconductor membrane sintered on the heat-resistant substrate is transferred on an arbitrary base material for receiving the transfer, a porous layer can be formed. Accordingly, such a transfer method is useful in that a base material for receiving the transfer can be selected according to an application or the like of an oxide semiconductor electrode irrespective of a material of the base material for receiving the transfer.

In the transfer method, an oxide semiconductor membrane formed on a heat-resistant substrate is transferred on a base material for receiving the transfer to form a porous layer. When the membrane is transferred, however, it is necessary to form a bonding layer on a base material for receiving the transfer. Accordingly, when for example an oxide semiconductor electrode where the porous layer is formed according to a transfer method is used in a dye-sensitized solar cell, a bonding layer is added to a general configuration of the dye-sensitized solar cell shown in FIG. 1. FIG. 2 shows a configuration of a dye-sensitized solar cell using an oxide semiconductor electrode with the porous layer formed by the transfer method. As shown in FIG. 2, when an oxide semiconductor electrode with the porous layer formed by the transfer method is used, in a dye-sensitized solar cell 12, a bonding layer Z is formed between a base material 1 and a first electrode layer 2,. As an adhesive used in such a bonding layer, general various kinds of synthetic resins and inorganic adhesives have conventionally been used with no particular restriction.

Here, in order to produce, by use of the transfer method, an oxide semiconductor electrode excellent in the temporal stability, the bonding layer needs to have excellent adhesive force and the adhesive force has to be stably maintained for a long time. However, conventionally used adhesives are insufficient in the adhesive force and there is a problem in that the interlayer peeling is caused with time. Furthermore, an phenomenon where, for example, when an oxide semiconductor electrode is used in the dye-sensitized solar cell, since a porous layer is porous, a solvent and a redox couple in an electrolyte layer permeate the porous layer and further permeate an electrode layer is confirmed. Accordingly, in a dye-sensitized solar cell having a bonding layer as shown in FIG. 2, there is a problem in that the adhesive force of the bonding layer is deteriorated under the action of the redox couple and the solvent in the electrolyte layer to result in causing the interlayer peeling. Owing to the problems, it was difficult to produce a dye-sensitized solar cell excellent in the temporal stability by using a transfer method. Furthermore, the transfer method, though advantageous in that no special requirement is needed for a material of the base material for receiving the transfer, leaves a fundamental problem of damaging the porous layer when the porous layer is transferred on the base material for receiving the transfer. Therefore, there is a problem in that the transfer method lacks the practicality.

Furthermore, since, in general, a dye-sensitized solar cell is low in the energy conversion efficiency in comparison with a silicon solar cell and the like, an oxide semiconductor electrode that can further improve the energy conversion efficiency of the dye-sensitized solar cell is in demand.

### SUMMARY OF THE INVENTION

The invention was achieved in view of the above problems and primarily intends: to provide an oxide semiconductor electrode provided with a bonding layer excellent in the temporal stability of the adhesive force and excellent in the productivity by a transfer method and a dye-sensitized solar cell with the oxide semiconductor electrode; and to provide a method of producing an oxide semiconductor electrode that can produce an oxide semiconductor electrode excellent in the energy conversion efficiency at the high productivity.

In order to solve the above problems, the invention provides an oxide semiconductor electrode that includes a base material, a bonding layer formed on the base material and made of a thermoplastic resin, a first electrode layer formed on the bonding layer and made of a metal oxide, and a porous layer formed on the first electrode layer and containing a fine particle of a metal oxide semiconductor, wherein the thermoplastic resin contains a silane-modified resin.

According to the invention, by using the silane-modified resin as the thermoplastic resin, the adhesive force of the bonding layer to the base material and the first electrode layer can be strengthened. Accordingly, for example when the oxide semiconductor electrode of the invention is used in a dye-sensitized solar cell, the adhesion stability which does not damage the adhesive force, even when a redox couple permeates from an electrolyte layer to the bonding layer, can be obtained. Thus, according to the invention, an oxide semiconductor electrode which does not cause the interlayer peeling with time or the like and is excellent in the temporal stability can be obtained.

Furthermore, the invention provides an oxide semiconductor electrode that includes a base material, a bonding layer formed on the base material and made of a thermoplastic resin, a first electrode layer formed on the bonding layer and made of a metal oxide, and a porous layer formed on the first electrode layer and containing a fine particle of a metal oxide semiconductor, wherein the porous layer is constituted of an oxide semiconductor layer in contact with the first electrode layer and an intermediate layer that is formed on the oxide semiconductor layer and higher in the porosity than the oxide semiconductor layer.

According to the invention, since the porous layer is constituted of an oxide semiconductor layer in contact with the first electrode layer and an intermediate layer that is formed on the oxide semiconductor layer and higher in the porosity than the oxide semiconductor layer, the adhesive force between the heat-resistant substrate and the porous layer can be reduced when a porous layer is formed by the transfer method. As a result, according to the invention, an oxide semiconductor electrode excellent in the productivity due to the transfer method can be obtained.

Furthermore, according to the invention, since the bonding layer is made of the thermoplastic resin, the bonding layer can be rendered excellent in the flexibility. Accordingly, an oxide semiconductor electrode that is difficult to cause the “crack” or the like in the bonding layer itself and has the resistance to an external impact can be obtained.

In the invention, the thermoplastic resin preferably includes an adhesive resin. This is because when the thermoplastic resin includes the adhesive resin, the adhesive force of the bonding layer to the base material and the first electrode layer can be strengthened. Thereby, an oxide semiconductor electrode that is not only provided with high productivity due to the transfer method but also does not cause the interlayer peeling with time or the like, and is excellent in the temporal stability can be obtained.

Furthermore, in the invention, the base material is preferably a resinous film base material. This is because when the base material is a resinous film base material, the oxide semiconductor electrode of the invention can be rendered one excellent in the flexibility.

Still furthermore, in the invention, the porous layer preferably contains a metal element same as the metal element that a metal oxide constituting the first electrode layer has. When the porous layer contains a metal element same as the metal element that a metal oxide constituting the first electrode layer has, an oxide semiconductor electrode of the invention can be made excellent in the electric conductivity.

Furthermore, in the invention, the porous layer is preferably patterned. This is because when the porous layer is patterned, for example when the oxide semiconductor electrode of the invention is used in a dye-sensitized solar cell, a dye-sensitized solar cell high in the module electromotive force can be produced.

In the invention, a dye sensitizer is preferably absorbed on a surface of a fine particle of a metal oxide semiconductor contained in the porous layer. By the porous layer containing a dye sensitizer, when the oxide semiconductor electrode of the invention is used in a dye-sensitized solar cell, a process of producing a dye-sensitized solar cell can be simplified.

Furthermore, the invention provides an oxide semiconductor electrode with a heat-resistant substrate, which has a heat-resistant substrate on the porous layer that the oxide semiconductor electrode has.

According to the invention, when a heat-resistant substrate is provided on the porous layer that the oxide semiconductor electrode has, the heat-resistant base material is peeled, and an oxide semiconductor electrode with a beat-resistant substrate, which can readily form an oxide semiconductor electrode excellent in the adhesiveness between the respective layers, can be obtained

Furthermore, the invention provides a dye-sensitized solar cell, wherein a porous layer of the oxide semiconductor electrode in which a dye sensitizer is absorbed on a surface of a fine particle of a metal oxide semiconductor contained in the porous layer, and a second electrode layer of a counter electrode base material constituted of the second electrode layer and a counter base material, are disposed to face each other through an electrolyte layer containing a redox couple.

According to the invention, since the bonding layer is made of a thermoplastic resin, a dye-sensitized solar cell where the bonding layer itself is difficult to cause the “crack” or the like and has the resistance to the external impact can be obtained. Furthermore, according to the invention, since the bonding layer is made of a silane-modified resin, the adhesive force of the bonding layer can be strengthened. Thereby, a dye-sensitized solar cell that does not cause the interlayer peeling with time or the like and is excellent in the temporal stability can be obtained,

Furthermore, the invention provides a method of producing a laminated body for an oxide semiconductor electrode, comprising the processes of: a process of forming an intermediate layer-forming pattern, wherein an intermediate layer-forming coating material that contains an organic material and a fine particle of a metal oxide semiconductor is applied to a heat-resistant substrate in pattern and set to form an intermediate layer-forming pattern; a process of forming an oxide semiconductor layer-forming layer, wherein an oxide semiconductor layer-forming coating material whose solid has a higher concentration of a fine particle of a metal oxide semiconductor than that of the particle in the solid of the intermediate layer-forming coating material, is applied to the heat-resistant substrate and the intermediate layer-forming pattern and set to form an oxide semiconductor Iayer-forming layer; a sintering process, wherein the intermediate layer-forming pattern and the oxide semiconductor layer-forming layer are sintered to be a porous body respectively to form a porous intermediate layer and a porous oxide semiconductor layer; and a process of forming a first electrode layer, wherein a first electrode layer is formed on the oxide semiconductor layer.

According to the invention, a laminated body for an oxide semiconductor electrode, which has an intermediate layer formed in pattern, can be obtained. When the laminated body for an oxide semiconductor electrode is used, an oxide semiconductor electrode, in which the intermediate layer and the oxide semiconductor layer are patterned on the first electrode layer, can be obtained.

Furthermore, in the invention, it is preferable that the heat-resistant substrate is provided with, on a surface thereof, a wettability-variable layer where the wettability can be varied under the action of a photo-catalyst accompanied by energy irradiation, and, prior to the process of forming the intermediate layer-forming pattern energy is irradiated on the wettability-variable layer to form a wettability-varying pattern. This is because the intermediate layer-forming pattern can be formed with precision along the wettability-varying pattern.

Still Furthermore, the invention provides a method of producing an oxide semiconductor electrode with a heat-resistant substrate, comprising a process of forming a base material, wherein a base material is disposed on the first electrode layer of the laminated body for an oxide semiconductor electrode that is obtained by the method of producing the laminated body for an oxide semiconductor electrode.

According to the invention, for example, when the oxide semiconductor electrode with a heat-resistant substrate, which is obtained by the producing method, is used to produce a dye-sensitized solar cell, a dye-sensitized solar cell excellent in the energy conversion efficiency can be obtained.

Furthermore, the invention provides a method of producing an oxide semiconductor electrode with a heat-resistant substrate, comprising the processes of: a process of forming an intermediate layer-forming pattern, wherein an intermediate layer-forming coating material that contains an organic material and a fine particle of a metal oxide semiconductor is applied to a heat-resistant substrate in pattern and set to form an intermediate layer-forming pattern; a process of forming an oxide semiconductor layer-forming layer, wherein an oxide semiconductor layer-forming coaxing material whose solid has a higher concentration of a fine particle of a metal oxide semiconductor than that of the particle in the solid of the intermediate layer-forming coating material is applied to the heat-resistant substrate and the intermediate layer-forming pattern and set to form an oxide semiconductor layer-forming layer; a sintering process, wherein the intermediate layer-forming pattern and the oxide semiconductor layer-forming layer are sintered to be a porous body respectively to form a porous intermediate layer and a porous oxide semiconductor layer,
wherein the processes are carried out to form an oxide semiconductor substrate, and to superpose the oxide semiconductor layer and the first electrode layer by using the oxide semiconductor substrate and an electrode base material provided with a base material and a first electrode layer.

According to the invention, for example, when the oxide semiconductor electrode with a heat-resistant substrate, which is obtained by the producing method, is used to produce a dye-sensitized solar cell, a dye-sensitized solar cell excellent in the energy conversion efficiency can be obtained.

Furthermore, the invention provides a method of producing an oxide semiconductor electrode, comprising a peeling process of peeling the heat-resistant substrate from the oxide semiconductor electrode with a heat-resistant substrate obtained by the method of producing the oxide semiconductor electrode with a heat-resistant substrate.

According to the invention, for example, when the oxide semiconductor electrode that is obtained by the producing method is used to produce a dye-sensitized solar cell, a dye-sensitized solar cell excellent in the energy conversion efficiency can be obtained.

Furthermore, the invention provides a method of producing a dye-sensitized solar cell, comprising a process of forming a counter electrode base material by facing, with an oxide semiconductor electrode obtained by the method of producing the oxide semiconductor electrode and a counter electrode base material provided with a second electrode pattern and a counter base material, the intermediate layer and the second electrode pattern to form a base material pair for a dye-sensitized solar cells wherein a filling process, in which a process of supporting a dye sensitizer on a pore surface of the intermediate layer and the oxide semiconductor layer, and a process of forming an electrolyte layer between the second electrode pattern and the intermediate layer and inside of pores of the porous body of the oxide semiconductor layer and the intermediate layer after the process of supporting a dye sensitizer are carried out to the laminated body for an oxide semiconductor electrode, the oxide semiconductor electrode with a heat-resistant substrate, the oxide semiconductor electrode or the base material pair of a dye-sensitized solar cell.

According to the invention, for example, when the oxide semiconductor electrode or the like is used to produce a dye-sensitized solar cell, a dye-sensitized solar cell excellent in the energy conversion efficiency can be obtained.

Furthermore, in the invention, a process of forming first electrode pattern where the first electrode layer is formed in pattern to form a first electrode pattern is preferably applied to the laminated body for an oxide semiconductor electrode or the oxide semiconductor electrode. This is because when the first electrode pattern is used, a dye-sensitized solar cell excellent in the energy conversion efficiency can be obtained.

The invention has advantages in that an oxide semiconductor electrode that is excellent in the adhesion stability of the respective layers and has high productivity, and a dye-sensitized solar cell can be obtained. The invention has a further advantage in that oxide semiconductor electrode excellent in the energy conversion efficiency can be produced at high productivity.

### BRIEF DESCRIPTION OF THE DRAWINGS

FIG. 1 is a schematic cross-sectional view showing an example of a general configuration of a dye-sensitized solar cell.

FIG. 2 is a schematic cross-sectional view showing an example of a dye-sensitized solar cell having a bonding layer.

FIG. 3 is a schematic cross-sectional view showing an example of an oxide semiconductor electrode according Lo the invention.

FIG. 4 is a schematic cross-sectional view showing another example of an oxide semiconductor electrode according to the invention.

FIGS. 5A to 5B are a schematic cross-sectional views showing yet another example of an oxide semiconductor electrode according to the invention.

FIGS. 5A to 6C are process drawings showing an example of a method of producing a base material with a heat-resistant substrate in the invention.

FIG. 7 is a process drawing showing an example of peeling process of a heat-resistant substrate in the invention.

FIG. 8 is a process drawing showing an example of patterning process of a porous layer in the invention.

FIG. 9 is a schematic cross-sectional view showing an example of an oxide semiconductor electrode with a heat-resistant substrate of the invention.

FIG. 10 is a schematic cross-sectional view showing an example of a dye-sensitized solar cell according to the invention.

FIGS. 11A and 11B are explanatory drawings explaining a shape of a laminated body for an oxide semiconductor electrode obtained by the invention.

FIGS. 12A to 12D are process drawings showing an example of a method of producing a laminated body for an oxide semiconductor electrode obtained by the invention.

FIG. 13 is an explanatory drawing showing an example of a method of forming a first electrode layer used in the invention.

FIG. 14 is an explanatory drawing showing another example of a method of forming a first electrode layer used in the invention.

FIG. 15 is an explanatory drawing showing yet another example of a method of forming a first electrode layer used in the invention.

FIGS. 16A and 16B are a process drawing showing an example of a method of producing an oxide semiconductor electrode with a heat-resistant substrate according to the invention.

FIGS. 17A and 17B are a process drawing showing another example of a method of producing an oxide semiconductor electrode with a heat-resistant substrate according to the invention.

FIGS. 18A and 18B are a process drawing showing an example of a method of producing an oxide semiconductor electrode according to the invention.

FIGS. 19A to 19D are a process drawing showing an example of a method of producing a dye-sensitized solar cell according to the invention.

FIG. 20 is an explanatory drawing showing an example of a dye-sensitized solar cell obtained by the invention.

### DESCRIPTION OF THE PREFERRED EMBODIMENT

Hereinafter, an oxide semiconductor electrode, an oxide semiconductor electrode with a heat-resistant substrate, a dye-sensitized solar cell, a method of producing a laminated body for an oxide semiconductor electrode, a method of producing an oxide semiconductor electrode with a heat-resistant substrate, a method of producing an oxide semiconductor electrode, and a method of producing a dye-sensitized solar cell according to the invention will be described.

A. Oxide Semiconductor Electrode

First, an oxide semiconductor electrode according to the invention will be described. An oxide semiconductor electrode according to the invention includes a base material, a bonding layer formed on the base material and made of a thermoplastic resin, a first electrode layer formed on the bonding layer and made of a metal oxide and, a porous layer formed on the first electrode layer and made of a fine particle of a metal oxide semiconductor.

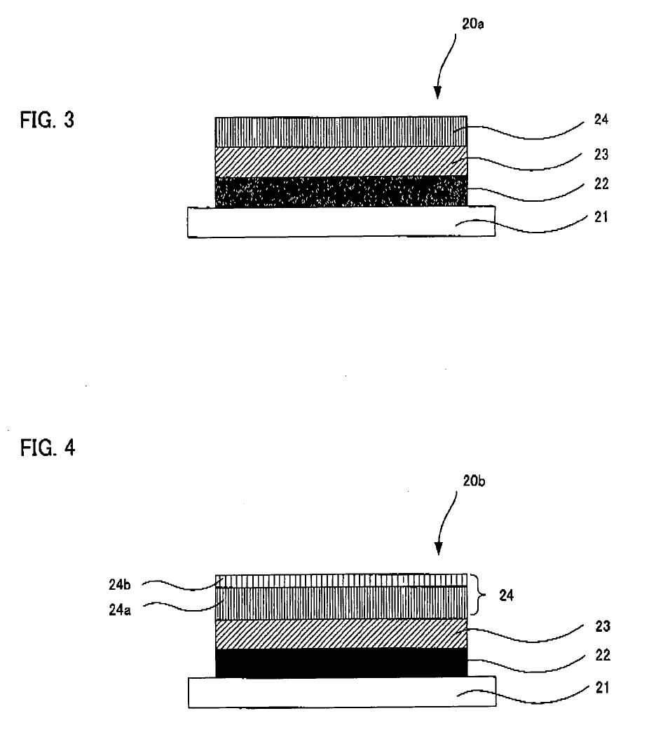

Next, the oxide semiconductor electrode according to the invention will be described with reference to the drawing. In FIG. 3, a schematic cross-sectional view showing one example of the oxide semiconductor electrode according to the invention is shown. As shown in FIG. 3, an oxide semiconductor electrode 20a of the invention includes a base material 21, a bonding layer 22 formed on the base material and made of a thermoplastic resin, a first electrode layer 23 formed on the bonding layer 22 and made of a metal oxide and, a porous layer 24 formed on the first electrode layer and made of a fine particle of a metal oxide semiconductor.

The oxide semiconductor electrode of the invention can be divided into “a oxide semiconductor electrode of a first aspect” where the thermoplastic resin contains a silane-modified resin, and “a oxide semiconductor electrode of a second aspect” where the porous layer is constituted of an oxide semiconductor layer in contact with the first electrode layer and an intermediate layer that is formed on the oxide semiconductor layer and higher in the porosity than the oxide semiconductor layer. Hereinafter, the oxide semiconductor electrode of the invention will be detailed separately as the oxide semiconductor electrode of the first aspect and of the oxide semiconductor electrode of the second aspect,

A-1: Oxide Semiconductor Electrode of First Aspect

Firstly, the oxide semiconductor electrode of the first aspect will be described. The oxide semiconductor electrode of the first aspect is an oxide semiconductor electrode including abase material, a bonding layer formed on the base material and made of a thermoplastic resin, a first electrode layer formed on the bonding layer and made of a metal oxides and a porous layer formed on the first electrode layer and made of a fine particle of a metal oxide semiconductor, wherein the thermoplastic resin includes a silane-modified resin.

According to the oxide semiconductor electrode of the first aspect, by using a silane-modified resin the thermoplastic resin, the adhesive force between the base material of the bonding layer and the first electrode layer can be strengthened. The mechanism why the adhesive force between the base material of the bonding layer and the first electrode layer is improved when the silane-modified resin is thus used as the thermoplastic resin is not clear. However, it is considered to be caused because a reactive functional group that the silane-modified resin has generates a condensation reaction or the like with a compound constituting the base material and the first electrode layer to form a chemical bond.

Furthermore, by using the silane-modified resin as the thermoplastic resin, as mentioned above, the adhesive force of the bonding layer can be strengthened. Accordingly, the adhesion stability where the adhesive force is not damaged can be obtained, even when a redox couple penetrates from the-electrolyte layer to the bonding layer. Accordingly, according to the oxide semiconductor electrode of the first aspect, an oxide semiconductor electrode that does not cause the interlayer peeling with time or the like and is excellent in the tempo-al stability can be obtained.

A method of producing an oxide semiconductor electrode by a transfer method is very useful in that the transfer method can be used regardless of a material of a base material that can be used for an oxide semiconductor electrode. In order to produce an oxide semiconductor electrode excellent in the temporal stability, it is necessary that the bonding layer has excellent adhesive force and the adhesive force has to be stably maintained for a long time. However, there is a problem in that an adhesive agent that has been used to produce an oxide semiconductor electrode by the conventional transfer method is insufficient in the adhesive force, thereby resulting in the interlayer peeling with time.

Furthermore, for example, when the oxide semiconductor electrode is used in a dye-sensitized solar cell, since a porous layer is porous, a phenomenon, wherein a redox couple contained in an electrolyte layer penetrates through the porous layer and furthermore penetrates through the electrode layer, is confirmed. Accordingly, in a dye-sensitized solar cell that uses an oxide semiconductor electrode with a bonding layer, there is a problem in that under the action of a redox couple, a solvent, and the like in the electrolyte layer, the adhesive force of the bonding layer is deteriorated to generate the interlayer peeling. Due to such problems, it was difficult to produce, with an oxide semiconductor electrode formed by use of the transfer method, a dye-sensitized solar cell excellent in the temporal stability.

According to the oxide semiconductor electrode of he first aspect of the invention, by using the silane-modified resin as the thermoplastic resin constituting the bonding layer, the adhesive force between the base material of the bonding layer and the first electrode layer can be strengthened. Accordingly, the oxide semiconductor electrode excellent in the temporal stability can be obtained. Hereinafter, the respective constituents of the oxide semiconductor electrode of the aspect will be described.

1. Bonding Layer

Firstly, a bonding layer in an oxide semiconductor electrode of a first aspect will be described. The bonding layer in the aspect has a function of adhering the base material and the first electrode layer, and is made of a silane-modified resin.

(1) Silane-modified Resin

The silane-modified resin used in the aspect is not particularly restricted, as far as it shows the thermoplasticity and the adhesive properties with the base material and the first electrode layer described below. In the aspect, the melting point thereof is preferably in the range of 50 to 200° C.; more preferably in the range of 60 to 180° C.; and particularly preferably in the range of 65 to 150° C. When the melting point is lower than the above range, for example, when a dye-sensitized solar cell produced with the oxide semiconductor electrode of the aspect is used in the open air, the adhesion between the base material and the first electrode layer may not be sufficiently maintained. On the other hand, when the melting point is higher than the above range, when a dye-sensitized solar cell is produced from the oxide semiconductor electrode of the aspect by means of, for example, the transfer method, since in the transfer process a heating process higher than the melting point is necessary, the base material itself nay be thermally damaged depending on the kind of the base material that is used in the aspect.

The silane-modified resin used in the aspect is not particularly restricted as far as it has the above melting point. Among these, as the silane-modified resin used in the aspect, a copolymer of a polyolefin compound and an ethylenic unsaturated silane compound is preferably used. This is because when such a copolymer is used, for example, depending on a method of producing the oxide semiconductor electrode of the aspect, various physicalities of the silane-modified resin can be readily controlled in a preferable range. In the aspect, the copolymer may be or may not be crosslinked with a silanol catalyst.

As the polyolefin compound used in the aspect, homopolymers of α-olefins having substantially 2 to 8 carbon atoms such as an ethylene, a propylene and a 1-butene, and copolymers between the above-mentioned α-olefins and other α-olefins having substantially 2 to 20 carbon atoms such as an ethylene, a propylene, a 1-butene, a 3-methyl-1-butene, a 1-pentene, a 4-methyl-1-pentene, a 1-hexene, a 1-octene and a 1-decene, a vinyl acetate, a (meth)acrylic acid and a (meth)acrylic acid ester can be cited. Specifically, for example, ethylenic resins such as (branched or linear) ethylene homopolymers such as low, medium and high density polyethylene, ethylene-propylene copolymers, ethyle-1-butene copolymers, ethylene-4-methyl-1-pentene copolymers, ethylene-1-hexene copolymers, ethyle-1-octene copolymers, ethylene-vinyl acetate copolymers, ethylene-(meth)acrylic acid copolymers and ethylene-(meth)acrylic acid ester copolymers, propylenic resins such as propylene homopolymers, propylene-ethylene copolymers and propylene-ethylene-1-butene copolymers, and 1-betenic resins such as 1-butene homopolymers, 1-butene-ethylene copolymers and 1-butene-propylene copolymers can be cited. Among these, in the aspect, the polyethylenic resins are preferable.

The copolymers used in the aspect may be any one of a random copolymer, an alternative copolymer, a block copolymer and a graft copolymer. In the aspect, the graft copolymers are preferable, and graft copolymers polymerized with polymerizing polyethylene as a main chain and an ethylenic unsaturated silane compound as a side chain are more preferable. In such graft copolymers, since the degree of freedom of the silanol group that contributes to the adhesive force becomes higher, the adhesive force of the bonding layer can be more strengthened.

The polyethylenic resin used in the aspect (hereinafter, referred to as polyethylene for polymerization) is not particularly restricted as far as it is a polyethylenic polymer. As such polyethylenic polymers, low density polyethylene, medium density polyethylene, high density polyethylene, very low density polyethylene, ultra low density polyethylene or linear low density polyethylene can be cited. Furthermore, in the aspect, one kind of these polyethylenic polymers may be used singularly or at least two kinds thereof may be combined to use.

Furthermore, the polyethylene for polymerization used in the aspect is preferably one that is low in the density among the polyethylenic polymers. Specifically, one of which density is in the range of 0.850 to 0.960 g/cm³ is preferable and one of which density is in the range of 0.865 to 0.930 g/cm³ is particularly preferable. The polyethylenic polymer low in the density generally containing many side chains so that it can be preferably used in the graft polymerization. Accordingly, when the density is higher than the range, the graft polymerization becomes insufficient, and thereby in some cases desired adhesive force may rot be imparted to the bonding layer. On the other hand, when the density is lower than the range, the mechanical strength of be bonding layer may be damaged.

As the ethylenic unsaturated silane compound used in the aspect, there is no particular restriction, as far as it can polymerize with the polyethylene for polymerization to form a thermoplastic resin. As such ethylenic unsaturated silane compound, at least one kind selected from a group of vinyltrimethoxysilane, vinyltriethoxysilane, vinyltripropoxysilane, vinyltributoxysilane, vinyltripentyloxysilane, vinyltriphenoxysilane, vinyltribenzyloxysilane, vinyltrimethylenedioxysilane, vinyltriethylenedioxysilane, vinylpropionyloxysilane, vinyltriacetoxysilane and vinyltricarboxysilane can be preferably used.

Next, a method of producing a graft copolymer between the polyolefin compound and the ethylenic unsaturated silane compound will be described. A method of producing such a graft copolymer is not particularly restricted as far as it can obtain a desired yield, and known polymerization methods can be used to produce. Among these, in the aspect, a method wherein a silane-modified resin composition made of the polyolefin compound, the ethylenic unsaturated silane compound and a free radical generator is heated/melted/mixed to obtain a graft copolymer, can be preferably used. This is because, according to such a method, the graft copolymer can be readily obtained at high yield.

A heating temperature during the heating/melting/mixing is not particularly restricted as far as a polymerization reaction comes to completion within a predetermined time period. Normally, it is preferable to be 300° C. or less; more preferable to be 270° C. or less; and particular preferable to be in the range of 160 to 250° C. When the heating temperature is lower than the above range, in some cases, the polymerization reaction does not proceed sufficiently. On the other hand, when the heating temperature is higher than the above range, there is a risk that a portion of silanol group is crosslinked to gelate.

The free radical generator is not particularly restricted as far as it can contribute to forward the polymerization reaction. Examples of such free radical generator include: organic peroxides such as hydroperoxides such as diisopropylbenzene hydroperoxide and 2,5-dimethyl-2,5-di(hydroperoxy)hexane; dialkyl peroxides such as di-t-butyl peroxide, t-butyl cumyl peroxide, dicumyl peroxide, 2,5-dimethyl-2,5-di(t-butyl peroxy) hexane and 2,5-dimethyl-2,5-di(t-peroxy)hexane-3; diacyl peroxides such as bis-3,5,5-trimethyl hexanoyl peroxide, octanoyl peroxide, benzoyl peroxide, o-methyl benzoyl peroxide and 2,4-dichlorobenzoyl peroxide; peroxy esters such as t-butyl peroxy isobutyrate, t-butyl peroxy acetate, t-butyl peroxy-2-ethyl hexanoate, t-butyl peroxy pyvalate, t-butyl peroxy octoate, t-butyl peroxy isopropyl carbonate, t-butyl peroxy benzoate, di-t-butyl peroxy phthalate, 2,5-dimethyl-2,5-di(benzoyl peroxy)hexane and 2,5-dimethyl-2,5-di (benzoyl peroxy)hexane-3; and ketone peroxides such as methyl ethyl ketone peroxide and cyclohexanone peroxide, or azo compounds such as azobisisobutyronitrile and azobis(2,4-dimethylvaleronitrile). The free radical generators may be singularly used as a single body or in a combination of at least two kinds thereof.

A content of the free radical generator in the silane-modified resin composition can be arbitrarily determined depending on the kind of the free radical generator and the polymerization conditions. The content is preferably in the range where a residual amount thereof in the silane-modified resin obtained by the polymerization reaction is in the range of 0.001 mass percent or less. In the aspect, normally, to 100 parts by weight of the polyolefin compound in the silane-modified resin composition, the free radical generator is preferably contained by 0.001 parts by weight or more, and particularly preferably in the range of 0.01 to 5 parts by weight.

A content of the ethylenic unsaturated silane compound in the silane-modified resin composition is preferably, to 100 parts by weight of the polyethylene for polymerization, in the range of 0.001 to 4 parts by weight; and more preferably in the range of 0.01 to 3 parts by weight. When the content of the ethylenic unsaturated silane compound is more than the above range, free ethylenic unsaturated silane compounds may remain without being polymerized. On the other hand, when the content is less than the above range, the adhesive force of the bonding layer becomes insufficient and thereby the stability of the oxide semiconductor electrode of the aspect may be damaged.

(2) Other compounds

In the bonding layer of the aspect, if necessary, other compounds than the silane-modified resin may be contained. In the aspect, as such other compound, a thermoplastic resin is preferably used, and a polyolefin compound (hereinafter, referred to as polyolefin compound for addition) can be more preferably used. Furthermore, when a copolymer of a polyolefin compound and an ethylenic unsaturated silane compound is used as the silane-modified resin contained in the bonding layer, a polyolefin compound used in the copolymer is preferably used as such a polyolefin compound for addition.

In the aspect, a content of the polyolefin compound for addition in the bonding layer is, to 100 parts by weight of the silane-modified resin, preferably in the range of 0.01 to 9900 parts by weight; and particularly preferably in the range 0.1 to 2000 parts by weight. When the content of the polyolefin compound for addition is less than the range, in some cases, it is disadvantageous from a viewpoint of the cost. On the other hand, when the content is more than the range, the adhesive force of the bonding layer may be insufficient.

In the aspect, as the polyolefin compound, a polyethylenic resin (hereinafter referred to as polyethylene for addition) is preferably used. This is because, in the aspect a copolymer of a polyethylenic resin and an ethylenic unsaturated silane compound is preferably used as the silane-modified resin.

As the polyethylene for addition, at least one kind selected from a group of low density polyethylene, medium density polyethylene, high density polyethylene, very low density polyethylene and linear low density polyethylene can be preferably used.

Furthermore, the bonding layer used in the aspect preferably contains at least one kind of additive selected from a group of a light stabilizer, a UV absorber, a thermal stabilizer and an antioxidant. This is because, when the additives are contained, the mechanical strength, prevention of yellowing, prevention of cracking and excellent processability can be stably obtained over a long period.

The light stabilizer arrests an active species that initiates light deterioration in the thermoplastic resin used in the bonding layer to inhibit the photo oxidation from occurring. Specifically, the light stabilizers such as hindered amine-based compounds and hindered piperidine compounds can be cited.

The UV absorber absorbs harmful UV ray in sunlight to convert the ray into harmless thermal energy in the molecule, and thereby inhibits an active species that initiates light deterioration in the thermoplastic resin used in the bonding layer from being excited. Specifically, inorganic UV absorbers such as benzophenone-based absorbers, benzotriazole-based absorbers, salicylate-based absorbers, acrylonitrile-based absorbers, metal complex salt-based absorbers, hindered amine-based absorbers and ultra fine particle titanium oxide (particle size: 0.01 to 0.06 μm), or ultra fine particle zinc oxide (particle size: 0.01 to 0.04 μm) can be listed.

As the thermal stabilizer, phosphorus-based thermal stabilizers such as tris(2,4-di-t-butylphenyl)phosphite, bis[2,4-bis(1,1-dimethylethyl)-6-methylphenyl]ethyl phosphate, tetrakis(2,4-di-t-butylphenyl)[1,1-biphenyl]-4,4′-diyl bisphosphonite and bis(2,4-di-t-butylphenyl)pentaerythritol diphosphite; lactone-based thermal stabilizers such as a reaction product of 8-hydroxy-5,7-di-t-butyl-furan-2-one and o-xylene can be listed. It is preferable to use a phosphorus-based thermal stabilizer and a Lactone-based thermal stabilizer together in combination.

The antioxidant inhibits the thermoplastic resin-used in the bonding layer from deteriorating owing to the oxidation. Specific examples thereof include the antioxidants such as phenol-based, amine-based, sulfur-based, phosphorus-based, and lactone-based antioxidants.

These light stabilizers, UV absorbers, thermal stabilizers and antioxidants, respectively, can be used singularly or in combination of at least two kinds.

A content of each of the lights stabilizer, UV absorber, thermal stabilizer and antioxidant, though different depending on its particle shape, density and the like, is preferably in a range of 0.001 to 5 mass percent respectively based on materials in the bonding layer.

Furthermore, as other compounds used in the aspect, other than the above compounds, a crosslinking agent, a dispersing agent, a leveling agent, a plasticizer and a defoaming agent can be cited.

(3) Bonding Layer

A thickness of the bonding layer used in the aspect is not particularly restricted as far as it is in the range that can develop the adhesive force necessary in accordance with the species of the silane-modified resin constituting the bonding layer. Normally, it is preferably in the range of 5 to 300 μm and particularly preferably in the range of 10 to 200 μm. When the thickness of the bonding layer is thinner than the above range, in some cases, desired adhesive force may not be obtained. On the other hand, when the thickness thereof is thicker than the above range, in order to sufficiently develop the interlayer adhesive strength by the bonding layer, excessive heating becomes necessary, resulting in causing large thermal damage to the base material or the like in some cases.

2. First Electrode Layer

Next, a first electrode layer used in the aspect will be described. The first electrode layer used in the aspect is made of a metal oxide.

(1) Metal Oxide

A metal oxide used in the aspect is not particularly restricted as far as it is a material that is excellent in the electrical conductivity and has the resistance to a redox couple described below. In the aspect, a material excellent in the transparency to sunlight is preferably used. This is because, for example, when a dye-sensitized solar cell is produced with an oxide semiconductor electrode of the aspect, since normally an aspect where sunlight is received from a base material side is taken, if the metal oxide is poor in the transparency to sunlight, the electricity generating efficiency of the dye-sensitized solar cell with the oxide semiconductor electrode of the aspect gets deteriorated.

As the metal, oxide excellent in the sunlight transparency, for example, SnO₂, ITO, IZO and ZnO can be cited. In the invention, among the metal oxides, fluorine-doped SnO₂ (hereinafter referred to as FTO) and ITO are preferably used. This is because the FTO and ITO are excellent in both of the electrical conductivity and transparency to sunlight.

(2) First Electrode Layer

A first electrode layer in the invention may have a configuration made of a single layer or a configuration where a plurality of layers is laminated. As the configuration where a plurality of layers is laminated, for example, an aspect wherein layers different in the work function from each other are laminated, or an aspect where layers made of metal oxides different from each other are laminated can be cited.

A thickness of the first electrode layer in the aspect is not particularly restricted, as far as it is within a range that can realize desired electrical conductivity in accordance with an application of a dye-sensitized solar cell using an oxide semiconductor electrode of the aspect. The thickness of the first electrode layer in the aspect is normally preferably in the range of 5 to 2000 nm, and particularly preferably in the range of 10 to 1000 nm. When the thickness is thicker than the above range, in some cases, the first electrode layer has difficulty in forming uniformly. Furthermore, when the thickness is thinner than the above range, depending on an application of the oxide semiconductor electrode according to the aspect, the electrical conductivity of the first electrode layer may be insufficient

A thickness of the first electrode layer, when the first electrode layer is constituted of a plurality of layers, indicates a total thickness obtained by summing thicknesses of all layers.

Furthermore, as the first electrode layer in the invention, one having a configuration wherein, on a base material, a metal mesh that has a sufficient opening to be transparent to light and the metal oxide are integrated or laminated, can be used as well.

3. Porous Layer

Next, a porous layer in the aspect will be described. The porous layer used in the invention includes a fine particle of a metal oxide semiconductor.

(1) Fine Particle of Metal Oxide Semiconductor

Examples of the fine particle of the metal oxide semiconductor used in the embodiment includes TiO₂, ZnO, SnO₂, ITO, ZrO₂, MgO, Al₂O₃, CeO₂, Bi₂O₃, Mn₃O₄, Y₂O₃, WO₃, Ta₂O₅, Nb₂O₅, and La₂O₃. The fine particle of these metal oxide semiconductors are preferred for oxide semiconductor electrode of the present embodiment because they are suitable for the production of the porous layer with porous property and can increase energy conversion efficiency and reduce costs. One kind of these fine particles or a mixture of two or more kinds of these fine particles may be used. One kind of these fine particles may be used to form a fine core particle, and any other fine particles may be used to form a shell surrounding each of the fine core particles in a core-shell structure. In the embodiment, TiO₂ is most preferably used for the fine particle of the metal oxide semiconductor.

A particle diameter of the fine particle of a metal oxide semiconductor used in the aspect is not particularly restricted, as far as it is in the range that can obtain a desired surface area in the porous layer. Normally, it is preferably in the range of 1 nm to 10 μm and particularly preferably in the range of 10 nm to 1000 nm. When the particle diameter is smaller than the above range, in some cases, the respective fine particle of a metal oxide semiconductor may coagulate to form secondary particles. On the other hand, when the particle diameter is larger than the above range, not only the porous layer is thickened but also the porosity of the porous layer, that is, the specific surface area decreases. As a result, for example, when the oxide semiconductor electrode of the aspect is applied to a dye-sensitized solar cell, in some cases, a dye sensitizer sufficient to carry out the photoelectric conversion cannot be supported in the porous layer.

Furthermore, in the aspect, as the fine particle of a metal oxide semiconductor, a mixture of a plurality of fine particle of a metal oxide semiconductor different in the particle diameter may be used. By using a mixture of a plurality of fine particle of a metal oxide semiconductor different in the particle diameter, the light scattering effect in the porous layer can be heightened. As a result, for example, when the oxide semiconductor electrode of the aspect is applied to a dye-sensitized solar cell, the light absorption by the dye sensitizer can be efficiently carried out. Accordingly, in the aspect, a mixture of a plurality of fine particle of a metal oxide semiconductor different in the particle diameter can be particularly preferably used.

As such a mixture of a plurality of fine particle of a metal oxide semiconductor different in the particle diameter, it may be a mixture of fine particle of a metal oxide semiconductor same in the species or a mixture of fine particle of metal oxide semiconductors different in the species. As a combination of different particle diameters, for example, an aspect wherein fine particle of a metal oxide semiconductor in the range of 10 to 50 nm and fine particle of a metal oxide semiconductor in the range of 50 to 800 nm are mixed to use can be cited.

(2) Other Compounds

The porous layer in the aspect preferably contains a metal element same as the metal element that a metal oxide constituting the first electrode layer has (hereinafter, in some cases, referred to as electrode metal element). This is because when the porous layer contains the electrode metal element, the oxide semiconductor electrode according to the aspect can be made excellent in the electrical conductivity.

A distribution of the electrode metal element in the porous layer can be arbitrarily determined in accordance with an application of the oxide semiconductor electrode of the aspect. However, it is preferable to have a concentration gradient that is in a decreasing tendency form a surface on the first electrode layer side to a surface on an opposite side. This is because, in the porous layer, when the electrode metal element has such a distribution, the current collection efficiency of the porous layer can be further improved.

In the aspect, whether or not the electrode metal element is contained in the porous layer and has the above-mentioned distribution can be judged when the strength of characteristic X-ray of a metal element wanted to be specified is mapped in two dimension with an electron beam as a probe. Specifically, an EPMA (Electron Probe Micro Analyzer) manufactured by JEOL DATUM can be used to judge. Furthermore, the concentration gradient of the metal element can be judged from a profile of the strength detected in a vertical direction (sectional vertical direction) in a sectional element mapping image obtained by use of the EMMA.

Furthermore, the porous layer in the aspect preferably contains a dye sensitizer. That is, it is preferable that on a surface of the fine particle of a metal oxide semiconductor contained in the porous layer a dye sensitizer is absorbed. This is because by the porous layer containing the dye sensitizer, in the case of the oxide semiconductor electrode of the aspect being used in the dye-sensitized solar cell, a process of producing the dye-sensitized solar cell can be simplified. As the dye sensitizer used in the aspect, there is no particular restriction as far as it can absorb light and generate the electromotive force. The dye sensitizer like this, being same as that mentioned in a section of “G. Method of Producing Dye-Sensitized Solar Cell” described below, will be omitted from explaining here.

In the aspect, the above wording “including a dye sensitizer” means that the dye sensitizer is absorbed on the surface of a fine particle of an oxide semiconductor contained in the porous layer (intermediate layer and oxide semiconductor layer).

(3) Porous Layer

A film thickness of the porous layer in the aspect is not particularly restricted, as far as it is in a range that can impart desired mechanical strength to the porous layer in accordance with an application of the oxide semiconductor electrode of the invention. The film thickness of the porous layer in the invention is normally preferably in the range of 1 to 100 μm, and particularly preferably in the range of 5 to 30 μm. When the thickness of the porous layer is thicker than the above range, the peeling from the bonding layer and the cohesion failure of the porous layer itself are likely to occur to result in the membrane resistance in some cases. When the thickness of the porous layer is thinner than the above range, a uniform porous layer is formed with difficulty, and, for example, when the oxide semiconductor electrode of the aspect is applied to a dye-sensitized solar cell, since the porous layer containing a dye sensitizer cannot sufficiently absorb sunlight, the performance failure may be caused.

The porous layer in the aspect may have a configuration made of a single layer or a configuration where a plurality of layers is laminated. However, in the aspect, the porous layer preferably has a configuration where a plurality of layers laminated. As a configuration where a plurality of layers is laminated, in accordance with a method of producing an oxide semiconductor electrode of the aspect or the like, an arbitrary configuration can be appropriately selected to adopt. Above all, in the aspect, the porous layer is preferably formed into a two-layer structure that is made of an oxide semiconductor layer in contact with the first electrode layer and an intermediate layer that is formed on the oxide semiconductor layer and higher in the porosity than the oxide semiconductor layer. This is because when the porous layer is formed into a two-layer structure made of the oxide semiconductor layer and the intermediate layer, when the porous layer is formed by use of the transfer method, the adhesive force between the heat-resistant substrate and the porous layer can be lowered and thereby an oxide semiconductor electrode excellent in the productivity due to the transfer method can be obtained.

In the aspect, when the porous layer is formed into a two-layer structure that is made of an oxide semiconductor layer in contact with the first electrode layer and an intermediate layer that is formed on the oxide semiconductor layer and higher in the porosity than the oxide semiconductor layer, the intermediate layer is not necessarily formed uniformly on the oxide semiconductor layer, that is, may have a thickness distribution, or may have a portion where the intermediate layer is not present on the oxide semiconductor layer. This is because, even when the intermediate layer is present in such a manner, an oxide semiconductor electrode excellent in the productivity can be obtained by means of the transfer method.

A thickness ratio of the oxide semiconductor layer and the intermediate layer when the porous layer is formed into a two-layer structure of the oxide semiconductor layer and the intermediate layer may well be optionally determined in accordance with a method of producing the oxide semiconductor electrode of the aspect or the like. Above all, in the aspect, a thickness ratio of the oxide semiconductor layer and the intermediate layer is preferably in the range of 10:0.1 to 10:5; more preferably in the range of 10:0.1 to 10:3. When the thickness of the intermediate layer is thicker than the above range, the cohesion failure of the intermediate layer becomes likely to occur. Accordingly, when the oxide semiconductor electrodes of the invention are produced, the yield is deteriorated, and, for example, when the oxide semiconductor electrode of the aspect is applied to a dye-sensitized solar cell, on a surface of the fine particle of a metal oxide semiconductor contained in the porous layer, a desired amount of the dye sensitizer may not be absorbed. Furthermore, when the thickness is thinner than the above range, in some cases, the productivity of the oxide semiconductor electrode of the aspect may not be improved.

The porosity of the oxide semiconductor layer is preferably in the range of 10 to 60%, and more preferably in the range of 20 to 50%. For example, when the oxide semiconductor electrode of the aspect is applied to a dye-sensitized solar cell, if the porosity of the oxide semiconductor electrode is smaller than the above range, a specific surface area becomes smaller; accordingly, the porous layer containing the dye sensitizer may not effectively absorb sunlight or the like. On the other hand, when the porosity of the oxide, semiconductor layer is larger than the above range, a desired amount of the dye sensitizer may not be contained in the oxide semiconductor layer.

The porosity of the intermediate layer is not particularly restricted, as far as it is larger than that of the oxide semiconductor layer. Normally, it is normally preferably in the range of 25 to 65%, and particularly preferably in the range of 30 to 60%. When the porosity of the intermediate layer is smaller than the above range, the adhesion with the heat-resistant substrate becomes higher; accordingly, the productivity may be deteriorated. On the other hand, when the porosity of the intermediate layer is larger than the above range, in some cases, it is difficult to form a uniform intermediate layer.

The porosity in the invention indicates a non-occupation rate of the fine particle of a metal oxide per unit volume. In the measurement method of the porosity, a pore volume is measured with a gas absorption amount analyzer (trade name: Autosorb-1MP, manufactured by Quantachrome Instruments) and the porosity is calculated from a ratio to a volume per unit area. As to the porosity of the intermediate layer, the porosity of the porous layer laminated with the oxide semiconductor layer is obtained followed by calculating from a value obtained as a simple body of the oxide semiconductor layer.

4. Base Material

Next, the base material used in the aspect will be described. The base material that can be used in the aspect is not particularly restricted, as far as it has desired transparency in accordance with an application of the oxide semiconductor electrode of the aspect or the like. Normally, the transmittance to light in a wavelength range of 400 to 1000 nm is preferably 78% or more, and more preferably 80% or more. This is because if the transmittance of the base material is lower than the above range, for example, when a dye-sensitized solar cell is produced with the oxide semiconductor electrode of the aspect, the electricity generation efficiency may be damaged.

Furthermore, the base material that is used in the aspect, among the above-mentioned transparent ones, is preferably one that is excellent in the heat resistance, the weather resistance and the gas barrier property to moisture and other. This is because by the base material having the gas barrier property, for example, when the oxide semiconductor electrode of the aspect is applied to a dye-sensitized solar cell, the temporal stability can be improved. In the aspect, a base material having the gas barrier property in that the oxygen transmission rate under the conditions of 23° C. and 90% humidity is 1 cc/m²/day atm or less and the moisture transmission rate under the conditions of 37.8° C. and 100% humidity is 1 g/m²/day or less is preferably used. In the aspect, in order to achieve such gas barrier properties, one in which a gas barrier layer is disposed on an arbitrary base material may be used.

As examples of the base material having the gas barrier property include an inflexible rigid transparent substrate such as a quartz glass plate, a Pyrex (registered trademark) glass plate, and a synthetic quartz plate; and a resin film base material such as an ethylene-tetrafluoroethylene copolymer film, a biaxially oriented polyethylene terephthalate film, a polyethersulfone (PES) film, a polyetheretherketone (PEEK) film, a polyetherimide (PEI) film, a polyimide (PI) film, and a polyester naphthalate (PEN) film.

In the present embodiment, the resin film base material is more preferably used among the above-mentioned base material. This is because the resin film base material has good workability and can easily be used in combination with any other device and can find a wide range of applications. The resin film base material is also effective in improving productivity and reducing production costs. A single type of a base material may be used alone, or two or more types may be laminated to form the base material of the embodiment. In the embodiment, a biaxial oriented polyethylene terephthalate film (PET), a polyester naphthalate (PEN), a polycarbonate (PC) are particularly preferable for the base material.

A thickness of the base material used in the aspect is not particularly restricted, as far as it is in the range that has the self-supporting properties in accordance with an application of the oxide semiconductor electrode of the aspect or the like. In the aspect, the thickness of the base material is normally preferably in the range of 50 to 2000 Mm; more preferably in the range of 75 to 1800 μm; and particularly preferably in the range of 100 to 1500 μm. When the thickness of the base material is thinner than the above range, in some cases, necessary self-supporting properties cannot be secured. On the other hand, when the thickness of the base material is thicker than the above range, the processability may be damaged.

5. Oxide Semiconductor Electrode

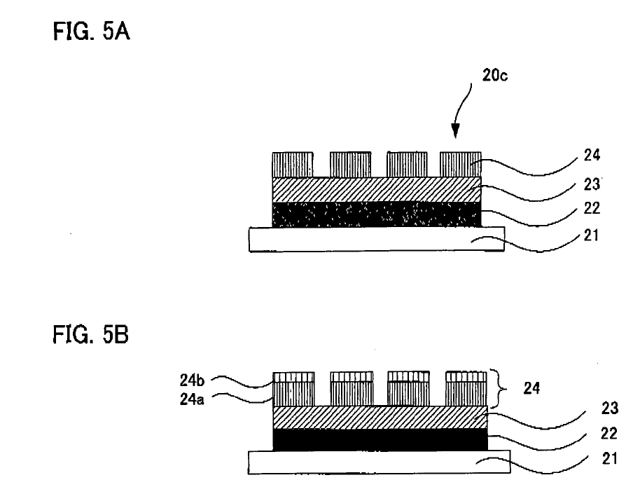

The porous layer in the oxide semiconductor electrode of the aspect is preferably patterned. This is because, when the porous layer is patterned, the oxide semiconductor electrode of the aspect can be made one preferable to produce a dye-sensitized solar cell high in the module electromotive force. The patterning of the porous layer in the aspect will be described with reference to the drawing. FIGS. 5A and 5B are schematic cross-sectional views showing an example of a patterning aspect of the porous layer in the aspect. In the patterning of the porous layer in the aspect, as shown in FIG. 3A, at least a porous layer 24 has only to be patterned. Furthermore, as shown in FIG. 5B, when the porous layer 24 is made of an oxide semiconductor layer 24a and an intermediate layer 24b, it is preferable that both layers are patterned in the same shape.

Furthermore, as a patterning aspect of the porous layer in the aspect, the porous layer 24 and the first electrode layer 23 are preferably patterned. When the porous layer 24 and the first electrode layer 23 are patterned, the patterning shapes of the porous layer 24 and the first electrode layer 23 are preferably different from each other such as that a patterning shape of the porous layer 24 is smaller than a patterning shape of the first electrode layer 23.

A pattern when the porous layer is patterned in the aspect can be arbitrarily determined depending on an application or the like of the oxide semiconductor electrode of the aspect. However, the pattern is most preferably formed in stripe.

A method of patterning the porous layer is not particularly restricted, as far as it can pattern the porous layer into a desired pattern with precision. As a patterning method that can be used in the aspect, for example, laser scribe, wet etching, lift-off, dry etching and mechanical scribe can be cited. Among these, the laser scribe and the mechanical scribe are preferable.

As a patterning method other than the above methods, an example where, as shown in FIG. 8, after a patterning base material 30 having a hot-melt resin layer 32 patterned on an arbitrary base material 31 and the oxide semiconductor electrode of the aspect are heat-sealed so that the hot melt resin layer 32 and the porous layer 24 may be brought into contact, the patterning base material 30 is peeled to pattern the porous layer can be cited. As a method of forming a patterned hot-melt resin layer on the base material 31, without restricting to particular one, a known method such as a printing method can be used.

When the oxide semiconductor electrode of the aspect is used to produce a dye-sensitized solar cell, the patterning process may be carried out in a state where the porous layer does not contain a dye sensitizer, or, after the supporting process of the dye sensitizer described below, wherein the porous layer contains the dye sensitizer.

The oxide semiconductor electrode of the aspect can be used as a base material for a dye-sensitized light chargeable capacitor used in a dye-sensitized light chargeable capacitor, a base material for an electrochromic display used in an electrochromic display, a contaminant decomposition base material that can decompose a contaminant in air due to a photocatalyst reaction, a base material for a dye-sensitized solar cell used in a dye-sensitized solar cell, and the like. Above all, the oxide semiconductor electrode can be preferably used as a base material for a dye-sensitized solar cell used in a dye-sensitized solar cell.

6. Method of Producing Oxide Semiconductor Electrode

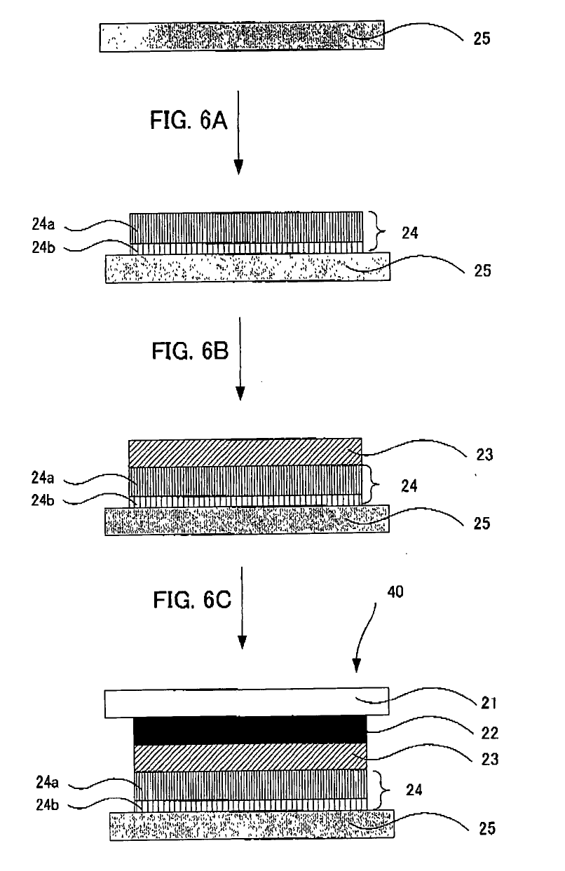

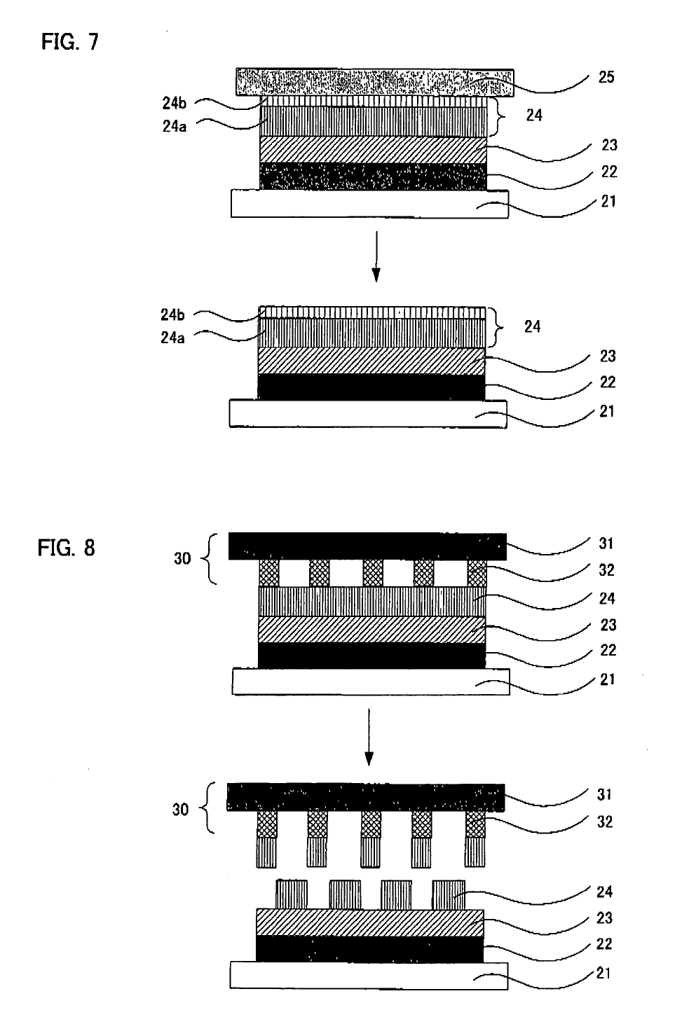

A method of producing an oxide semiconductor electrode of the aspect is not particularly restricted, as far as it can produce an oxide semiconductor electrode having the above-mentioned configuration. As such a method, normally, a method wherein a laminated body of a porous layer and a first electrode layer is transferred can be used on the substrate through a bonding layer. Such a method of producing an oxide semiconductor electrode of the aspect will be described with reference to the drawing. FIGS. 6A to 6C are schematic views showing an example of a method of producing an oxide semiconductor electrode of the aspect. As illustrated in FIGS. 6A to 6C, the oxide semiconductor electrode of the aspect can be produced by the following method. After producing an oxide semiconductor electrode with a heat-resistant substrate 40 by the process of forming a base material with a heat-resistant substrate that includes: the process of forming a porous layer of forming a porous layer 24 on a heat-resistant substrate 25 (FIG. 6A); the process of forming a first electrode layer of forming a first electrode layer 23 on the porous layer 24 (FIG. 6B); and the process of forming a base material of imparting a bonding layer 22 and base material 21 on the first electrode layer 23 (FIG. 6C), a heat-resistant substrate 25 that the oxide semiconductor electrode with a heat-resistant substrate 40 has is peeled off from the porous layer 24 in the process of peeling the heat-resistant substrate shown in FIG. 7. In the aspect, as such a method, for example, a method detailed below in a section of “F. Method of Producing Oxide Semiconductor Electrode” can be preferably used.

A-2: Oxide Semiconductor Electrode of Second Aspect

Next, an oxide semiconductor electrode of a second aspect of the invention will be described. The oxide semiconductor electrode of the second aspect is an oxide semiconductor electrode including a base material, a bonding layer formed on the base material and made of a thermoplastic resin, a first electrode layer formed on the bonding layer and made of a metal oxide, and a porous layer formed on the first electrode layer and containing the fine particle of a metal oxide semiconductor, wherein the porous layer being formed of an oxide semiconductor layer in contact with the first electrode layer and an intermediate layer formed on the oxide semiconductor layer and higher in the porosity than the oxide semiconductor layer.

A schematic cross-sectional view showing an example of the oxide semiconductor electrode of the second aspect is shown in FIG. 4. As shown in FIG. 4, in the oxide semiconductor electrode of the second aspect 20b, a porous layer 24 includes an oxide semiconductor layer 24a in contact with the first electrode layer and an intermediate layer 24b formed on the oxide semiconductor layer 24a and higher in the porosity than that the oxide semiconductor layer 24a.

According to the oxide semiconductor electrode of the second aspect, since the porous layer is made of the oxide semiconductor layer and the intermediate layer, an oxide semiconductor electrode excellent in the productivity by the transfer method can be obtained. That is, when a porous layer is formed by means of the transfer method, the porous layer is peeled off from the heat-resistant substrate. If the adhesive force between the heat-resistant substrate and the porous layer is high, when the porous layer is peeled off from the heat-resistant substrate, the porous layer is damaged and thereby a high quality porous layer cannot be obtained. As shown in FIG. 4, when the porous layer 24 is made of the oxide semiconductor layer 24 a and the intermediate layer 24b, since the adhesive force between the porous layer 24 and the heat-resistant substrate can be reduced, an oxide semiconductor electrode excellent in the productivity by the transfer method can be obtained. Hereinafter, the respective configurations of the oxide semiconductor electrode of the aspect will be described.

1. Porous Layer

First, a porous layer will be described. The porous layer in the aspect includes an oxide semiconductor layer in contact with the first electrode layer and an intermediate layer formed on the oxide semiconductor layer and higher in the porosity than the oxide semiconductor layer. In the aspect, by forming the porous layer into a two-layer structure, when the porous layer is formed by the transfer method, the adhesive force between the heat-resistant substrate and the porous layer can be lowered. Accordingly, an oxide semiconductor electrode excellent in the productivity due to the transfer method can be obtained.

(1) Configuration of Porous Layer

In the aspect, the intermediate layer constituting the porous layer is not necessarily formed uniformly on she oxide semiconductor layer, that is, may have a thickness distribution, or may have a portion where the intermediate layer is not present on the oxide semiconductor layer. This is because, even when the intermediate layer is present in such a manner, an oxide semiconductor electrode excellent in the productivity can be obtained by means of the transfer method.

A thickness ratio of the oxide semiconductor layer and the intermediate layer may well be optionally determined according to a method of producing the oxide semiconductor electrode of the aspect or the like. In the aspect, a thickness ratio of the oxide semiconductor layer and the intermediate layer is preferably in the range of 10:0.1 to 10:5; more preferably in the range of 10:0.1 to 10:3. When the thickness of the intermediate layer is thicker than the above range, for example, when the oxide semiconductor electrode of the aspect is applied to a dye-sensitized solar cell a desired amount of the dye sensitizer may not be included in the porous layer. Furthermore, when the thickness is thinner than the above range, in some cases, the productivity of the oxide semiconductor electrode according to the aspect may not be improved.

The porosity of the oxide semiconductor layer can be optionally determined in accordance with an application or the like of the oxide semiconductor electrode of the embodiment. In the embodiment, it is preferably in the range of 10 to 60%; and more preferably in the range of 20 to 50%. For example, when the oxide semiconductor electrode of the aspect is applied to a dye-sensitized solar cell, if the porosity of the oxide semiconductor electrode is smaller than the above range, a function to conduct the charge generated by the dye sensitizer to the first electrode layer may be deteriorated. On the other hand, when the porosity of the oxide semiconductor layer is larger than the above range, a desired amount of the dye sensitizer may not be contained in the oxide semiconductor layer.

The porosity of the intermediate layer is not particularly restricted, as far as it is larger than that of the oxide semiconductor layer. However, it is normally preferably in the range of 25 to 65%; and particularly preferably in the range of 30 to 60%. When the porosity of the intermediate layer is smaller than the above range, the adhesion with the heat-resistant substrate becomes higher; accordingly, the productivity may be deteriorated. On the other hand, when the porosity of the intermediate layer is larger than the above range, in some cases, it is difficult to form a uniform intermediate layer.

(2) Fine Particle of Metal Oxide Semiconductor

The fine particle of a metal oxide semiconductor used in the invention are similar to one described in a section of 3. Porous Layer, (1) Fine Particle of Metal Oxide Semiconductor of the “A-1: Oxide Semiconductor Electrode of First Aspect”; accordingly, the description thereof will be omitted here.

(3) Other Compounds

The porous layer in the invention may contain, if necessary, other compounds than the fine particle of a metal oxide semiconductor. Such other compounds are similar to one described in a section of 3. Porous Layer, (2) other Compounds of the “A-1: Oxide Semiconductor Electrode of First Aspect”; accordingly, the description thereof will be omitted here.

(4) Porous Layer

A film thickness of the porous layer in the aspect is similar to one described in a section of 3. Porous Layer, (3) Porous Layer of the “A-1: Oxide Semiconductor Electrode of First Aspect”; accordingly, the description there of will be omitted here.

The porous layer of the invention is preferably patterned. This is because when the porous layer is patterned, the oxide semiconductor electrode of the invention can be made one preferable for producing a dye-sensitized solar cell high in the module electromotive force. The patterning aspect of the porous layer in the aspect is similar to one described in a section of 3. Porous Layer, (3) Porous Layer of the “A-1: Oxide Semiconductor Electrode of First Aspect”; accordingly, the description thereof will be omitted here.

2. Bonding Layer

Next, a bonding layer in the aspect will be described. The bonding layer in the invention is made of a thermoplastic resin.

(1) Thermoplastic Resin

A thermoplastic resin used in the bonding layer in the aspect is not particularly restricted, as far as it is a resin that melts at a desired temperature. In the aspect, a melting point of the thermoplastic resin is preferably in the range of 50 to 200° C.; more preferably in the range of 60 to 180° C.; and particularly preferably in the range of 65 to 10° C. When the melting point is lower than the above range, for example, when a dye-sensitized solar cell produced with the oxide semiconductor electrode of the aspect is used in the open air, the adhesion between the base material and the first electrode layer may not be sufficiently maintained. Furthermore, when the melting point is higher than the above range, for example, when a dye-sensitized solar cell is produced from the oxide semiconductor electrode according to the aspect by use of the transfer method, since a heating process higher than the melting point becomes necessary in the transfer process, depending on the kind of the base material used in the aspect, in some cases the base material itself may be thermally damaged.

Furthermore, the thermoplastic resin is preferable to be an adhesive resin. Preferable examples of such an adhesive resin include: a polyolefin such as a polyethylene, a polypropylene, a polyisobutylene, a polystyrene and an ethylene-propylene rubber; an ethylene-vinyl acetate copolymer; an ethylene-acrylic acid copolymer; a cellulose derivatives such as an ethyl cellulose and a cellulose triacetate; a polyvinyl acetal such as a copolymer of poly(meth)acrylic acid and an ester thereof, a polyvinyl acetate, a polyvinyl alcohol and a polyvinyl butyral; a polyacetal; a polyamide; a polyimide; a nylon; a polyester resin; a urethane resin; an epoxy resin; a silicone resin; and a fluororesin can be cited. Among these, from viewpoints of the adhesive properties, the resistance to an electrolytic solution, the light transparency and the transferability, a polyolefin, an ethylene-vinyl acetate copolymer, a urethane resin, an epoxy resin, a silane-modified resin and an acid-modified resin are preferable.

The following the polyolefin compound can be cited as another examples of the adhesive resin. Specifically, homopolymers of α-olefins having substantially 2 to 8 carbon atoms such as an ethylene, a propylene and a 1-butene, and copolymers between the above-mentioned α-olefins and other α-olefins having substantially 2 to 20 carbon atoms such as an ethylene, a propylene, a 1-butene, a 3-methyl-1-butene, a 1-pentene, a 4-methyl-1-pentene, a 1-hexene, a 1-octene and a 1-decene, a vinyl acetate, a (meth)acrylic acid and a (meth)acrylic acid ester, a (anhydrous) maleic acid-modified resin, a silane-modified resin, an olefinic elastomer can be cited. Examples of homopolymer or copolymer of the α-olefin include polyolefins such as (branched or linear) ethylene homopolymers such as low, medium and high density polyethylene, an ethylene-propylene copolymer, an atactic polypropylene, a propylene homopolymer and a 1-butene homopolymer; ethylene-(meth)acrylate copolymers such as an ethylene-1-butene copolymer, an ethylene-propylene-1-butene copolymer, an ethyl-4-methyl-1-pentene copolymer, an ethylene-1-hexene copolymer, an ethylene-1-octene copolymer, a propylene-1-butene copolymer, a propylene-ethylene-1-butene copolymer, an ethylene-vinyl acetate copolymer, an ethylene-(meth)acrylic acid copolymer or an ionomer thereof, and an ethylene-acrylic acid ester copolymer; (anhydrous)maleic acid-modified resins such as a maleic acid-modified ethylene-vinyl acetate copolymer resin, a maleic acid-modified polyolefin resin and an ethylene-ethyl acrylate-maleic acid anhydride ternary copolymer; and modified polyolefins such as a silane-modified resin made of a copolymer of an ethylenic unsaturated silane compound and a polyolefin compound.

As the olefinic elastomer or the like, an elastomer that has a polyethylene or a polypropylene as a hard segment and an ethylene-propylene rubber (EPR) or an ethylene-propylene-diene rubber (EPDM) as a soft segment can be cited.

The polyolefin compounds can be used singularly or in a combination of at least two species. Among the polyolefin compounds, from the viewpoint of the adhesive properties, modified polyolefins, in particular, modified ethylenic resins (for example, ethylene copolymers such as a silane-modified resin made of a copolymer of an ethylenic unsaturated silane compound and a polyolefin compound, an ethylene-vinyl acetate copolymer, and an ethylene-ethyl acrylate copolymer) are preferable. Above all, the silane-modified resin can be most preferably used as a bonding layer.

In the aspect, among the thermoplastic resins, the silane-modified resins can be preferably used. When the silane-modified resin is used, the bonding layer is assumed to form a chemical bond with the base material and the first electrode layer. Accordingly, it is considered that the adhesive force that the bonding layer shows can be more strengthened. The silane-modified resin used in the aspect is similar to one described in a section of 1. Bonding Layer, (1) Silane-modified Resin of the “A-1: Oxide Semiconductor Electrode of First Aspect”; accordingly, the description thereof will be omitted here.

(2) Other Compounds

The bonding-layer in the invention may contain, if necessary, other compounds than those mentioned above. Such other compounds are similar to one described in a section of 1. Bonding Layer, (2) Other Compounds of the “A-1: Oxide Semiconductor Electrode of First Aspect”; accordingly, the description thereof will be omitted here.

(3) Bonding Layer

A thickness of the bonding layer in the aspect is similar to one described in a section of 1. Bonding Layer, (3) Bonding Layer of the “A-1: Oxide Semiconductor Electrode of First Aspect”; accordingly, the description thereof will be omitted here.

3. First Electrode Layer

The first electrode layer used in the aspect is similar to one described in a section of 2. First Electrode Layer, of the “A-1: Oxide Semiconductor Electrode of First Aspect”; accordingly, the description thereof will be omitted here.

4. Base Material

The base material used in the aspect is similar to one described in a section of 4. Base Material, of the “A-1: Oxide Semiconductor Electrode of First Aspect”; accordingly, the description thereof will be omitted here.

5. Method of Producing Oxide Semiconductor Electrode

As a method of producing an oxide semiconductor electrode of the aspect, anyone of methods that can produce an oxide semiconductor electrode having the above configuration can be used without restriction. As such a method, normally, a transfer method where a laminated body of a porous layer and a first electrode layer is transferred through a bonding layer on the base material is used. In the aspect, as such a method, for example, a method detailed below in a section of “F. Method of Producing Oxide Semiconductor Electrode” can be preferably used.

B. Oxide Semiconductor Electrode with Heat-resistant Substrate

Next, an oxide semiconductor electrode with a heat-resistant substrate of the invention will be described. The oxide semiconductor electrode with a heat-resistant substrate of the invention includes a heat-resistant substrate on a porous Layer that the oxide semiconductor electrode of the first aspect or the oxide semiconductor electrode of the second aspect has.

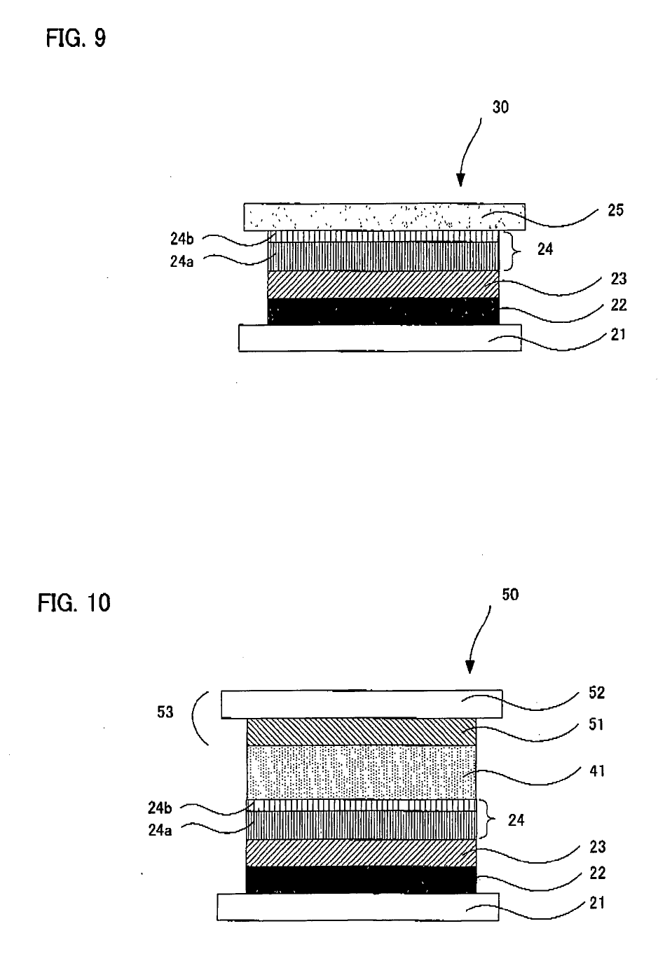

Next, the oxide semiconductor electrode with a heat-resistant substrate of the invention will be described with reference to the drawing. FIG. 9 is a schematic cross-sectional view showing an example of the oxide semiconductor electrode with a heat-resistant substrate of the invention. As shown in FIG. 9, an oxide semiconductor electrode with a heat-resistant substrate 30 of the invention has a heat-resistant substrate 25 on a porous layer 24 that an oxide semiconductor electrode 20b has.

According to the oxide semiconductor electrode with a heat-resistant substrate of the invention, since the heat-resistant substrate is disposed on the porous layer that the oxide semiconductor electrode of the first aspect or the oxide semiconductor electrode of the second aspect has, in the process of peeling a heat-resistant substrate shown in FIG. 7, by peeling the heat-resistant substrate, an oxide semiconductor electrode excellent in the adhesion between the respective layers can be readily formed.

Hereinafter, the respective configurations of the oxide semiconductor electrode with a heat-resistant substrate of the invention will be described.

1. Heat-resistant Substrate

The heat-resistant substrate used in the invention is similar to one that is described below in a section of “D. Laminated body for Oxide Semiconductor Electrode”. Accordingly, the description thereof will be omitted here.

2. Oxide Semiconductor Electrode

An oxide semiconductor electrode used in the invention, is similar to ones described in sections of the “A-1: Oxide Semiconductor Electrode of First Aspect” and “A-2: Oxide Semiconductor Electrode of Second Aspect”; accordingly, a description thereof will be omitted here

3. Oxide Semiconductor Electrode with Heat-resistant Substrate

The oxide semiconductor electrode with a heat-resistant substrate of the invention can be used to produce an electrode for a dye-sensitized light chargeable capacitor, an electrode for an electrochromic display, a contaminant decomposition substrate, a substrate for a dye-sensitized solar cell, and the like. Above all, the oxide semiconductor electrode can be preferably used to produce a base material for a dye-sensitized solar cell.

4. Method of Producing Oxide Semiconductor Electrode with Heat-resistant Substrate

As a method of producing an oxide semiconductor electrode with a heat-resistant substrate of the invention, any one of methods that can produce an oxide semiconductor electrode with a heat-resistant substrate of the invention having the above configuration can be used without restriction. As such a method, for example, a method described below in a section of “E. Method of Producing Oxide Semiconductor Electrode with Heat-resistant Substrate” can be preferably used.

C. Dye-sensitized Solar Cell

Next, a dye-sensitized solar cell of the invention will be described. In the dye-sensitized solar cell of the invention, the oxide semiconductor electrode of the first aspect or the oxide semiconductor electrode of the second aspect and a counter electrode base material made of a second electrode layer and a counter base material are disposed to face each other with an electrolyte layer containing a redox couple interposed therebetween.

The dye-sensitized solar cell of the invention will be described with reference to the drawing. FIG. 10 is a schematic cross-sectional view showing an example of a dye-sensitized solar cell of the invention. As shown in FIG. 10, in a dye-sensitized solar cell 50 of the invention, an oxide semiconductor electrode 20b, wherein a base material 21, a bonding layer 22 formed on the base material 21 and made of a thermoplastic resin, a first electrode layer 23 formed on the bonding layer 22 and made of a metal oxide, and a porous layer 24 formed on the first electrode layer 23 and containing a fine particle of a metal oxide supporting a dye sensitizer are included, is disposed to face a counter electrode base material 53 made of a second electrode layer 51 and a counter base material 52 through an electrolyte layer containing a redox couple 41.

According to the invention, when the oxide semiconductor electrode of the first aspect where the thermoplastic resin constituting the bonding layer includes a silane-modified resin is used, the adhesive force between a base material of the bonding layer and the first electrode layer can be strengthened. Accordingly, the adhesion stability that does not damage the adhesive force even when a redox couple permeates from the electrolyte layer to the bonding layer can be obtained. Thus, according to the invention, a dye-sensitized solar cell that does not cause the interlayer peeling with time or the like, and is excellent in the stability can be obtained.

Furthermore, according to the invention, when the oxide semiconductor electrode of the second aspect where the porous layer is constituted of an oxide semiconductor layer in contact with the first electrode layer and an intermediate layer formed on the oxide semiconductor layer and higher in the porosity than the oxide semiconductor layer is used, a dye-sensitized solar cell excellent in the productivity due to the transfer method can be obtained.

Still furthermore, in the first aspect and second aspect oxide semiconductor electrodes of the invention, since she bonding layer is constituted of a thermoplastic resin, the bonding layer is excellent in the flexibility and the “crack” or the like is difficult to generate in the bonding layer itself. Thus, according to the invention, a dye-sensitized solar cell resistant to the external impact can be obtained.

Hereinafter, the respective configurations of the dye-sensitized solar cell of the invention will be detailed.

1. Electrolyte Layer

First, an electrolyte layer in the invention will be described. The electrolyte layer in the invention includes a redox couple.

(1) Redox Couple

A redox couple used in the electrolyte layer in the invention is not particularly restricted, as far as it is one that is generally used in the electrolyte layer. Such a redox couple, being similar to one described below in a section of “G: Method of Producing Dye-sensitized Solar Cell”, is omitted from describing here.

(2) Other Compounds

The electrolyte layer in the invention may contain, as other compounds than the redox couple, additives such as a crosslinking agent, a photopolymerization initiator, a viscosity improver and a room-temperature fused salt.

(3) Electrolyte Layer

The electrolyte layer may be an electrolyte layer in any one state of gel-like, solid or liquid state. When the electrolyte layer is made gel-like, anyone of a physical gel and a chemical gel may be used. The physical gel is one that forms a gel according to a physical interaction in the proximity of room temperature, and the chemical gel is one that forms a gel due to a chemical bond by a crosslinking reaction or the like.

Furthermore, when the electrolyte layer is liquid, one that contains a redox couple with for example acetonitrile, methoxyacetonitrile or propylene carbonate can be rendered as a solvent, or, similarly, with an ionic liquid where an imidazolium salt is a cation can be rendered as a solvent.

Still furthermore, when the electrolyte layer is in a solid state, it may be one that does not contain a redox couple and works as a hole transferring agent by itself. For example, it may be a hole transferring agent containing CuI, polypyrrole or polythiophene.

2. Counter Electrode Base Material

Next, a counter electrode base material in the invention will be described. The counter electrode base material in the invention is made of a second electrode layer and a counter base material.

(1) Second Electrode Layer

A second electrode layer in the invention is similar to one described in a section of 2. First Electrode Layer in the “A-1: Oxide Semiconductor Electrode of First Aspect”; accordingly, a description thereof will be omitted here.

(2) Counter Base Material

A counter base material in the invention is similar to one described in a section of 4. Base material in the “A-1; Oxide Semiconductor Electrode of First Aspect”; accordingly, a description thereof will be omitted here.

(3) Other Layers

The counter electrode base material in the invention, if necessary, may contain other layers than the above. As the other layers used in the invention, a catalyst layer can be cited. In the invention, when the catalyst layer is formed on the second electrode layer, a dye-sensitized solar cell of the invention can be made one more excellent in the electricity generation efficiency. As an example of such a catalyst layer, an aspect where Pt is deposited on the second electrode layer can be cited. However, the catalyst layer is not restricted to the above.

3. Oxide Semiconductor Electrode

An oxide semiconductor electrode in the invention, being similar to one described in a section of the “A-1: Oxide Semiconductor Electrode of First Aspect”, is omitted from describing here.

4. Method of Producing Dye-sensitized Solar Cell

As a method of producing a dye-sensitized solar cell of the invention, any one of methods that can produce a dye-sensitized solar cell having the above-mentioned configuration can be used without restriction. As such a method, for example, a method detailed below in a section of “G. Method of Producing Dye-sensitized Solar Cell” can be preferably used.

D. Method of Producing Laminated Body for Oxide Semiconductor Electrode

Firstly, a method of producing a laminated body for an oxide semiconductor electrode of the invention will be described. The method of producing a laminated body for an oxide semiconductor electrode of the invention includes the processes of: a process of forming an intermediate layer-forming pattern, wherein, to a heat-resistant substrate in pattern, an intermediate layer-forming coating material containing an organic material and the fine particle of a metal oxide semiconductor is applied, and set to form an intermediate layer-forming pattern; a process of forming an oxide semiconductor layer-forming layer, wherein, to the heat-resistant substrate and the intermediate layer-forming pattern, an oxide semiconductor layer-forming coating material higher in a concentration in a solid content of the fine particle of a metal oxide semiconductor than that of the intermediate layer-forming coating material is applied, and set to form an oxide semiconductor layer-forming layer; a sintering process, wherein the intermediate layer-forming pattern and the oxide semiconductor layer-forming layer are sintered to form a porous intermediate layer and a porous oxide semiconductor layer; and a process of forming a first electrode layer, wherein a first electrode layer is formed on the oxide semiconductor layer.

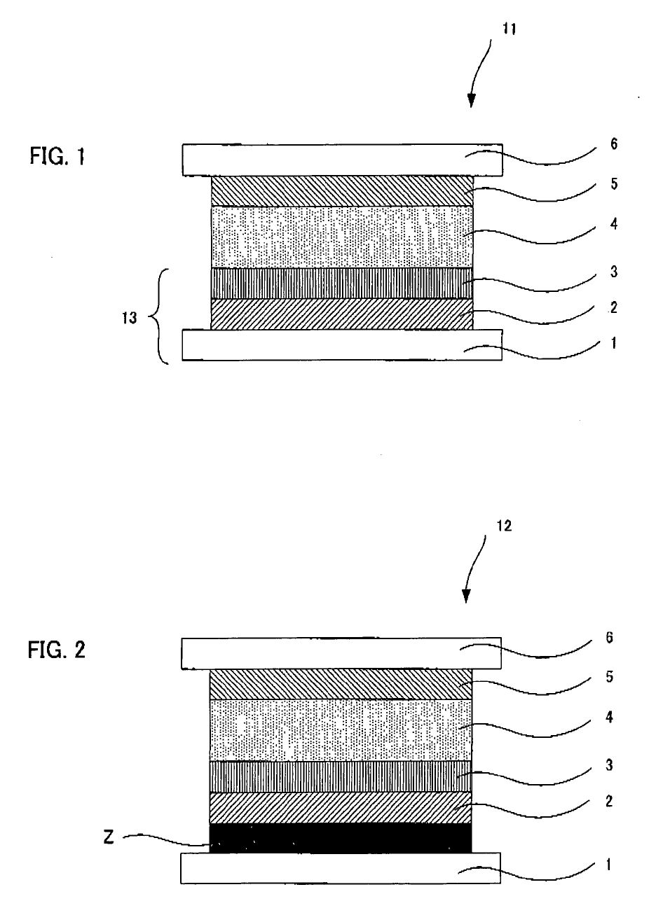

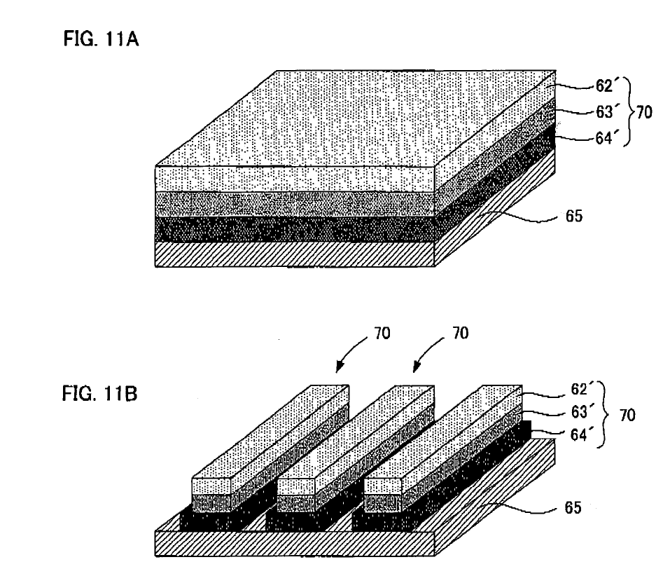

According to the invention, a laminated body for an oxide semiconductor electrode with an intermediate layer formed in pattern can be formed. By using the laminated body for an oxide semiconductor electrode, an oxide semiconductor electrode where an intermediate layer and an oxide semiconductor layer are patterned on a first electrode layer can be obtained. In an oxide semiconductor electrode where an intermediate layer and an oxide semiconductor layer are not patterned, as shown for example in FIG. 1A, on an entire surface of a first electrode layer 64′, an oxide semiconductor layer 63′ is formed and an intermediate layer 62′ is further formed on the oxide semiconductor layer 63′. Since only one cell 70 made of a first electrode layer 64′, an oxide semiconductor layer 63′ and an intermediate layer 62′ is formed on a base material 65, in a device that uses such an oxide semiconductor electrode, in some cases, practical output current and output voltage are difficult to obtain. On the other hand, when an oxide semiconductor electrode is produced with a laminated body for an oxide semiconductor electrode obtained of the invention, for example as shown in FIG. 11B, an oxide semiconductor electrode where the oxide semiconductor layer 63′ and the intermediate layer 62′ are patterned and that is provided with a first electrode pattern 64′ formed corresponding to the pattern shape and having a larger surface area than the pattern can be formed. Since a plurality of cells 70, each of which is made of the first electrode pattern 64′, the oxide semiconductor layer 63′ and the intermediate layer 62′, can be formed on the base material 65, the cells can be connected in parallel to improve the output current or in series to improve the output voltage.

Furthermore, as a conventional method of producing an oxide semiconductor electrode, there is a method where, an oxide semiconductor layer is formed on a heat-resistant substrate through an organic membrane made of an organic material that does not contain the fine particle of a metal oxide semiconductor. However, in the above method, there is a problem in that after the sintering, owing to the difference of the thermal expansion coefficients of the organic material contained in the organic membrane and the fine particle of a metal oxide semiconductor contained in the oxide semiconductor, the crack tends to be caused between the organic membrane and the oxide semiconductor layer. On the other hand, when an oxide semiconductor layer is formed directly on a heat-resistant substrate without involving the organic membrane, there is a problem in that the adhesion between both is too strong so that peeling the heat-resistant substrate off from the oxide semiconductor layer becomes difficult. According to the invention, by forming an intermediate layer between the heat-resistant substrate and the oxide semiconductor layer with an intermediate layer-forming coating material containing the fine particle of a metal oxide semiconductor, the crack due to the difference of the thermal expansion coefficients can be suppressed from occurring.

Furthermore, by forming an intermediate layer with an intermediate layer-forming coating material where a concentration of the fine particle of a metal oxide semiconductor is lower than that of an oxide semiconductor layer-forming coating material described below, appropriate adhesion and the peelability can be imparted between the heat-resistant substrate and the intermediate layer. Accordingly, oxide semiconductor electrodes can be produced at high yield from laminated bodies for an oxide semiconductor electrode obtained of the invention. Furthermore, in the laminated body for an oxide semiconductor electrode obtained of the invention, the adhesion between the intermediate layer and the heat-resistant substrate, and the adhesion between the oxide semiconductor layer and the heat-resistant layer are different. Accordingly, by use of the difference of the adhesions, an oxide semiconductor electrode where the oxide semiconductor layer and the intermediate layer ace patterned can be obtained. Such a method of producing an oxide semiconductor electrode will be detailed below in “F. Method of Producing Oxide Semiconductor Electrode”.

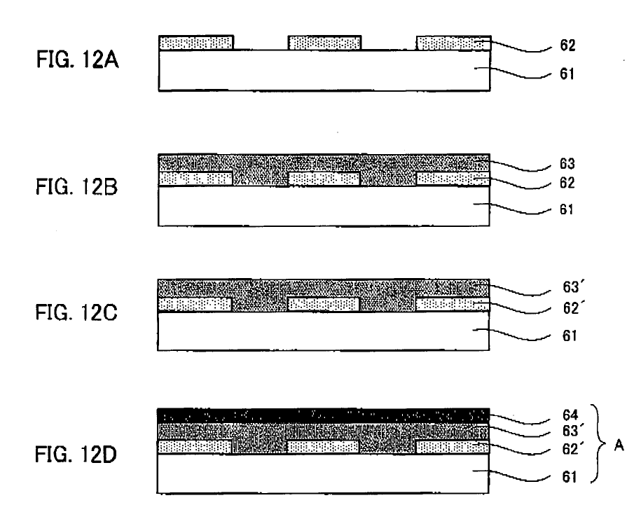

Next, a method of producing a laminated body for an oxide semiconductor electrode of the invention will be specifically described with reference to the drawing. FIGS. 12A to 12D are processing drawings showing an example of a method of producing the laminated body for an oxide semiconductor electrode of the invention.

Firstly, as shown in FIG. 12A, on a heat-resistant substrate 61, an intermediate layer-forming coating material is coated in pattern, and followed by setting the coating to form an intermediate layer-forming pattern 62 (an intermediate layer-forming process).

Next, as shown in FIG. 12B, on the heat-resistant substrate 61 and the intermediate layer-forming pattern 62, an oxide semiconductor layer-forming coating material is coated, and followed by setting the coating to form an oxide semiconductor layer-forming layer 63 (an oxide semiconductor layer-forming layer-forming process).

Next, the heat-resistant substrate 61 on which an intermediate layer-forming pattern 62 and an oxide semiconductor layer-forming layer 63 are layered is subjected to heating and sintering to form, as shown in FIG. 12C, an intermediate layer 62′ and an oxide semiconductor layer 63′ that form a porous body having a continuous pore (sintering process).

Next, as shown in FIG. 12D, a first electrode layer 64 is formed on the oxide semiconductor layer 63′ (a first electrode layer forming process), and thereby a laminated body for an oxide semiconductor electrode A is obtained.

Hereinafter, a method of producing a laminated body for an oxide semiconductor electrode of the invention will be described of each of the respective processes.

1. Process of Forming Intermediate Layer-forming Pattern

First, a process of forming an intermediate layer-forming pattern in the invention will be described. The process of forming an intermediate layer-forming pattern in the invention is a process, wherein an intermediate layer-forming coating material containing an organic material and the fine particle of a metal oxide semiconductor is coated on a heat-resistant substrate in pattern, and followed by setting the coating to form an intermediate layer-forming pattern.

The intermediate layer-forming pattern means one that is formed by applying an intermediate layer-forming coating material in pattern, and setting the coating to form. Furthermore, an intermediate layer described below means one that is formed as a porous body by sintering the intermediate-forming pattern. Still furthermore, when a laminated body for an oxide semiconductor electrode obtained by the method of producing thereof of the invention is used in a dye-sensitized solar cell, the intermediate layer means both of one where a dye sensitizer is supported by a process of supporting a dye sensitizer described below and one that does not support a dye sensitizer.

(1) Intermediate Layer-forming Coating Material

First, an intermediate layer-forming coating material used in the process will be described. The intermediate layer-forming coating material used in the process contains at least the fine particle of a metal oxide semiconductor and an organic material.

(a) Fine Particle of Metal Oxide Semiconductor

Fine particle of a metal oxide semiconductor used in the process work so as to conduct charges when the intermediate layer-forming pattern is finally converted into an intermediate layer. When the fine particle of a metal oxide semiconductor are added to an intermediate layer-forming coating material, the crack owing to the difference of the thermal expansion coefficients can be inhibited from occurring.

A content of the fine particle of a metal oxide semiconductor in a solid content of the intermediate layer-forming coating material is not particularly restricted, as far as it is within a range smaller than a content of the fine particle of a metal oxide semiconductor in a solid content in an oxide semiconductor layer-forming coating material to be described later. In the aspect, the content of the fine particle of a metal oxide semiconductor is, in a solid content of the intermediate layer-forming coating material, preferably in the range of 20 to 80 mass percent, and particularly preferably in the range of 30 to 70 mass percent.

Furthermore, a concentration in an intermediate layer-forming coating material of the fine particle of a metal oxide semiconductor can be arbitrarily determined, depending on a method of applying an intermediate layer-forming coating material described below or the like, as far as it is in a range that can form an intermediate layer-forming pattern excellent in the planarity. Normally, the concentration is preferably in the range of 0.01 to 30 mass percent, and more preferably in the range of 0.1 to 15 mass percent.

The fine particle of a metal oxide semiconductor used in the invention, being similar to one described in a section of the “A. Oxide Semiconductor Electrode”, is omitted from describing here.

(b) Organic Material

Next, an organic material used in the intermediate layer-forming coating material will be described. An organic material used in the intermediate layer-forming coating material is not particularly restricted as far as it can be readily decomposed in a sintering process described below. In the process, a synthetic resin is preferably used as the organic material. As a synthetic resin, by arbitrarily selecting a molecular weight and a material, a compound that is provided with desired pyrolyzability can be obtained. Accordingly, there are advantages in that restrictions on the conditions of a sintering process described below can be lessened.

As the synthetic resin, as far as it is one that is dissolved with difficulty in a solvent used in an oxide semiconductor layer-forming coating material described later, there is no particular restriction. In the process, a weight-average molecular weight of a synthetic resin is preferably in the range of 2000 to 600000; more particularly in the range of 5000 to 300000; and most preferably in the range of 10000 to 200000. When the molecular weight of the synthetic resin is larger than the above range, in some cases, the pyrolysis in a sintering process described below becomes insufficient. On the other hand, when the molecular weight is smaller than the above range, the viscosity of the intermediate layer-forming coating material is lowered, and thereby the fine particle of a metal oxide semiconductor may coagulate.

Specific examples of the synthetic resin used in the process include: cellulose-based resins such as an ethyl cellulose, a methyl cellulose, a nitrocellulose, an acetyl cellulose, an acetylethyl cellulose, a cellulose propionate, a hydroxypropyl cellulose, a butyl cellulose, a benzyl cellulose and a nitrocellulose; acrylic resins made of polymers or copolymers such as a methyl methacrylate, an ethyl methacrylate, a tert-butyl methacrylate, an n-butyl methacrylate, an isobutyl methacrylate, an isopropyl methacrylate, a 2-ethyl methacrylate, a 2-ethylhexyl methacrylate and a 2-hydroxyethyl methacrylate; and polyalcohols such as a polyethylene glycol. In the process, the synthetic resins may be used singularly or in a combination of at least two species.

A concentration of the synthetic resin to the intermediate layer-forming coating material is, though not particularly restricted, preferably in the range of 0.01 to 30 mass percent and, particularly preferably in the range of 0.1 to 15 mass percent.

(c) Solvent

The intermediate layer-forming coating material used in the process may be a coating material that does not contain a solvent or a coating material that contains a solvent. When a solvent is contained in the intermediate layer-forming coating material, the solvent is preferably a good solvent to an organic material used. The solvent used in the process is appropriately selected by mainly considering the volatility of the solvent and the solubility of the organic material used. Specifically, ketones, hydrocarbons, esters, alcohols, haloganated hydrocarbons, glycol derivatives, ethers, ether esters, amides, acetates, ketone esters, glycol ethers, sulfones and sulfoxides can be cited. These car be used singularly or in a combination of at least two species. Above all, organic solvents such as an acetone, a methyl ethyl ketone, toluene, a methanol, an isopropyl alcohol, an n-propyl alcohol, an n-buthanol, an isobutanol, a terpineol, an ethyl cellosolve, a butyl cellosolve and a butyl carbitol are preferable. It is because the intermediate layer-forming coating material, by using the organic solvent to coat on a heat-resistant substrate, can be applied to the heat-resistant substrate with excellent wettability.

(d) Additive

Furthermore, in the process, in order to improve the coating aptitude of the intermediate layer-forming coating material, various additives may be used. As the additive, for example, a surfactant, a viscosity adjustor, a dispersing aid, a pH adjustor, and the like can be used. As the pH adjustor, for example, a nitric acid, a hydrochloric acid, an acetic acid, a dimethylformamide and an ammonia can be cited. Furthermore, as the dispersing aid, polymers such as a polyethylene glycol, a hydroxyethyl cellulose and a carboxymethyl cellulose; surfactants; acids; and chelates can be cited.

(2) Heat-resistant Substrate

As the heat-resistant substrate used in the process there is no particular restriction, as far as it has the heat-resistance to a heating temperature during a sintering process described below. As such heat-resistant substrates, a heat-resistant substrate made of a glass, ceramic, metal plate or the like can be cited. Among the above, in the process, as the heat-resistant substrate, a flexible metal plate can be preferably used. It is because, by using such a heat-resistant substrate, a sintering process described below can be carried out at sufficiently high temperatures, and thereby the bindability between the fine particles of a metal oxide semiconductor can be heightened. Furthermore, the heat-resistant substrate is preferably a reusable one.

A film thickness of the heat-resistant substrate, though different depending on a material of the heat-resistant substrate, is for example in the range of 10 μm to 1 mm; more preferably in the range of 50 to 500 μm; and particularly preferably in the range of 80 to 300 μm.

Furthermore, the heat-resistant substrate is preferably flexible one. It is because an oxide semiconductor electrode and the like can be produced by means of a roll-to-roll method.

Still furthermore, the heat-resistant substrate preferably has the acid resistance. The “acid resistance” in the invention means the acid resistance to an extent that, when an intermediate layer-forming coating material described below or an oxide semiconductor layer-forming coating material described below is acidic, is not corroded by the composition; alternatively, the acid resistance to an extent that, even when the heat-resistant substrate is a little corroded, an acid decomposition product thereof does not cause the modification or the peeling and the like of the intermediate layer, the oxide semiconductor layer and the like.

Furthermore, a material of the heat-resistant substrate having such acid resistance is not particularly restricted. For example, metals such as a simple substance metal, a metal alloy and a metal oxide can be cited. As the simple substance metals, for example, Ti, W, Mo, Nb, Cr, Ni, Ag, Zr, Pt, Ta and Au can be cited; above all Ti, W, Pt and Au are preferable. As the metal alloys, for example, SUS, a Ti alloy, a Fe alloy, a Ni alloy, an Al alloy, a W alloy, a Mg alloy, a Co alloy and a Cr alloy can be cited; above all, SUS, a Ti alloy and an Al alloy are preferable. As the metal oxides, for example, a Si oxide, an Al oxide, a Ti oxide, a Zr oxide, a Sn oxide, a Cr oxide and a W oxide can be cited; above all, a Si oxide, an Al oxide and a Ti oxide are preferable.

Furthermore, the heat-resistant substrate having the acid resistance may be a single layer or a plurality of layers. As a specific example when the heat-resistant substrate having the acid resistance is formed of a plurality of layers, for example, one where the heat-resistant substrate has a heat-resistant Layer and an acid resistant layer formed on at least one surface of the heat-resistant layer can be cited. In this case, normally, on the acid resistant layer, an intermediate layer-forming coating material or the like is applied.

The heat-resistant layer is used together with an acid-resistant layer described below. Accordingly, the heat-resistant layer itself is not necessarily acid-resistant, and an arbitrary material can be used, as far as it has sufficient heat resistance. As such materials of the heat-resistant layer, for example, metal, glass and ceramics can be cited, and above all, the metal is preferable. Furthermore, as the metal, specifically, simple substance metals, metal alloys and metal oxides can be cited. As the simple substance metals, metal alloys and metal oxides, normally have sufficient heat resistance, the species thereof or the like are not particularly restricted. As the simple substance metals, specifically, Ti, W, Pt, Au, and the like are preferable. As the metal alloys, specifically, SUS, a Ti alloy, an Al alloy, and the like are preferable. As the metal oxides, specifically, Si oxide, Al oxide, Ti oxide, and the like are preferable.

Furthermore, a film thickness of the heat-resistant layer is, though not particularly restricted, for example in the range of 10 μm to 10 mm; more preferably in the range of 50 μm to 5 mm;, and particularly preferably in the range of 83 μm to 2 mm.

On the other hand, the acid-resistant layer is formed on at least one surface of the heat-resistant layer. Such a material of the acid-resistant layer is not particularly restricted and the material similar to that of “material of heat-resistant substrate with acid resistance” described above can be used. Furthermore, as a film thickness of the acid-resistant layer is, though not particularly restricted, for example in the range of 10 μm to 10 mm; more preferably in the range of 50 μm to 5 mm; and particularly preferably in the range of 80 μm to 2 mm.

Furthermore, a combination of the heat-resistant layer and the acid-resistant layer can be arbitrarily selected, without restricting to particular one. For example, a combination where a material of the heat-resistant layer is metal, glass or ceramics and a material of the acid-resistant layer is metal can be cited. Above all, a combination where materials of the beat-resistant layer and the acid-resistant layer are metals is preferable.

As a combination where materials of the heat-resistant layer and the acid-resistant layer are metals, for example, a combination where the material of the heat-resistant layer is a simple metal substance, a metal alloy or a metal oxide and the material of the acid-resistant layer is a simple metal substance, a metal alloy or a metal oxide other than the metals used in the heat-resistant layer can be cited. Specifically, as a combination of a material of the heat-resistant layer/a material of the acid-resistant layer, Ti simple substance/Ti oxide, SUS/Cr simple substance, SUS/Si oxide, SUS/Ti oxide, SUS/Al oxide, SUS/Cr oxide, and the like can be cited.

Furthermore, when materials of the heat-resistant layer and the acid-resistant layer are metals, a metal element contained in the heat-resistant layer and a metal element contained in the acid-resistant layer are preferably different. Mere, “a metal element contained in the heat-resistant layer” means a metal element contained most abundantly in the heat-resistant layer. Accordingly, even when SUS contains such as Cr and Ni, “a metal element contained in the heat-resistant layer” is Fe. Furthermore, “a metal element contained in the acid-resistant layer” is similarly defined. As a combination of the heat-resistant layer and the acid-resistant layer, SUS/Cr simple substance, SUS/Si oxide, SUS/Ti oxide, SUS/Al oxide, SUS/Cr oxide, and the like can be cited as a combination of a material of the heat-resistant layer/a material of the acid-resistant layer.

A method of forming an acid-resistant layer on a heat-resistant layer is not restricted to particular one. For example, dry deposition methods such as PVD methods of a vacuum deposition method, a sputtering method, an ion plating method and the like, CVD methods of a plasma CVD method, a thermal CVD method, an atmospheric pressure CVD method and the like, and wet deposition methods of a plating method, a sol/gel method and the like can be cited. Furthermore, when, for example, a metal simple substance or a metal alloy is used in the heat-resistant layer, on a surface thereof, a chemical conversion treatment such as an alumite treatment, a chromate treatment or a manganese phosphate film treatment is applied, and a layer obtained according to the chemical conversion treatment may be used as an acid-resistant layer. Furthermore, a spray thermal decomposition method or the like may be used.

Furthermore, the heat-resistant substrate used in the process is preferably provided with a wettability-variable layer of which wettability can be varied under the action of a photocatalyst accompanying energy irradiation. This is because an intermediate layer-forming pattern can be formed with precision along the wettability-varying pattern. Specifically, a method where energy is applied to the wettability-variable layer to form a wettability-varying pattern in which a particular portion is rendered a hydrophilic area, and, along the wettability-varying pattern, an intermediate layer-forming pattern is formed, and the like can be cited. When the heat-resistant substrate is provided with the wettability-variable layer, before the process of forming the intermediate layer-forming pattern, energy is preferably applied to the wettability-varying pattern to form a wettability-varying pattern.

Furthermore, a configuration of the wettability-variable layer is not particularly restricted as far as the wettability thereof can be varied under the action of a catalyst accompanying energy irradiation. For example: one where a wettability-variable layer has a photocatalyst and a characteristics-variable material of which characteristics are varied under the action of the photocatalyst accompanying energy irradiation; one where the wettability-variable layer has a photocatalyst-containing layer that contains at least a photocatalyst and a characteristics-variable layer formed on the photocatalyst-containing layer and contains the characteristics-variable material; or one where the wettability-variable layer is a characteristics-variable layer that does not contain the photocatalyst and contains the characteristics-variable material, and a photocatalyst-containing layer separately formed and containing the photocatalyst is disposed to face the wettability-variable layer in the proximity thereof, under the action of the photocatalyst in the photocatalyst-containing layer, a wettability-varying pattern is formed in the wettability-variable layer, can be cited. As to the photocatalyst and the characteristics-variable material, ones shown for example in JP-A Nos. 2001-074928, 2003-209339 and 2003-222626 can be used.

(3) Method of Forming Intermediate Layer-forming Pattern

In the process, as a method of coating the intermediate layer-forming coating material in pattern on the heat-resistant substrate, there is no particular restriction as far as it can obtain a desired intermediate layer-forming pattern. For example, a method where by using a known coating method to apply an intermediate layer-forming coating material to an entire surface of the heat-resistant substrate, an intermediate layer-forming layer is formed on the heat-resistant substrate; followed by masking the intermediate layer-forming layer so as to form a desired pattern; further followed by removing an area that is not masked with a solvent that can dissolve the intermediate layer-forming layer, can be cited. Examples of such a known method include die coating, gravure coating, gravure reverse coating, roll coating, reverse roll coating, bar coating, blade coating, knife coating, air knife coating, slot die coating, slide die coating, dip coating, microbar coating, microbar reverse coating, and screen printing (rotary type). Furthermore, as the solvents that can dissolve the intermediate layer-forming layer, for example, solvents that are used in the intermediate layer-forming coating material can be cited.

Still furthermore, as another method of coating the intermediate layer-forming coating material in pattern on the heat-resistant substrate, for example, a method where a surface of a heat-resistant substrate is masked, followed by applying the coating material to an entire surface of the heat-resistant substrate and the masking by use of a known applying method to further remove the masking can be cited. A known coating method is same as that mentioned above. Furthermore, as still another method of applying the intermediate layer-forming coating material in pattern on the heat-resistant substrate, a method where an intermediate layer-forming pattern is directly formed by use of, for example, a die coating method or a gravure coating method can be cited. This is a method to form an intermediate layer-forming pattern without applying the masking and is industrially excellent. Moreover, when the heat-resistant substrate has the wettability-variable layer and is provided in advance with a wettability-varying pattern, by coating the coating material to an entire surface by a known coating method, an intermediate layer-forming pattern can be formed along the wettability-varying pattern.

(4) Intermediate Layer-forming Pattern

A shape of the intermediate layer-forming pattern obtained by the process can be arbitrarily determined depending on the application or the like of a laminated body for an oxide semiconductor electrode obtained by a method of producing the same in the invention. In the invention, specifically, a rectangular shape, a square shape, a circular shape, an elliptical shape, a trapezoidal shape or a decorative figure, a character, a drawing, a mark, or the like can be cited. Among these, from a viewpoint of an improvement in the current collection efficiency, a rectangular shape is preferable.

Furthermore, in particular, when the intermediate layer-forming pattern is formed into a rectangular shape, a line width of the intermediate layer-forming pattern is preferably in the range of 5 to 150 mm; and particularly preferably in the range of 8 to 100 mm. This is because when the line width exceeds the above range, the resistance loss by the first electrode layer increases to be likely to lower the current collection efficiency; and, when the line width is less than the range, the mechanical strength may not be sufficiently secured. Moreover, a gap between the intermediate layer-forming patterns is in the range of 0.1 to 100 mm, and preferably in the range of 1 to 50 mm. This is because, when the gap exceeds the range, a module may be rendered larger in the area; and, when it is less than the range, it is difficult to obtain the intermediate layer-forming pattern with precision.

A film thickness of the intermediate layer-forming pattern obtained by the process is not particularly restricted. However, a film thickness is preferably adjusted and determined, when the intermediate layer-forming pattern is formed as a porous body in a sintering process described below, so as to be a film thickness described in “3. Sintering Process” described below. Specifically, the film thickness is in the range of 0.01 to 50 μm, and preferably in the range of 0.01 to 30 μm.

2. Process of Forming Oxide Semiconductor Layer-forming Layer

Next, a process of forming an oxide semiconductor layer-forming layer will be described. The process of forming an oxide semiconductor layer-forming layer in the invention is a process, wherein an oxide semiconductor layer-forming coating material in which a concentration in a solid content of the fine particle of a metal oxide semiconductor is higher than that of the intermediate layer-forming coating material is applied, on the heat-resistant substrate and the intermediate layer-forming pattern, and set to form an oxide semiconductor layer-forming layer.

The oxide semiconductor layer-forming layer here means one that is formed by applying an oxide semiconductor layer-forming coating material and setting the coating. Furthermore, when a laminated body for an oxide semiconductor electrode obtained by a producing method of the invention is used in a dye-sensitized solar cell, the oxide semiconductor layer means both that one supports a dye sensitizer according to a process of supporting a dye sensitizer described below and one that does not support a dye sensitizer.

(1) Oxide Semiconductor Layer-forming Coating Material

An oxide semiconductor layer-forming coating material used in the process will be described. An oxide semiconductor layer-forming coating material used in the process contains at least the fine particle of a metal oxide semiconductor and a resin, wherein a concentration of the fine particle of a metal oxide semiconductor in a solid content is controlled higher than that of the intermediate layer-forming coating material.

(a) Fine Particle of Metal Oxide Semiconductor

Fine particle of a metal oxide semiconductor used in the process works to conduct charge when the oxide semiconductor layer-forming layer finally became an oxide semiconductor layer.

A concentration of the fine particle of a metal oxide semiconductor in a solid content in the oxide semiconductor layer-forming coating material is not particularly restricted as far as the concentration thereof is higher than that of the intermediate layer-forming coating material. Normally, it is preferably in the range of 50 to 100 mass percent, and particularly preferably in the range of 65 to 90 mass percent. For example, when a laminated body for an oxide semiconductor electrode obtained by a producing method of the invention is used in a dye-sensitized solar cell, by using such an oxide semiconductor layer-forming coating material, in an oxide semiconductor layer formed as a porous body obtained after a sintering process, a sufficient amount of a dye sensitizer can be supported on a pore surface thereof. Accordingly, in a finally obtained oxide semiconductor layer, a function of conducting charges generated from the dye sensitizer under the photoirradiation can be sufficiently obtained.

Furthermore, a concentration of the fine particle of a metal oxide semiconductor in an oxide semiconductor layer-forming coating material is, though differing depending on a method of coating or the like, specifically in the range of 5 to 50 mass percent and preferably in the range of 10 to 40 mass percent. This is because, when such an oxide semiconductor layer-forming coating material is used, an oxide semiconductor layer-forming layer can be formed at a desired film thickness with precision.

Still furthermore, particle diameters of the fine particle of a metal oxide semiconductor are, though not particularly restricted, specifically, in the range of 1 nm to 10 μm, and, preferably in the range of 10 nm to 1000 nm. When the particle diameter is smaller than the range, such fine particles are difficult to produce and in some cases the respective particles coagulate to unfavorably form secondary particles. On the other hand, when the particle diameter is larger than the range, a surface area of the oxide semiconductor layer decreases. Accordingly, when a laminated body for an oxide semiconductor electrode obtained by a producing method of the invention is used to produce a dye-sensitized solar cell, a dye-supporting amount in the oxide semiconductor layer decreases and thereby the performance may be deteriorated.

Furthermore, fine particles of same kind or a different kind of metal oxide semiconductor, which have particle diameters that are in the above range and different from each other, may be mixed and used. Thereby, the light scattering effect can be heightened and more light can be confined in a finally obtained oxide semiconductor layer. Accordingly, light can be efficiently absorbed with the dye sensitizer. For example, a case where fine particles of a metal oxide semiconductor in the range of 10 to 50 nm and fine particles of a metal oxide semiconductor in the range of 50 to 800 nm are mixed to use can be cited.

Furthermore, since such fine particle of a metal oxide semiconductor are similar to that described in the “1. Process of Forming Intermediate Layer-forming Pattern”, a description thereof will be omitted here.

(b) Resin

A resin used in the process is used to generate pores to a porous body by a sintering process described below. Furthermore, when an amount of resin used is varied, the viscosity of an oxide semiconductor layer-forming coating material can be controlled.

A concentration of the resin to an oxide semiconductor layer-forming coating material is, though not particularly restricted, normally preferably in the range of 0.1 to 30 mass percent;, more preferably in the range of 0.5 to 20 mass percent; and most preferably in the range of 1 to 10 mass percent.

Examples of such a resin include a cellulose based resin, a polyester based resin, a polyamide based resin, a polyacrylic acid ester based resin, a polycarbonate based resin, a polyurethane resin, a polyolefin based resin, a polyvinyl acetal based resin, a fluororesin based resin, and a polyimide resin, and polyhydric alcohols such as a polyethylene glycol.

(c) Solvent

An oxide semiconductor layer-forming coating material used in the process may be a coating material that does not contain a solvent or a coating material that contains a solvent. When a solvent is used in the oxide semiconductor layer-forming coating material, there is no particular restriction, as far as the resin can be dissolved and an organic material used to form the intermediate layer-forming pattern is difficult to dissolve. A variety of solvents maybe used such as water, a methanol, an ethanol, an isopropyl alcohol, a propylene glycol monomethyl ether, a terpineol, a dichloromethane, an acetone, an acetonitrile, an ethyl acetate, and a tert-butyl alcohol. In particular, water or an alcoholic solvent is preferred. This is because since water or an alcoholic solvent is immiscible with an organic solvent used in the intermediate layer-forming coating material, the intermediate layer-forming pattern and the oxide semiconductor layer-forming layer can be inhibited from mixing.

(d) Additives

Furthermore, in the process, in order to improve the coating aptitude of the oxide semiconductor layer-forming coating material, various kinds of additives may be added. For example, as the additives, a surfactant, a viscosity adjustor, a dispersing aid, a pH adjuster and the like can be used. Since these are similar to that used in the “1. Process of Producing Intermediate Layer-forming Pattern”, descriptions thereof will be omitted here. Moreover, in the process, in particular, a polyethylene glycol is preferably used as a dispersing aid. This is because by varying a molecular weight of polyethylene glycol, the viscosity of a dispersion liquid can be controlled, and thereby an oxide semiconductor layer that is difficult to peel can be formed and the porosity of the oxide semiconductor layer and the like can be controlled.

(2) Method of Forming Oxide Semiconductor Layer-forming Layer

In this process, any known method of application may be used for the application of the oxide semiconductor layer-forming coating material on the intermediate layer-forming pattern. Examples of such a method include die coating, gravure coating, gravure reverse coating, roll coating, reverse roll coating, bar coating, blade coating, knife coating, air knife coating, slot die coating, slide die coating, dip coating, microbar coating, microbar reverse coating, and screen printing (rotary type).

(3) Oxide Semiconductor Layer-forming Layer

A film thickness of an oxide semiconductor layer-forming layer obtained by the process is preferably controlled and determined to be, when a porous body is formed in a sintering process described below, a film thickness described in “3. Sintering Process” described below. Specifically, the film thickness is in the range of 1 to 65 μm and preferably in the range of 5 to 30 μm. The film thickness of the oxide semiconductor layer-forming layer here means a distance from an upper end of the intermediate layer-forming pattern formed on the heat-resistant substrate to an upper end of the oxide semiconductor layer formed on the heat-resistant substrate and the intermediate layer-forming pattern.

3. Sintering Process

Next, a sintering process in the invention will be described. A sintering process in the invention is a process where the intermediate layer-forming pattern and the oxide semiconductor layer-forming layer are sintered to render a porous body and thereby an intermediate layer and an oxide semiconductor layer are formed. According to the process, the intermediate layer and the oxide semiconductor layer that are formed as a porous body having continuous pores can be formed.

In the process, a sintering temperature is not restricted to particular one, as far as it is within a range where an organic material and a resin contained in the intermediate layer-forming pattern and the oxide semiconductor layer-forming layer can be pyrolyzed. Normally, the sintering temperature is preferably in the range of 300 to 700° C. and particularly preferably in the range of 350 to 600° C.

Furthermore, in the process, a method of heating when the intermediate layer-forming pattern and the oxide semiconductor layer-forming layer are sintered is not restricted to particular one, as far as the intermediate layer-forming pattern and the oxide semiconductor layer-forming layer can be uniformly sintered without the heating irregularity. Specifically, a known heating method can be used.

The total thickness of the intermediate membrane and the oxide semiconductor membrane formed as porous bodies in this process is preferably In the range of 1 to 100 μm, more preferably in the range of 5 to 30 μm. This is because by setting a film thickness in the above range, after the sintering process, an oxide semiconductor layer difficult to cause the peeling and the crack and high in the mechanical strength can be obtained.

The ratio of the thickness of the oxide semiconductor layer to that of the intermediate layer is preferably in the range of 10:0.1 to 10;5, more preferably in the range of 10:0.1 to 10:3. In the invention, the higher the concentration in a solid content of the fine particle of a metal oxide semiconductor, the lower the porosity and the stronger the mechanical strength can be provided. Accordingly, when a ratio of the film thicknesses is set in the above range, while maintaining excellent adhesion to and the peelability off the heat-resistant substrate, the mechanical strength can be strengthened.

4. Process of Forming First Electrode Layer

Next, a process of forming a first electrode layer in the invention will be described. A process of forming a first electrode layer in the invention is a process where a first electrode layer is formed on the oxide semiconductor layer. The first electrode layer obtained by the process becomes, after a first electrode pattern-forming process described below, a first electrode pattern.

In the process, a method of disposing a first electrode layer on the oxide semiconductor layer is not restricted to particular one, as far as it can form a first electrode layer excellent in the conductivity. For example, dry deposition methods such as PVD methods of a vacuum deposition method, a sputtering method, an ion plating method and the like, of CVD methods such as a plasma CVD method, a thermal CVD method, an atmospheric pressure CVD method and the like; a solution spray method and a spraying method can be cited. Among these, a solution spray method and a spray method are preferable because a dense first electrode layer can be formed.

Hereinafter, a solution spray method and a spray method in the process will be detailed.

(1) Solution Spray Method

In a solution spray method in the process: a solution process where a first electrode undercoat layer-forming coating material, in which a metal salt or a metal complex having a metal element constituting a first electrode layer is dissolved, is brought into contact with the oxide semiconductor layer to dispose a first electrode undercoat layer inside or on a surface of the oxide semiconductor layer; and a spray process where a first electrode upper layer is disposed on the first electrode undercoat layer, are carried out to dispose a first electrode layer on an oxide semiconductor layer.

In the solution spray method by firstly using a first electrode undercoat layer-forming coating material in the solution process, the first electrode undercoat layer-forming coating material can be permeated into the inside of the oxide semiconductor layer that is a porous body to dispose a first electrode undercoat layer inside of the oxide semiconductor layer. Thereafter, in the spray process, a first electrode upper layer is disposed on the first electrode undercoat layer to obtain a dense first electrode layer. In the spray method, the first electrode layer indicates the first electrode undercoat layer and the first electrode upper layer.

Hereinafter, the solution process and the spray process in the solution spray method will be described.

(a) Solution Process

The solution process in the solution spray method is a process where a first electrode undercoat layer-forming coating material, in which a metal salt or a metal complex having a metal element constituting a first electrode layer is dissolved, is brought into contact with the oxide semiconductor layer to dispose a first electrode undercoat layer inside or on a surface of the oxide semiconductor layer.

(i) First Electrode Undercoat Layer-forming Coating Material

Firstly, a first electrode undercoat layer-forming coating material used in the solution process will be described. In a first electrode undercoat layer-forming coating material used in the solution process, at least a metal salt or a metal complex (hereinafter, in some cases, referred to as a metal source) having a metal element constituting a first electrode layer is dissolved in a solvent. Furthermore, the first electrode undercoat layer-forming coating material preferably contains at least one of an oxidizing agent and a reducing agent. This is because under the action of the oxidizing agent and/or reducing agent, a circumstance where a first electrode undercoat layer is readily formed can be obtained.

(Metal Source)

The metal source used for first electrode undercoat layer-forming coating material may be any of a metal salt and a metal complex, as long as it contains a metal element for forming the first electrode layer and can form the first electrode undercoat layer. In the invention, the “metal complex” includes coordination compounds, in which an inorganic or organic matter(s) coordinates a metal ion(s) and so called organometallic compounds having a metal-carbon bond in their molecule.

A metal element constituting a metal source used in the first electrode undercoat layer-forming coating material is not restricted to particular one, as far as it can obtain a first electrode layer excellent in the conductivity. For example, at least one kind of metal element selected from a group consisting of Mg, Al, Si, Ti, V, Mn, Fe, Co, Ni, Cu, Zn, Y, Zr, Ag, In, Sn, Ce, Sm, Pb, La, Hf, Sc, Gd and Ta can be cited. Among these, at least one kind of metal element selected from a group consisting of Zn, Zr, Al, Y, Fe, Ga, La, Sb, In and Sn is preferable.

Example of the metal salt including the metal element may be a metal element-containing chloride, nitrate, sulfate, perchlorate, acetate, phosphate, or bromate. In the invention, a chloride, a nitrate and an acetate are more preferably used, because these compounds are easily available as general purpose products.

Examples of the metal complex include a magnesium diethoxide, an aluminum acetylacetonate, a calcium acetylacetonate dihydrate, a calcium di(methoxyethoxide), a calcium gluconate monohydrate, a calcium citrate tetrahydrate, a calcium salicylate dihydrate, a titanium lactate, a titanium acetylacetonate, a tetraisopropyl titanate, a tetra(n-butyl)titanate, a tetra(2-ethylhexyl) titanate, a butyl titanate dimer, a titanium bis(ethylhexoxy)bis(2-ethyl-3-hydroxyhexoxide), a diisopropoxytitanium bis(triethanolaminate), a dihydroxybis(ammonium lactate)titanium, a diisopropoxytitanium bis(ethylacetoacetate), a titanium peroxo citrate ammonium tetrahydrate, a dicyclopentadienyl iron(II), an iron(II)lactate trihydrate, an iron(III) acetylacetonate, a cobalt(II)acetylacetonate, a nickel(II)acetylacetonate dihydrate, a copper(II)acetylacetonate, a copper(II)dipivaloylmethanate, a copper(II)ethylacetoacetate, a zinc acetylacetonate, a zinc lactate trihydrate, a zinc salicylate trihydrate, a zinc stearate, a strontium dipivaloylmethanate, a yttrium dipivaloylmethanate, a zirconium tetra(n-butoxide), a zirconium(IV)ethoxide, a zirconium n-propylate, a zirconium n-butylate, a zirconium tetraacetylacetonate, a zirconium monoacetylacetonate, a zirconium acetylacetonate bis(ethylacetoacetate), a zirconium acetate, a zirconium monostearate, a penta(n-butoxy)niobium, a pentaethoxyniobium, a pentaisopropoxyniobium, an indium(III)tris(acetylacetonate), an indium(III)2-ethylhexanoate, a tetraethyltin, a dibutyltin(IV)oxide, a tricyclohexyltin(IV)hydroxide, a lanthanum acetylacetonate dihydrate, a tri(methoxyethoxy)lanthanum, a pentaisopropoxytantalum, a pentaethoxytantalum, a tantalum(V)ethoxide, a cerium(III)acetylacetonate n(hydrate), a lead(II)citrate trihydrate, and a lead cyclohexanebutyrate. In the solution process, preferably used are a magnesium diethoxide, an aluminum acetylacetonate, a calcium acetylacetonate dihydrate, a titanium lactate, a titanium acetylacetonate, a tetraisopropyl titanate, a tetra(n-butyl)titanate, a tetra(2-ethylhexyl)titanate, a butyl titanate dimer, a diisopropoxytitanium bis(ethylacetoacetate), an iron(II) lactate trihydrate, an iron(III)acetylacetonate, a zinc acetylacetonate, a zinc lactate trihydrate, a strontium dipivaloylmethanate, a pentaethoxyniobium, an indium(III)tris(acetylacetonate), an indium(III)2-ethylhexanoate, a tetraethyltin, a dibutyltin(IV)oxide, a lanthanum acetylacetonate dihydrate, a tri(methoxyethoxy)lanthanum, and a cerium(III)acetylacetonate n(hydrate).

While the concentration of the metal source is not limited as long as it allows the production of the desired first electrode undercoat layer, it is generally from 0.001 to 1 mol/l, preferably from 0.01 to 0.1 mol/l in the case of the metal salt, and generally from 0.001 to 1 mol/l, preferably from 0.01 to 0.1 mol/l in the case of the metal complex.

(Oxidizing Agent)

The oxidizing agent used in the first electrode undercoat layer-forming coating material has the function of promoting the oxidation of the metal ion or the like derived from the dissolved metal source. An environment where the first electrode undercoat layer can easily develop can be created by changing the valence of the metal ion or the like.

While the concentration of the oxidizing agent is not limited as long as it allows the production of the desired first electrode undercoat layer, it is generally from 0.001 to 1 mol/1, preferably from 0.01 to 0.1 mol/l. If the concentration is lower than the above range, the oxidizing agent can have no effect. Concentrations higher than the above range are not preferred in view of costs because of no significant increase in the effect.

Any oxidizing agent soluble in the solvent as shown below and capable of promoting the oxidation of the metal ion or the like maybe used. Examples of such an oxidizing agent include a hydrogen peroxide, a sodium nitrite, a potassium nitrite, a sodium bromate, a potassium bromate, a silver oxide, a dichromic acid, and a potassium permanganate. In particular, a hydrogen peroxide and a sodium nitrite are preferably used.

(Reducing Agent)

The reducing agent used in the first electrode undercoat layer-forming coating material serves to release electrons in a decomposition reaction, to produce hydroxide ions by electrolysis of water, and to raise the pH of the first electrode undercoat layer-forming coating material. If the pH of the first electrode undercoat layer-forming coating material is raised, an environment where the first electrode undercoat layer can easily develop can be creamed.

While the concentration of the reducing agent is not limited as long as it allows the production of the desired first electrode undercoat layer, it is generally from 0.001 to 1 mol/l, preferably from 0.01 to 0.1 mol/l in the case where the metal source is a metal salt; and generally from 0.001 to 1 mol/l, preferably from 0.01 to 0.1 mol/l in the case where the metal source is a metal complex. If the concentration is lower than the above range, the reducing agent can have no effect. Concentrations higher than the above range are not preferred in view of costs because of no significant increase in the effect.

Any reducing agent soluble in the solvent as shown below and capable of releasing electrons in a decomposition reaction may be used. Examples of such a reducing agent include a borane complex such as a borane-tert-butylamine complex, a borane-N,N-diethylaniline complex, a borane-dimethylamine complex, and a borane-trimethylamine complex, sodium cyanoborohydride, and sodium borohydride. In particular, the borane complex is preferably used.

The first electrode undercoat layer-forming coating material used in the solution process may contain the reducing agent and the oxidizing agent. Examples of such a combination of the reducing agent and the oxidizing agent include, but are not limited to, a combination of hydrogen peroxide or sodium nitrite and any reducing agent and a combination of any oxidizing agent and a borane complex. A combination of hydrogen peroxide and a borane complex is more preferred.

(Solvents)

Any solvent in which the metal salt or the Like is soluble may be used in the first electrode undercoat layer-forming coating material. When the metal source is a metal salt, the solvent may be water, a lower alcohol with at most five total carbon atoms such as a methanol, an ethanol, an isopropyl alcohol, a propanol, and a butanol, a toluene, or any mixture thereof. When the metal source is a metal complex, the solvent maybe the above lower alcohol, a toluene, or a mixture thereof.

(Additives)

The first electrode undercoat layer-forming coating material may contain an additive such as an auxiliary ion source and a surfactant.

The auxiliary ion source reacts with electrons to produce hydroxide ions, and thus it can raise the pH of the first electrode undercoat layer-forming coating material and can create an environment where the first electrode undercoat layer can easily be formed. The auxiliary ion source is preferably used in an amount properly selected depending on the metal salt or the reducing agent for use.

For example, the auxiliary ion source may be an ion species selected from the group consisting of a chlorate ion, a perchlorate ion, a chlorite ion, a hypochlorite ion, a bromate ion, a hypobromate ion, a nitrate ion, and a nitrite ion.

The surfactant acts on the interface of the porous body surface of the first electrode undercoat layer-forming coating material and the oxide semiconductor layer to facilitate the production of the metal oxide film (first electrode undercoat layer) on the porous body surface. The surfactant is preferably used in an amount properly selected depending on the metal salt and the reducing agent or use.

Examples of the surfactant include Surfynol series such as Surfynol 485, Surfynol SE, Surfynol SE-F, Surfynol 504, Surfynol GA, Surfynol 104A, Surfynol 104BC, Surfynol 104PPM, Surfynol 104E, and Surfynol 104PA (each manufactured by Nisshin Chemicals Co., Ltd.) and NIKKOL AM301 and NIKKOL AM313ON (each manufactured by Nikko Chemicals Co., Ltd.).

(iii) Method of Bringing First Electrode Undercoat Layer-Forming Coating Material Into Contact With Oxide Semiconductor Layer

Next, a method of bringing the first electrode undercoat layer-forming coating material into contact with the oxide semiconductor layer will be explained. Any method may be used to bring the first electrode undercoat layer-forming coating material into contact with the oxide semiconductor layer. Examples of the contact method include a dipping method, a sheet-feed method, and a method to coat the solution in spray form.

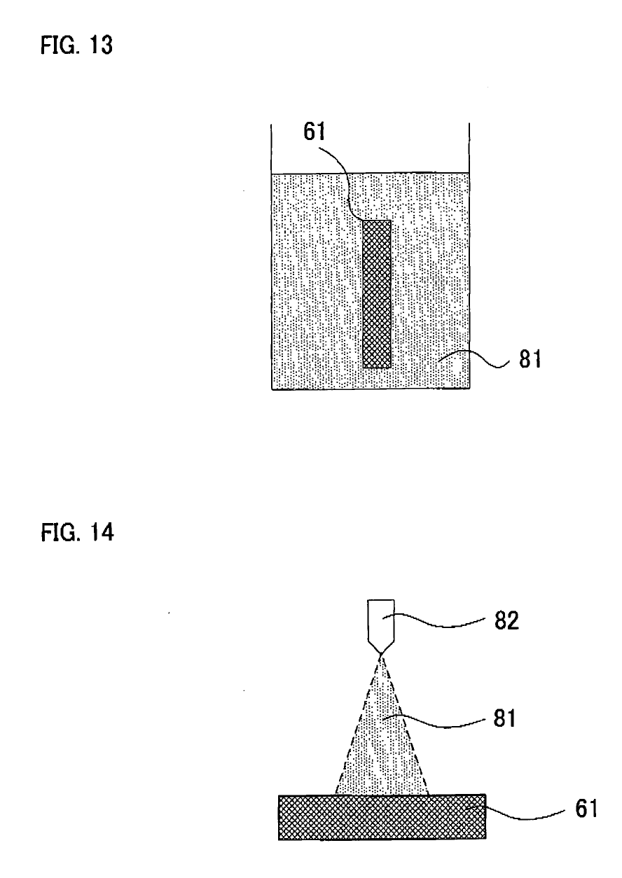

For example, the dipping method includes dipping, in the first electrode undercoat layer-forming coating material, the heat-resistant substrate with the oxide semiconductor layer so that the first electrode undercoat layer is formed in the inside of or on the surface of the oxide semiconductor layer. As shown in FIG. 13, for example, the heat-resistant substrate 61 with the oxide semiconductor layer or the like is dipped in the first electrode undercoat layer-forming coating material 81 when the first electrode undercoat layer is produced.

In the solution process, heating is preferably performed when the oxide semiconductor layer is allowed to contact the first electrode undercoat layer-forming coating material. Heating can enhance the activity of the oxidizing agent and the reducing agent and can increase the rate of formation of the first electrode undercoat layer. While any method may be used in heating, heating the oxide semiconductor layer is preferred and heating the oxide semiconductor layer and the first electrode undercoat layer-forming coating material is more preferred, because the reaction to form the first electrode undercoat layer can be facilitated in the vicinity of the oxide semiconductor layer.

Such heating is preferably performed at a temperature properly selected depending on the feature of the oxidizing agent, the reducing agent or the like. For example, the heating temperature is preferably in the range of 50 to 150° C., more preferably in the range of 70 to 100° C.

(iii) First Electrode Undercoat Layer

Next, a first electrode undercoat layer formed in the solution process will be described. A first electrode undercoat layer disposed inside of an oxide semiconductor layer by a method described below is not restricted to particular ones as far as it can obtain a first electrode layer having desired denseness by a spray method applied after that. For example, the first electrode undercoat layer may be a film that is present from the inside of the oxide semiconductor layer to a surface thereof and completely covers the oxide semiconductor layer or one that partially covers a surface of the oxide semiconductor layer. As a specific example of the first electrode undercoat layer that partially covers a surface of the oxide semiconductor layer, for example, a case where the first electrode undercoat layer is present sea island-like inside of the oxide semiconductor layer that is a porous body can be cited. Furthermore, in a solution spray method used in the process, after the solution process, a spray process described below is applied. Since a first electrode undercoat layer can be obtained inside or on a surface of the oxide semiconductor layer that is a porous body by the above-mentioned solution process, irrespective of a spray method described below, a dense first electrode layer can be obtained even when a known layer-forming method is used.

(b) Spray Process

A spray process in the solution spray method is a process, wherein a first electrode upper layer is disposed by a spray method on a first electrode undercoat layer formed by the solution process. Hereinafter, the spray process will be described.

The spray method is a process of forming the first electrode upper layer, which includes: heating the first electrode undercoat layer at a temperature equal to or higher than a first electrode upper layer-forming temperature; and bringing the undercoat layer into contact with the first electrode upper layer-forming coating material, which contains a dissolved metal salt or metal complex with a metal element for forming the first electrode layer, in order to form the first electrode upper layer on the undercoat layer.

In the spray method, the “first electrode upper layer-forming temperature” is a temperature at which the metal element contained in the first electrode upper layer-forming coating material, described below, can combine with oxygen to form a metal oxide film, which serves as the first electrode upper layer or the like. Such a temperature can significantly vary with the type of the metal ion or the like derived from the dissolved metal source, the composition of the first electrode upper layer-forming coating material and the like. In the spray method, the first electrode upper layer-forming temperature may be determined by the following method. A first electrode upper layer-forming coating material is experimentally prepared in which the desired metal source is dissolved. The coating material is then brought into contact with the heat-resistant substrate having the first electrode undercoat layer, while the heating temperature is changed. In this process, a lowest heating temperature is determined at which a metal oxide film serving as the first electrode upper layer is formed. The lowest heating temperature is defined as the “first electrode upper layer-forming temperature” in the spray method. In this process, whether or not the metal oxide film is formed is generally determined from the result of measurement with an X-ray diffractometer (RINT-1500 manufactured by Rigaku Corporation), and any amorphous film with no crystallinity is generally determined from the result of measurement with a photoelectron spectrometer (ESCALAB 200i-XL manufactured by V. G. Scientific).

In the spray method, while the first electrode undercoat layer is heated to a temperature equal to or higher than the first electrode upper layer-forming temperature, the undercoat layer is brought into contact with the first electrode upper layer-forming coating material to form the first electrode upper layer on the undercoat layer, so that a dense first electrode layer can be formed on the porous oxide semiconductor layer.

(i) First Electrode Upper Layer-Forming Coating Material

A description is first provided of the first electrode upper layer-forming coating material for use in the spray method. The first electrode upper layer-forming coating material comprises a solvent, in which the metal salt or the metal complex having a metal element for forming the first electrode layer is dissolved.

The first electrode upper layer-forming coating material preferably contains at least one of an oxidizing agent and a reducing agent. At least one of the oxidizing agent and the reducing agent can reduce the heating temperature at which the first electrode upper layer is formed.

(Metal Source)

The metal source for use in the first electrode upper layer-forming coating material has a metal element(s) for forming the first electrode layer. Any of a metal salt and a metal complex may be used to form the first electrode upper layer. While the type of the metal source may be the same as the metal salt of the fist electrode undercoat layer-forming coating material in the solution treatment, a metal source capable of forming a conductive transparent first electrode upper layer is more preferred, because the first electrode upper layer acts as a collecting electrode. Examples of the metal oxide for forming the conductive transparent first electrode upper layer include, but are not limited to, ITO, ZnO, FTO (fluorine-doped tin oxide), ATO (antimony-doped tin oxide), and SnO2 (TO). In the case of ITO, the metal source for forming such a metal oxide may be a tris(acetylacetonato)indium(III), an indium(III)2-ethylhexanoate, a tetraethyltin, a dibutyltin(IV)oxide, or a tricyclohexyltin(IV)hydroxide. In the case of ZnO, the metal source may be a zinc acetylacetonate, a zinc lactate trihydrate, a zinc salicylate trihydrate, or a zinc stearate. In the case of FTO, the metal source may be a tetraethyltin, a dibutyltin(IV)oxide, or a tricyclohexyltin(IV)hydroxide. The fluorine doping agent may be an ammonium fluoride or the like. In the case of ATO, the metal source may be an antimony(III)butoxide, an antimony(III)ethoxide, a tetraethyltin, a dibutyltin(IV)oxide, or a tricyclohexyltin(IV)hydroxide. In the case of SnO2(TO), the metal source may be a tetraethyltin, a dibutyltin(IV)oxide, or a tricyclohexyltin(IV)hydroxide.

The metal source for use in the first electrode upper layer-forming coating material is not limited as long as it can form the desired first electrode layer, and it may be the same as or different from the metal source for use in the first electrode undercoat layer-forming coating material. The combination of the first electrode upper layer and the first electrode undercoat layer is described later in the section “(iii) First Electrode Upper Layer,” and thus its description is not repeated here.

While the concentration of the metal source in the first electrode upper layer-forming coating material is not limited as long as it allows the production of the desired first electrode upper layer, it is generally from 0.001 to 1 mol/l, preferably from 0.01 to 0.5 mol/l in the case where the metal source is a metal salt; and generally from 0.001 to 1 mol/l, preferably from 0.01 to 0.5 mol/l in the case where the metal source is a metal complex. If the concentration is lower than the above range, it can take a long time to form the first electrode upper layer. If the concentration is higher than the above range, the resulting first electrode upper layer could be uneven in thickness.

(Others)

Furthermore, since an oxidizing agent, a reducing agent, a solvent, an additive and the like used in a first electrode layer-forming coating material are similar to that described in the solution process in the content, descriptions will be omitted here.

(ii) Method of Bringing First Electrode Upper Layer-Forming Coating Material Into Contact With First Electrode Undercoat Layer

A description is provided of the method of bringing the first electrode upper layer-forming coating material into contact with the first electrode undercoat layer according to the spray method. While any technique may be used to bring the first electrode undercoat layer into contact with the first electrode upper layer-forming coating material in the spray method, a contact method is preferably used in which a decrease in the temperature of the heated first electrode undercoat layer is prevented when the first electrode undercoat layer is brought into contact with the first electrode upper layer-forming coating material. This is because if the temperature of the first electrode undercoat layer is lowered, the first electrode layer could be formed in an undesired manner.

Examples of the method in which temperature decrease is prevented include, but are not limited to, a method of spraying droplets of the first electrode upper layer-forming coating material in bringing the first electrode undercoat layer into contact; and a method of allowing the first electrode undercoat layer to pass through a space containing a mist of the first electrode upper layer-forming coating material.

For example, the method of spraying the first electrode upper layer-forming coating material for contact may be a method of spraying it with a spray device or the like. Referring to FIG. 14, for example, such a method includes: heating the heat-resistant substrate 61 with the first electrode undercoat layer and so on to a temperature equal to or higher than the first electrode upper layer-forming temperature; and spraying the first electrode upper layer-forming coating material 81 from a spray device 82 to the substrate 61 to form the first electrode upper layer.

The droplets sprayed from the spray device generally have diameters of 0.1 to 1000 μm, preferably of 0.5 to 300 μm. If the diameters of the droplets are in the above range, temperature decrease can be suppressed so that a uniform first electrode upper layer can be formed. The spraying gas for the spray device may be air, a nitrogen, an argon, a helium, an oxygen, or the like. The spray rate of the spraying gas may be from 0.1 to 50 l/min, preferably from 1 to 20 l/min.

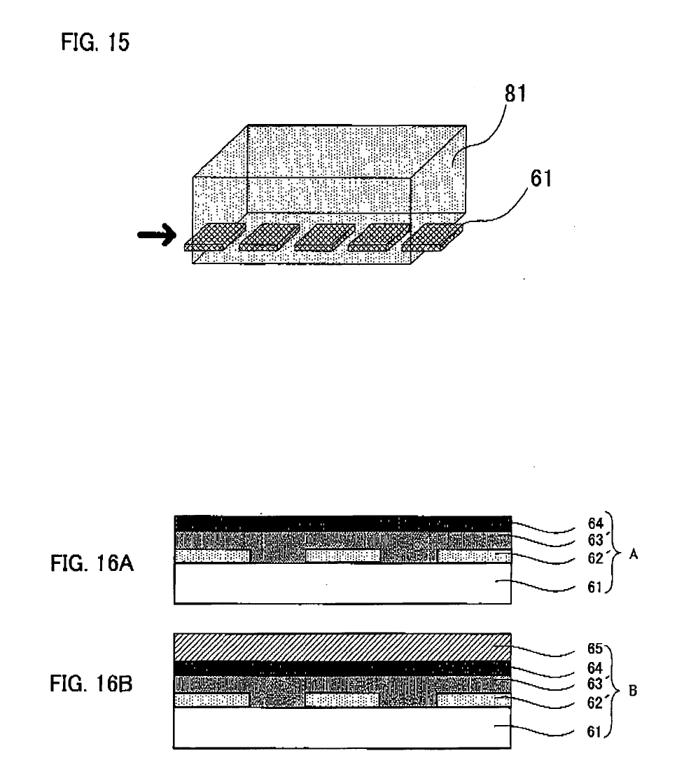

Referring to FIG. 15, the method of allowing the first electrode undercoat layer to pass through a space containing a mist of the first electrode upper layer-forming coating material may include: heating the substrate 61 having the first electrode undercoat layer or the like to a temperature equal to or higher than the first electrode upper layer-forming temperature; and allowing the heated substrate 61 to pass through a space containing a mist of the first electrode upper layer-forming coating material 81 to form the first electrode upper layer. In this method, the droplets generally have diameters of 0.1 to 300 μm, preferably of 1 to 100 μm. If the diameters of the droplets are in the above range, temperature decrease can be suppressed so that a uniform first electrode upper layer can be formed.

In the spray method, the first electrode undercoat layer is heated to a temperature equal to or higher than the “first electrode upper layer-forming temperature,” when the first electrode upper layer-forming coating material is brought into contact with the heated first electrode undercoat layer. While the “first electrode upper layer-forming temperature” can significantly vary with the type of the metal ion or the like derived from the dissolved metal source, the composition of the first electrode upper layer-forming coating material and the like, it is generally in the range of 400 to 600° C., preferably in the range of 450 to 550° C., in the case where the first electrode upper layer-forming coating material does not contain the oxidizing agent and/or the reducing agent. On the other hand, it is generally in the range of 150 to 600° C., preferably in the range of 250 to 400° C., in the case where the first electrode upper layer-forming coating material contains the oxidizing agent and/or the reducing agent. It is preferably in the range of 300 to 500° C., more preferably in the range of 350 to 450° C. in the case where an ITO film is formed as the first electrode layer by the spray method.

Any heating method may be used, for example, including hot plate heating, oven heating, sintering furnace heating, infrared lamp heating, and hot air blower heating. It is more preferred that in the heating method, the first electrode undercoat layer is brought into contact with the first electrode upper layer-forming coating material while kept at the above-mentioned temperature. Specifically, it is preferable to heat from a back side of the heat resistant substrate by using a hot plate.

(iii) First Electrode Upper Layer

A description is provided of the first electrode upper layer formed by the spray method. In the spray method, the first electrode upper layer is formed on the first electrode undercoat layer by heating the first electrode undercoat layer at a temperature equal to or higher than the first electrode upper layer-forming temperature and bringing the undercoat layer into contact with the first electrode upper layer-forming coating material, which contains a dissolved metal salt or metal complex with a metal element for forming the first electrode layer.

In the Invention, while the combination of the metal oxide of the first electrode undercoat layer and the metal oxide of the first electrode upper layer is not limited as long as it can form the first electrode layer with the desired denseness. A combination of the metal oxides having crystal systems close to each other is preferred, and a combination of the metal oxides sharing a common metal element is more preferred.

For example, with an ITO film for the first electrode upper layer, the first electrode undercoat layer may be any material that allows the formation of a dense ITO film for the first electrode upper layer. Examples of such a material include ZnO, ZrO₂, Al₂O₃, Y₂O₃, Fe₂O₃, Ga₂O₃, La₂O₃, Sb₂O₃, ITO, In₂O₃, and SnO₂. Al₂O₃, Y₂O₃, Fe₂O₃, Ga₂O₃, La₂O₃, Sb₂O₃, ITO, In₂O₃, and SnO₂ are preferred because their crystal system is close to that of the ITO film. ITO, In₂O₃ and SnO₂ are more preferred because they share a common metal element (In, Sn) with the metal oxide film (ITO film).

A film thickness of the first electrode layer formed in the process is not particularly restricted as far as it can exert excellent conductivity. Specifically, the film thickness thereof is in the range of 5 to 2000 nm and more preferably in the range of 10 to 1000 nm.

(2) Spray Method

Next, a spray method in the process will be described. In a spray method in the process, the oxide semiconductor layer is heated to a temperature equal to or higher than a first electrode layer-forming temperature to bring into contact with a first electrode layer-forming coating material, where a metal salt or a metal complex having a metal element constituting the first electrode layer is dissolved, and thereby a first electrode layer is disposed on the oxide semiconductor layer.

The spray method is a method where, in the solution spray method, the solution process is not carried out and a first electrode layer is directly disposed on the oxide semiconductor layer. Since the solution process is not applied, a first electrode layer can be formed by a convenient method on an oxide semiconductor layer that is a porous body. The spray method in the process is similar to the spray method used in the spray process of the solution spray method; accordingly, a description thereof will be omitted here. A first electrode layer-forming temperature of the spray method in the process can be obtained similarly to a first electrode upper layer-forming temperature in the spray method of the solution spray method.

A film thickness of the first electrode layer formed in the process is not particularly restricted as far as it can exert excellent conductivity. Specifically, the film thickness thereof is in the range of 5 to 2000 nm and more preferably in the range of 10 to 1000 nm.

5. Others

In a method of producing a laminated body for an oxide semiconductor electrode of the invention, after the first electrode layer-forming process, a first electrode pattern-forming process where a first electrode layer is formed in pattern to form a first electrode pattern may be applied. The first electrode pattern-forming process will be detailed in “G. Method of Producing Dye-sensitized Solar Cell” described below. Furthermore, in the invention, even one where he first electrode layer is a first electrode pattern can be called as a laminated body for an oxide semiconductor electrode. The situations are similar to an oxide semiconductor electrode with a heat-resistant substrate described below, an oxide semiconductor electrode and a base material pair for a dye-sensitized solar cell.

6. Laminated Body for Oxide Semiconductor Electrode

Next, a laminated body for an oxide semiconductor electrode obtained by the invention will be described. A laminated body for an oxide semiconductor electrode obtained by the invention, as shown in FIG. 12D for example, includes a heat-resistant substrate 61, an intermediate layer 62′ formed on the heat-resistant substrate 61, an oxide semiconductor layer 63′ formed on the heat-resistant substrate 61 and the intermediate layer 62′, and a first electrode layer 64 formed on the oxide semiconductor layer 63′. The respective configurations of the laminated body for an oxide semiconductor electrode obtained by the invention are same as that described in the above-mentioned X respective processes; accordingly, descriptions thereof will be omitted here.

The laminated body for an oxide semiconductor electrode obtained by a method of producing of the invention can be preferably used to prepare such as an electrode for a dye-sensitized light chargeable capacitor, an electrode for an electrochromic display, a contaminant decomposition substrate and a base material for a dye-sensitized solar cell, and, above all preferably, can be used to prepare a base material for a dye-sensitized solar cell.

E. Method of Producing Oxide Semiconductor Electrode with Heat-resistant Substrate Next, a method of producing an oxide semiconductor electrode with a heat-resistant substrate of the invention will be described. As a method of producing an oxide semiconductor electrode with a heat-resistant substrate, two aspects below can be cited.

That is, these are an aspect (first aspect) that includes the process of disposing a base material on a first 121. electrode layer of a Laminated body for an oxide semiconductor electrode obtained by a method of producing the laminated body for an oxide semiconductor electrode to form a base material, and an aspect (second aspect) comprising the processes of: applying, to a heat-resistant substrate, an intermediate layer-forming coating material that contains an organic material and the fine particle of a metal oxide semiconductor in pattern and setting the coating to form an intermediate layer-forming pattern; applying, to the heat-resistant substrate and the intermediate layer-forming pattern, an oxide semiconductor layer-forming coating material whose solids have a higher concentration of the fine particle of a metal oxide semiconductor than that of the fine particle in the solids of the intermediate layer-forming coating material and setting the coating to form an oxide semiconductor layer-forming layer; sintering the intermediate layer-forming pattern and the oxide semiconductor layer-forming layer to form a porous intermediate layer and a porous oxide semiconductor layer, wherein the processes are carried out to form an oxide semiconductor substrate, the oxide semiconductor layer and the first electrode layer are superposed by using the oxide semiconductor substrate and an electrode base material provided with a base material and a first electrode layer.

According to the invention, when an oxide semiconductor electrode with a heat-resistant substrate obtained by the producing method is used in, for example, a dye-sensitized solar cell, a dye-sensitized solar cell excellent in the energy conversion efficiency can be obtained.

Hereinafter, the first and second aspects will be detailed.

1. First Aspect

A method of producing an oxide semiconductor electrode with a heat-resistant substrate of the aspect includes the process of disposing a base material on a first electrode layer of a laminated body for an oxide semiconductor electrode obtained by the method of producing a laminated body for an oxide semiconductor electrode to form a base material.

In a method of producing an oxide semiconductor electrode with a heat-resistant substrate of the aspect, as shown in FIGS. 16A and 16B, on a first electrode layer 64 of a laminated body for an oxide semiconductor electrode A (FIG. 16A) obtained by the method of producing a laminated body for an oxide semiconductor electrode, a base material 65 is disposed to form an oxide semiconductor electrode with a heat-resistant substrate B (FIG. 16B).

Hereinafter, a process of forming a base material in the aspect will be detailed.

(1) Laminated Body for Oxide Semiconductor Electrode

First, a laminated body for an oxide semiconductor electrode that is used in the process will be described. The respective configurations of the laminated body for an oxide semiconductor electrode used in the process are same as that described in the “D. Method of Producing Laminated body for Oxide Semiconductor Electrode”; accordingly, descriptions thereof will be omitted here.

(2) Base Material

A base material that can be used in the process is same as that described in a section of the “A-1. Oxide Semiconductor Electrode of First Aspect”; accordingly, a description thereof will be omitted here.

Furthermore, a base material used in the aspect may have a bonding layer to improve the adhesion with the first electrode layer. A material constituting such a bonding layer is not restricted to particular one, as far as it can improve the adhesion between the base material and the first electrode layer. Specifically, a thermoplastic resin, a thermosetting resin, a UV-curable resin, an EB-curable resin and the like can be cited, and, among these, the thermoplastic resin is preferable. This is because the thermoplastic resin is excellent in the adhesion with the first electrode layer, difficult to cause the peeling and the crack, high in the resistance to a redox ion used in an electrolyte and a solvent, and excellent in the resistance. A thermoplastic resin used in the aspect is same as that described in a section of the “A-2: Oxide Semiconductor Electrode of Second Aspect”; accordingly, a description thereof will be omitted here.

In the process, among the above-mentioned thermoplastic resins, a silane-modified resin is preferably used. This is because when the silane-modified thermoplastic resin is used, the adhesive force that the bonding layer shows can be further strengthened.

The silane-modified resin used in the process is not particularly restricted as far as it has the above-mentioned melting point. As such a silane-modified resin, ones described in a section of the “A-1: Oxide Semiconductor Electrode of First Aspect” can be preferably used.

In the bonding layer in the process, if necessary, other compounds than the silane-modified resin can be contained. As such other compounds, ones described in a section of the “A-1: Oxide Semiconductor Electrode of First Aspect” can be preferably used,

(3) Method of Forming Base material

Next, a method of forming a base material on a first electrode layer of the laminated body for an oxide semiconductor electrode will be described. As a method of forming a base material on the first electrode layer there is no particular restriction, as far as it is a method that can form a base material on the first electrode layer with good adhesion. For example, a method of heat-sealing the first electrode layer of the laminated body of an oxide semiconductor electrode and the base material can be cited. Any heating method for heat-sealing may be used. For example, a method with a heat bar, a method with a lamp, a method with a laser, an electromagnetic induction heating method, and an ultrasonic friction heating method can be cited. Among them, a method using a laser is preferred. In this method, a solid-state laser (YAG laser), a semiconductor laser or the like may be used as a laser to be used.

2. Second Aspect

A method of producing an oxide semiconductor electrode with a heat-resistant substrate of the aspect comprises the processes of: applying, to a heat-resistant substrate, an intermediate layer-forming coating material that contains an organic material and the fine particle of a metal oxide semiconductor in pattern and setting the coating to form an intermediate layer-forming pattern; applying, to the heat-resistant substrate and the intermediate layer-forming pattern, an oxide semiconductor layer-forming coating material whose solids have a higher concentration of the fine particle of a metal oxide semiconductor than that of the fine particle in the solids of the intermediate layer-forming coating material and setting the coating to form an oxide semiconductor layer-forming layer; sintering the intermediate layer-forming pattern and the oxide semiconductor layer-forming layer to form a porous intermediate layer and a porous oxide semiconductor layer,

wherein the processes are carried out to form an oxide semiconductor substrate, the oxide semiconductor layer and the first electrode layer are superposed by using the oxide semiconductor substrate and an electrode base material provided with a base material and a first electrode layer.

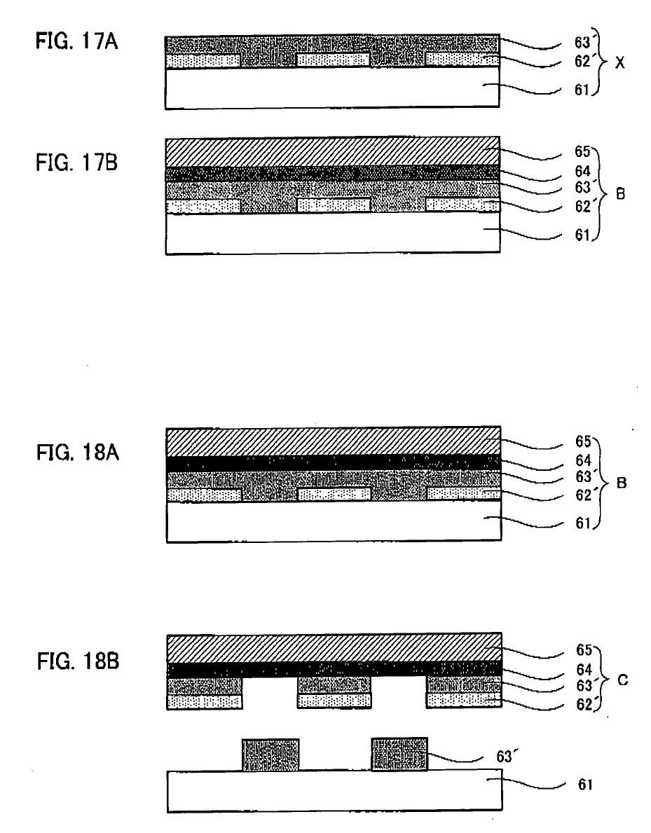

A method of producing an oxide semiconductor electrode with a heat-resistant substrate of the aspect is a method where, as shown in, for example, FIGS. 17A and 17B, to an oxide semiconductor substrate X (FIG. 17A) obtained through the process of forming an intermediate layer-forming pattern, the process of forming an oxide semiconductor layer-forming layer and the sintering process, an electrode base material provided with a base material 65 and a first electrode layer 64 is disposed to form an oxide semiconductor electrode with a heat-resistant substrate B (FIG. 17B).

Hereinafter, a method of disposing an oxide semiconductor substrate and an electrode base material used in the aspect will be detailed.

(1) Oxide Semiconductor Substrate

First, an oxide semiconductor substrate used in the process will be described. The oxide semiconductor substrate used in the process has, as shown in, for example, FIG. 17A, a heat-resistant substrate 61, an intermediate layer 62′ formed on the heat-resistant substrate 61, and an oxide semiconductor layer 63′ formed on the heat-resistant substrate 61 and the intermediate layer 62′. The oxide semiconductor substrate used in the process can be formed by carrying out, to a heat-resistant substrate, the process of forming an intermediate layer-forming pattern, the process of forming an oxide semiconductor layer-forming layer and the sintering process. The heat-resistant substrate and the above processes are same as those described in the “D. Method of Producing Laminated body for Oxide Semiconductor Electrode”: accordingly, descriptions thereof will be omitted here.

(2) Electrode Base Material

Next, an electrode base material used in the aspect will be described. The electrode base material used in the aspect is one that includes a base material and a first electrode layer. The base material and the first electrode layer are same as those used in the first aspect: accordingly, descriptions thereof will be omitted here.

Furthermore, as a method of producing the electrode base material used in the aspect, a known method can be used. Specifically, a wet coating method, a vapor deposition method, a sputtering method, a CVD method and the like can be cited. Above all, a vapor deposition method, a sputtering method and a CVD method can be preferably used.

Still furthermore, a electrode base material used in the aspect may have an conductive bonding layer on a first electrode layer. The conductive bonding layer is not particularly restricted as far as it is excellent in the conductivity and the adhesive property. Specifically, one where an inorganic electrically conductive material is dispersed in a transparent resin, or the like can be cited. The transparent resin is not particularly limited. Examples of the transparent resin include a polyester, an ethylene-vinyl acetate copolymer, an acrylic resin, a polypropylene, a chlorinated polypropylene; a polyethylene, a vinyl chloride resin, a polyvinylidene chloride, a polystyrene, a polyvinyl acetate, a fluoro resin, and a silicone resin. Further, the inorganic conductive material is not particularly limited. Examples include fine particles, needles, rods, flakes and the like (hereinafter generically referred to as “conductive fine particles”) of a highly conductive inorganic material such as an ITO, a tin oxide, an antimony-doped tin oxide (ATO), an antimony oxide, a gold, a silver, and a palladium. When the conductive fine particles are spherical, their diameters should preferably be selected within the range of about 5 to 1000 nm, more preferably in the range of about 10 to 500 nm as needed in view of their dispersibility, the light transmittance and the like. The content of the inorganic conductive material in the transparent resin is not particularly limited, however, it is preferably within the range of about 5 to 50% by weight, particularly in the range of about 10 to 40% by weight. The thickness of the bonding layer having the conductivity is preferably within the range of about 0.1 to 10 μm.

(3) Method of Disposing Electrode Base Material

Next, a method of forming an electrode base material on an oxide semiconductor layer of the oxide semiconductor substrate will be described. A method of forming a base material on the oxide semiconductor layer, is not restricted to particular one, as far as it can form an electrode base material on an oxide semiconductor layer with good adhesion. For example, a method where an oxide semiconductor layer of the oxide semiconductor substrate is selectively heated with a microwave or the like to adhere an oxide semiconductor layer and a first electrode layer of the electrode base material can be cited.

3. Oxide Semiconductor Electrode with Heat-resistant Substrate

Next, an oxide semiconductor electrode with a heat-resistant substrate obtained by the invention will be described. An oxide semiconductor electrode with a heat-resistant substrate obtained by the invention includes, as shown in, for example, FIG. 16B, a heat-resistant substrate 61, an intermediate layer 62′ formed on the heat-resistant substrate 61, an oxide semiconductor layer 63′ formed on the heat-resistant substrate 61 and the intermediate layer 62′, a first electrode layer 64 formed on the oxide semiconductor layer 63′, and a base material 65 formed on the first electrode layer 64. The respective configurations of an oxide semiconductor electrode with a heat-resistant substrate obtained by the invention are same as those described in the above-mentioned respective processes; accordingly, descriptions thereof will be omitted here. Furthermore, in the invention, in the first aspect, when a base material is provided with the bonding layer, an oxide semiconductor electrode with a heat-resistant substrate provided with a bonding layer between the first electrode layer and the base material can be obtained. Still furthermore, in the second aspect, when an electrode base material is provided with the conductive bonding layer, an oxide semiconductor electrode with a heat-resistant substrate provided with a conductive bonding layer between the oxide semiconductor layer and the first electrode layer can be obtained.

An oxide semiconductor electrode with a heat-resistant substrate obtained by a producing method of the invention can be used to prepare an electrode for a dye-sensitized light chargeable capacitor, an electrode for an electrochromic display, a contaminant decomposition substrate and a base material for a dye-sensitized solar cell. Above all, it can be preferably used to prepare a base material for a dye-sensitized solar cell.

F. Method of Producing Oxide Semiconductor Electrode

A method of producing the oxide semiconductor electrode of the invention comprises the process of peeling a heat-resistant substrate off from an oxide semiconductor electrode with a heat-resistant substrate obtained by the method of producing an oxide semiconductor electrode with a heat-resistant substrate.

According to the invention, when an oxide semiconductor electrode obtained by the producing method is applied in, for example, a dye-sensitized solar cell, a dye-sensitized solar cell excellent in the energy conversion efficiency can be obtained.

In a method of producing an oxide semiconductor electrode of the invention, as shown in, for example, FIGS. 18A and 18B, a heat-resistant substrate 61 of an oxide semiconductor electrode with a heat-resistant substrate B (FIG. 18A) obtained by the method of producing an oxide semiconductor electrode with a heat-resistant substrate is peeled. At this time, the heat-resistant substrate 61 is in contact with an intermediate layer 62′ and an oxide semiconductor layer 63′. As described in the “D. Method of Producing Laminated body for Oxide Semiconductor Electrode”, while the intermediate layer 62′, being lower in a concentration of the fine particle of a metal oxide semiconductor than that of the oxide semiconductor layer 63′, has excellent peelability from the heat-resistant substrate 61, the oxide semiconductor layer 63′, being higher in a concentration of the fine particle of a metal oxide semiconductor than that of the intermediate layer 62′, has excellent adhesion to the heat-resistant substrate 61. Accordingly, when the heat-resistant substrate 61 is peeled off front the oxide semiconductor electrode with a heat-resistant substrate B, while the intermediate layer 62′ is peeled in an interface with the heat-resistant substrate 61, the oxide semiconductor layer 63′ is not peeled in an interface with the heat-resistant substrate 61 and peeled in an interface with the first electrode layer 64 lower in the adhesion. As a result, an oxide semiconductor electrode C (FIG. 18B) having the oxide semiconductor layer 63′ along a pattern of the intermediate layer 62′ is formed.

Hereinafter, a peeling process according to the invention will be detailed.

1. Oxide Semiconductor Electrode with Heat-resistant Substrate

Firstly, an oxide semiconductor electrode with a heat-resistant substrate used in the process will be described. The respective configurations of the oxide semiconductor electrode with a heat-resistant substrate used in the process are same as that described in the “B. Method of Producing Oxide Semiconductor Electrode with Heat-resistant Substrate”; accordingly, a description thereof will be omitted here.

2. Method of Peeling Heat-resistant Substrate

Next, a method of peeling a heat-resistant substrate of the oxide semiconductor electrode with a heat-resistant substrate from the intermediate layer will be described. A method of peeling the heat-resistant substrate is not restricted to particular one as far as it can peel the heat-resistant substrate off from the intermediate layer. For example, when a heat-resistant substrate is flexible one and peeled by means of a roll-to-roll method, a method where a heat-resistant substrate of the oxide semiconductor electrode with a heat-resistant substrate and a base material are adhered by use of separate heat-rolls, followed by separately rolling the heat-resistant substrate and the oxide semiconductor electrode can be cited. Furthermore, for example, when a heat-resistant substrate is rigid one, a substrate of the oxide semiconductor electrode with a heat-resistant substrate is adhered by use of a heat-roll, followed by rolling the oxide semiconductor electrode can be cited. In the invention, when the heat-resistant substrate is peeled off from the intermediate layer, depending on the kinds and the like of the heat-resistant substrate and the intermediate layer, there are a case where the heat-resistant substrate and the intermediate layer cause the interfacial peeling and a case where the intermediate layer causes the cohesion failure to partially remain on the heat-resistant substrate.

Furthermore, in the process, the heat-resistant substrate can be peeled as well by means of the mechanical polishing and removing or a chemical removing method such as the etching.

3. Others

In a method of producing an oxide semiconductor electrode of the invention, after the peeling process, the process of forming a first electrode layer in pattern to form a first electrode pattern may be carried out. A process of forming a first electrode pattern will be detailed in a “G. Method of Producing Dye-sensitized Solar Cell” described below. Furthermore, in the invention, even one where the first electrode layer is a first electrode pattern can be called as an oxide semiconductor electrode.

4. Oxide Semiconductor Electrode

Next, an oxide semiconductor electrode obtained by the invention will be described. In an oxide semiconductor electrode obtained by the invention, as shown in, for example, FIG. 18B, sequentially from a base material 66, a first electrode layer 64, a patterned oxide semiconductor layer 63′ and a patterned intermediate layer 62′ are laminated. The respective configurations of an oxide semiconductor electrode obtained by the invention, being same as that described in the above process, are omitted from describing here. Furthermore, in the invention, when the heat-resistant substrate is provided with a wettability-variable layer described in the “D. Method of Producing Laminated body for Oxide Semiconductor Electrode” on a surface, an oxide semiconductor electrode containing the photocatalyst and/or the characteristics-variable material in the intermediate layer can be obtained.

An oxide semiconductor electrode obtained by a producing method of the invention can be applied to a base material for a dye-sensitized light chargeable capacitor used in a dye-sensitized light chargeable capacitor, a base material for an electrochromic display used in an electrochromic display, a contaminant decomposition substrate that can decompose a contaminant in air by a photocatalyst reaction, and a base material for a dye-sensitized solar cell used in a dye-sensitized solar cell; above all, is can be preferably used as a base material for a dye-sensitized solar cell used in a dye-sensitized solar cell.

G. Method of Producing Dye-sensitized Solar Cell

Next, a method of producing a dye-sensitized solar cell of the invention will be described. A method of producing a dye-sensitized solar cell of the invention includes the process of forming a counter electrode base material where, by use of an oxide semiconductor electrode obtained in the method of producing an oxide semiconductor electrode and a counter electrode base material provided with a second electrode pattern and a counter base material, with the intermediate layer and the second electrode pattern faced, a base material pair for a dye-sensitized solar cell is formed, wherein to the laminated body for an oxide semiconductor electrode, the oxide semiconductor electrode with a heat-resistant substrate, the oxide semiconductor electrode or the base material pair for a dye-sensitized solar cell, a filling process where the process of supporting a dye sensitizer on a pore surface of the intermediate layer and the oxide semiconductor layer, and, after the process of supporting a dye sensitizer, the process of forming an electrolyte layer between the second electrode pattern and the intermediate layer and inside of pores of a porous body of the oxide semiconductor layer and the intermediate layer are carried out is applied.

According to the invention, by use of the oxide semiconductor electrode, a dye-sensitized solar cell excellent in the energy conversion efficiency can be obtained.

Furthermore, in the invention, the process of forming the first electrode layer in pattern to form a first electrode pattern is preferably applied to the laminated body of an oxide semiconductor electrode or the oxide semiconductor electrode. This is because by use of the first electrode pattern, a dye-sensitized solar cell excellent in the energy conversion efficiency can be obtained.

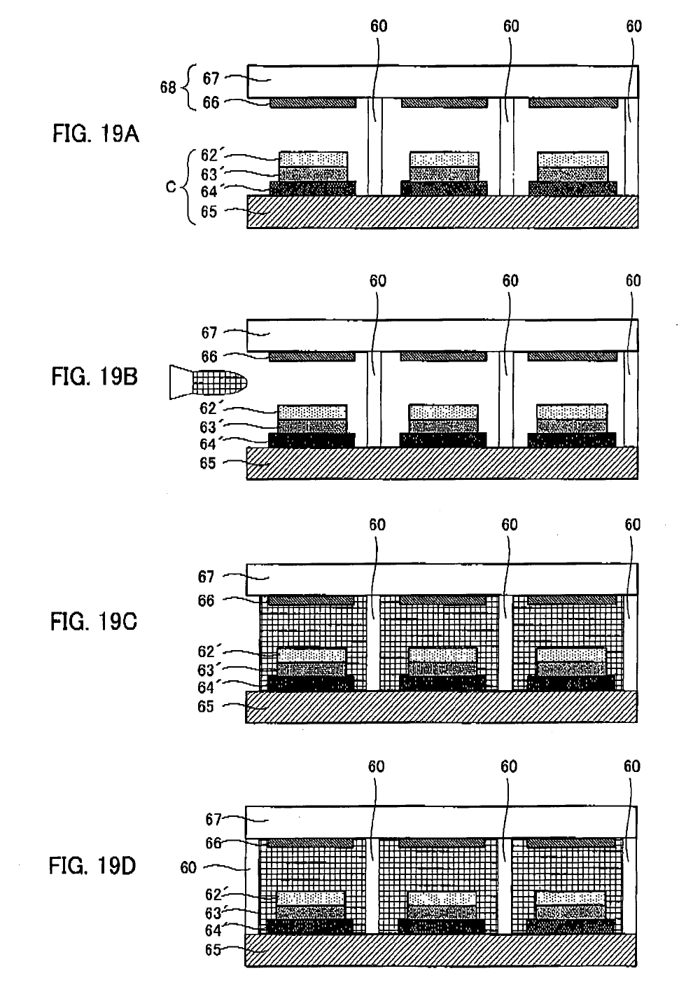

Next, an example of a method of producing a dye-sensitized solar cell of the invention will be described with reference to FIGS. 19A to 19D. In a method of producing a dye-sensitized solar cell of the invention, for example, by using an oxide semiconductor electrode C; in which a dye sensitizer is supported on pore surfaces of an intermediate layer 62′ and an oxide semiconductor layer 63′ patterned by applying the process of supporting a dye sensitizer and the process of forming a first electrode pattern in advance and has a first electrode pattern 64′ a counter electrode, and a base material 68 provided with a second electrode pattern 66 and a counter base material 67, an intermediate layer 62′ of the oxide semiconductor electrode C and the second electrode pattern 66 are disposed so as to face with a predetermined gap, and, with a sealing agent 60, cells are formed in accordance with shapes of the patterned intermediate layer 62′ and second electrode pattern 66, thereby a base material pair for a dye-sensitized solar cell is formed (FIG. 19A). Next, as shown in FIG. 19B, an electrolyte layer-forming coating material is charged in a gap formed between the intermediate layer 62′ and the second electrode pattern 66. Thereby, as shown in FIG. 19C, an electrolyte layer 69 can be formed between the intermediate layer 62′ and the second electrode pattern 66. Furthermore, when the electrolyte layer is liquid or gel-like in particular, in order to inhibit a solvent from volatilizing, the electrolyte layer from eluding and the like, as shown in FIG. 19D, a sealing agent 60 or the like is used to seal to produce a dye-sensitized solar cell.

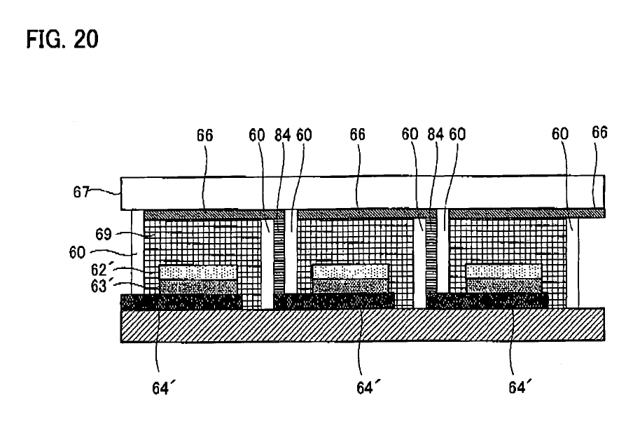

Furthermore, in the dye-sensitized solar cell obtained by the invention, a plurality of cell electrodes formed on a base material may be connected externally or internally. As a dye-sensitized solar cell and the like where cell electrodes are connected internally, as shown in, for example, FIG. 20, a dye-sensitized solar cell where by use of an insulative sealing agent 60 and an conductive connector 84, a first electrode pattern 64′ and a second electrode pattern 66 are internally connected in series can be cited.

In a method of producing a dye-sensitized solar cell of the invention, forming a base material pair for a dye-sensitized solar cell, carrying out a filling process to a laminated body for an oxide semiconductor electrode, an oxide semiconductor electrode with a heat-resistant substrate, an oxide semiconductor electrode or a base material pair of a dye-sensitized solar cell, and forming a first electrode pattern to a laminated body for an oxide semiconductor electrode or an oxide semiconductor electrode are carried out to form a dye-sensitized solar cell. Hereinafter, a base material pair for a dye-sensitized solar cell used in the invention, a filling process and a first electrode pattern-forming process will be detailed.

1. Base Material Pair for Dye-sensitized Solar Cell

First, abase material pair for a dye-sensitized solar cell used in the invention will be described. In the base material pair for a dye-sensitized solar cell used in the invention, by using an oxide semiconductor electrode obtained by the “F. Method of Producing Oxide Semiconductor Electrode” and a counter electrode base material provided with a second electrode pattern and a counter base material, the intermediate layer and the second electrode pattern are disposed to face each other, and thereby a counter electrode base material is obtained.

Hereinafter, a process of forming a counter electrode base material in the invention will be described.

(1) Counter Base Material

First, a counter base material used in the invention will be described. The counter base material used in the process is one that supports a second electrode pattern described below. As the counter base material used in the process, there is no particular restriction irrespective of being transparent or non-transparent. For example, when the counter base material becomes a light-receiving surface in a dye-sensitized solar cell, one excellent in the transparency is preferable. Furthermore, in the invention, a base material excellent in the heat resistance, the weather resistance and the barrier property to a gas such as water vapor can be preferably used. Such counter base material is same as that described in the “E. Method of Producing Oxide Semiconductor Electrode with Heat-resistant Substrate”; accordingly, description thereof is omitted here.

(2) Second Electrode Pattern

Next, a second electrode pattern used in the process will be described. The second electrode pattern used in the process faces an intermediate layer of the oxide semiconductor electrode and collects charges generated by photoirradiation. The second electrode pattern is formed normally so as to face a first electrode pattern described below when a dye-sensitized solar cell is prepared. A metal oxide constituting the second electrode pattern used in the process is not particularly restricted, as far as it is excellent in the conductivity and free from the corrosiveness to an electrolyte. However, when it is disposed on a light-receiving surface side, one excellent in the light transparency is preferable. A metal oxide capable of being used in such a second electrode pattern is, same as a metal oxide constituting a first electrode layer described in the “D. Method of Producing Laminated body for Oxide Semiconductor Electrode”, omitted from describing here. A metal oxide constituting a second electrode pattern is preferably appropriately selected considering a work function of constituent component constituting the first electrode layer and the like. Furthermore, a film thickness of a second electrode pattern used in the invention is, though not particularly restricted, specifically in the range of 0.1 to 500 nm, and preferably in the range of 1 to 300 nm.

(3) Method of Forming Base Material Pair for Dye-sensitized Solar Cell

Next, a method of forming a base material pair for a dye-sensitized solar cell will be described. A method of forming a base material pair for a dye-sensitized solar cell is not restricted to particular one, as far as it is a method that can obtain a dye-sensitized solar cell excellent in the energy conversion efficiency. Specifically, depending on the timing when a present process is applied to a process of forming an electrolyte layer in a filling process described below, the method of forming a base material pair is largely divided as follows; a case where the process is applied prior to the process of forming the electrolyte layer, and a case where the process is applied after the process of forming the electrolyte layer.

When the process is applied prior to the process of forming the electrolyte layer, since an electrolyte layer is not formed, a base material pair for a dye-sensitized solar cell has to be formed between the intermediate layer and the second electrode pattern so that a gap where an electrolyte layer is formed may be formed. In this case, a method of forming a base material pair for a dye-sensitized solar cell is not particularly restricted as far as it can obtain a base material pair for a dye-sensitized solar cell provided with the gap. For example, a method that uses a spacer can be cited. As a spacer, for example, a glass spacer, a resin spacer or an olefinic porous membrane can be cited. Furthermore, the gap is not restricted to particular one as far as it has a width capable of forming an electrolyte layer. The width is generally in the range of 0.01 to 100 μm, and preferably in the range of 0.1 to 50 μm.

On the other hand, when the process is carried out after the process of forming the electrolyte layer, since an electrolyte layer is already formed on a base material and an intermediate layer, there is no need of disposing a gap as mentioned above. In this case, a method of forming a base material pair for a dye-sensitized solar call is not restricted to particular one, as far as it is a method that can obtain a desired dye-sensitized solar cell. Specifically, a method of adhering the counter electrode base material can be cited.

Furthermore, in the process, by use of a general sealing agent, a cell can be formed in accordance with shapes of a patterned intermediate layer and a second electrode pattern, and thereby a base material pair for a dye-sensitized solar cell provided with a plurality of cells on a base material can be formed.

2. Filling Process

Then, a filling process in the invention will be described. The filling process in the invention includes a dye sensitizer supporting process and an electrolyte layer forming process, which is applied after the dye sensitizer supporting process. In the invention, the filling process is applied to a laminated body for an oxide semiconductor electrode, an oxide semiconductor electrode with a heat-resistant substrate, an oxide semiconductor electrode, or a base material pair for a dye-sensitized solar cell to produce a dye-sensitized solar cell. Hereinafter, a dye sensitizer supporting process and an electrolyte layer-forming process, which are the filling process in the invention, will be described.

(1) Dye Sensitizer Supporting Process

Firstly, a dye sensitizer supporting process in the filling process will be described. The dye sensitizer supporting process is carried out to the laminated body for an oxide semiconductor electrode, the oxide semiconductor electrode with a heat-resistant substrate, the oxide semiconductor electrode or the base material pair for a dye-sensitized solar cell to support a dye sensitizer on a pore surface of an intermediate layer and an oxide semiconductor layer of the members.

(a) Dye Sensitizer

A dye sensitizer used in the process is not particularly restricted as far as it can generate charges upon photoirradiation. Specifically, an organic dye or a metal complex dye can be used. Examples of the organic dye include acridine dyes, azo dyes, indigo dyes, quinone dyes, coumarin dyes, merocyanine dyes, and phenylxanthene dyes. Among then, coumarin dyes are more preferred.

Furthermore, as the metal complex dye, a ruthenium dye is preferable, in particular, a ruthenium bipyridine dye and ruthenium terpiridine dye, which are ruthenium complexes, are preferable. An oxide semiconductor layer can hardly absorb visible light (light having a wavelength substantially in the range of 400 to 800 nm). However, for example, a ruthenium complex, when supported by an oxide semiconductor layer, can largely absorb up to visible light to generate the photoelectric conversion and thereby a wavelength region of light that can be photoelectrically converted can be largely expanded.

(b) Method of Supporting Dye Sensitizer

In the process, as a method of supporting a dye sensitizer on a pore surface of the intermediate layer and the oxide semiconductor layer, there is no particular restriction. For example, a method where the oxide semiconductor layer and the intermediate layer are dipped in a solution of a dye sensitizer followed by drying can be cited; or, to a member that does not have a heat-resistant substrate but has an exposed intermediate layer, such as an oxide semiconductor electrode, a method where a dye sensitizer-dissolved solution is coated and dried can be cited.

(2) Process of Forming Electrolyte Layer

Next, a process of forming an electrolyte layer in the filling process will be described. The process of forming an electrolyte layer is the process of forming an electrolyte layer that transfers charges generated by photoirradiation between the second electrode pattern and the intermediate layer, and inside of pores of a porous body of the oxide semiconductor layer and the intermediate layer.

(a) Electrolyte Layer

An electrolyte layer obtained by the process is located between an intermediate layer and a second electrode pattern of a dye-sensitized solar cell and carries out charge transfer between a dye sensitizer, supported by the intermediate layer and the oxide semiconductor layer and the second electrode pattern. The electrolyte layer normally contains a redox couple. As the redox couple, one that can be used in an electrolyte of a general dye-sensitized solar cell can be used. As specific redox couples, an iodine-iodine compound and a bromine-bromine compound can be cited. Furthermore, as the iodine compounds, metal iodides such as LiI, NaI, KI and CaI can be cited; and as the bromine compounds LiBr, NaBr, KBr, CaBr₂ and the like can be cited.

Furthermore, a mode of an electrolyte layer obtained by the process is not particularly restricted as far as it can transfer charges. It may be in any one of a solid aspect, a gel aspect and a liquid aspect. Specifically, one that is obtained by solidifying the redox couple with a polymer, one that is rendered gel-like with a gelling agent, one that is liquefied by dissolving in a solvent, and the like can be cited.

In the invention, since the intermediate layer and the oxide semiconductor layer are porous, when the redox couple rendered gel-like and the liquefied redox couple are used, the redox couple partially moves to the inside of the porous.

The polymer used to solidify is not restricted to particular one. For example, CuI, a polypyrrole and a polythiophene can be cited. The polymers like this, being conductive and high in the hole transferability, can be preferably used.

Furthermore, the gelling agent is not restricted to particular one. For example, when an electrolyte of a physical gel is intended to obtain, as the gelling agent, a polyacrylonitrile and a polymethacrylate can be cited. Still furthermore, when an electrolyte of a chemical gel is intended to obtain, an acrylic ester type and a methacrylic ester type can be cited. The physical gel means one that is gel-like in the proximity of room temperature owing to the physical interaction, and the chemical gel means one that is gel-like owing to a chemical bond obtained by a crosslinking reaction or the like.

Moreover, as the solvent, without restricting to particular one, for example, water, an acetonitrile and a methoxyproxy nitrile can be cited.

Furthermore, the electrolyte layer obtained by the process, if necessary, may contain additives such as a crosslinking agent, a photopolymerization initiator, a viscosity improver and a salt capable of melting at room temperature.

A film thickness of the electrolyte layer obtained by the process, though not particularly restricted, including film thicknesses of an intermediate layer and an oxide semiconductor layer, is preferably in the range of 2 to 100 μm, and more preferably in the range of 2 to 50 μm. This is because when the film thickness thereof is less than the above range, the intermediate layer and the second electrode pattern are likely to come in to contact to cause the short-circuiting; on the other hand, when the film thickness thereof exceeds the above range, the internal resistance may become larger to deteriorate the performance.

(b) Method of Forming Electrolyte Layer

Next, a method of forming an electrolyte layer will be described. The method of forming an electrolyte layer is not restricted to particular one as far as a dye-sensitized solar cell excellent in the energy conversion efficiency can be obtained. Specifically, the method can be largely divided as follows depending on the timing when the present process is applied to the process of forming a counter electrode base material. That is, these are a case where the present process is applied prior to the process of forming a counter electrode base material, and a case where the present process is applied after the process of forming a counter electrode base material.

When the present process is applied prior to the process of forming a counter electrode base material, a base material pair for a dye-sensitized solar cell is not formed and an electrolyte layer is formed directly on a base material and an intermediate layer. Accordingly, a self-supporting electrolyte layer has to be formed. A method of forming an electrolyte layer like this is not restricted to particular one. Specifically, a method where an electrolyte layer-forming coating material containing constituent components of the electrolyte layer is applied to a base material and an intermediate layer, and followed by setting or the like the coating, and thereby an electrolyte layer is formed (coating method) can be cited. In the coating method, a solid electrolyte layer is mainly obtained. When the solid electrolyte layer is obtained, normally, the electrolyte layer-forming coating material contains the redox couple and the polymer that supports the redox couple.

As a method of coating in the coating method, without restricting to particular one, well-known coating methods can be used. Specifically, a die coating method, a gravure coating method, a gravure reverse coating method, a roll coating method, a reverse roll coating method, a bar coating method, a blade coating method, a knife coating method, an air knife coating method, a slot die coating method, a slide die coating method, a dip coating method, a microbar coating method, a microbar reverse coating method, a screen printing method (rotary method) and the like can be cited.

Furthermore, in the coating method, when the electrolyte layer-forming coating material contains a crosslinking agent and a photopolymerization initiator, after the electrolyte layer-forming coating material is coated, by irradiating an active ray to cure, a solid electrolyte layer can be formed.

On the other hand, when the present process is carried out after the process of forming a counter electrode base material, since a dye-sensitized solar cell having a predetermined gap is already formed, an electrolyte layer is formed in the gap. In this case, a method of forming an electrolyte layer is not restricted to particular one. Specifically, a method where an electrolyte layer-forming coating material containing constituent components of the electrolyte layer is injected between a base material and an intermediate layer and a second electrode pattern to form an electrolyte layer (injection method) can be cited. In the injection method, a solid, gel-like or liquid electrolyte layer can be formed.

A method of injecting in the injection method is not restricted to particular one, as far as it can inject an electrolyte layer-forming coating material in a gap between a base material and an intermediate layer and a second electrode pattern. For example, a method that makes use of the capillarity phenomenon can be used.

Furthermore, in the injection method, when the electrolyte layer-forming coating material contains the gelling agent, after the electrolyte layer-forming coating material is injected, for example, by carrying out a temperature control, UV irradiation, EB irradiation or the like, a gel-like or solid electrolyte layer crosslinked two-dimensionally or three-dimensionally can be formed.

3. Process of Forming First Electrode Pattern

Next, a process of forming a first electrode pattern in the invention will be described. The process of patterning a first electrode in the invention is a process where a first electrode pattern is formed in pattern to form a first electrode pattern. In this case, a first electrode pattern is formed in conformity with a pattern of an intermediate layer and the like, and so as to have an area larger than a pattern of the intermediate layer and the like. By carrying out the process of patterning a first electrode, cells made of patterned intermediate layer and oxide semiconductor layer and a first electrode pattern, which are described in the “D. Method of Producing Laminated body for Oxide Semiconductor Electrode”, can be formed; and when the cells are connected in parallel an output current can be improved or when cells are connected in series an output voltage can be improved. A method of forming a first electrode layer in pattern is not particularly restricted as far as it can form a desired cell. Specifically, a laser scribing method, a wet etching method, a lift-off method, a dry etching method, a mechanical scribing method and the like can be cited, and, among these, a laser scribing method and a mechanical scribing method are preferable. Furthermore, as another method of forming the first electrode layer in pattern, for example, a method of patterning, between a first electrode layer and a base material, a bonding layer described in the “E. Method of Producing Oxide Semiconductor Electrode with Heat-resistant Substrate” to use can be cited. Specifically, the bonding layer is formed in pattern on a base material, the patterned bonding layer and a first electrode layer of the laminated body for the oxide semiconductor electrode are adhered, and thereby an oxide semiconductor electrode with a heat-resistant substrate is prepared. When the heat-resistant substrate is peeled off from the oxide semiconductor electrode with a heat-resistant substrate, only a portion where a patterned bonding layer is present of the first electrode layer remains on the oxide semiconductor electrode, and, as a result, a first electrode pattern is obtained. At this time, by making an area of the patterned bonding layer larger than an area of a corresponding patterned intermediate layer, an oxide semiconductor electrode provided with a first electrode pattern having an area larger than that of the intermediate layer and the like can be formed.

4. Timing when Filling Process and Process of Forming First Electrode Pattern are Carried Out

Next, the timing when the filling process and the process of forming a first electrode pattern are carried out will be described. The filling process includes, as mentioned above, a dye sensitizer-supporting process and the electrode layer-forming process, and the two processes are applied to a laminated body for an oxide semiconductor electrode, an oxide semiconductor electrode with a heat-resistant substrate, an oxide semiconductor electrode or a base material pair for a dye-sensitized solar cell. In the invention, the two processes may be carried out continuously or may be carried out separately. Furthermore, the process of forming the first electrode pattern is a process where, as mentioned above, the first electrode pattern is shaped along a pattern of the intermediate layer and the like, and the process is applied to a laminated body for an oxide semiconductor electrode or an oxide semiconductor electrode. In the invention, even when the process of forming a first electrode pattern is not applied, a dye-sensitized solar cell can be obtained.

Hereinafter, based on the timings of the process of supporting a dye sensitizer carried out first in the filling process and the timing of forming a first electrode pattern, a method of producing a dye-sensitized solar cell of the invention will be illustrated.

(a) Case where Process of Supporting Dye Sensitizer is Firstly Applied to Laminated Body for Oxide Semiconductor Electrode

As a method of producing a dye-sensitized solar cell when a process of supporting a dye sensitizer is firstly applied to a laminated body for an oxide semiconductor electrode, methods according to (i) to (iv) below can be cited.

(i) A method of producing a dye-sensitized solar cell, in which, to the laminated body for an oxide semiconductor electrode, the process of supporting a dye sensitizer is applied, followed by sequentially applying the process of forming a first electrode pattern, the process of forming abase material, the peeling process, the process of forming an electrolyte layer and the process of forming a counter electrode base material to produce a dye-sensitized solar cell.

(ii) A method of producing a dye-sensitized solar cell, in which, to the laminated body for an oxide semiconductor electrode, the process of supporting a dye sensitizer is applied, followed by sequentially applying the process of forming a base material, the peeling process, the process of forming a first electrode pattern, the process of forming an electrolyte layer and the process of forming a counter electrode base material to produce a dye-sensitized solar cell.

(iii) A method of producing a dye-sensitized solar cell, in which, to the laminated body for an oxide semiconductor electrode, the process of supporting a dye sensitizer is applied, followed by sequentially applying the process of forming a first electrode pattern, the process of forming a base material, the peeling process, the process of forming a counter electrode base material and the process of forming an electrolyte layer to produce a dye-sensitized solar cell.

(iv) A method of producing a dye-sensitized solar cell, in which, to the laminated body for an oxide semiconductor electrode, the process of supporting a dye sensitizer is applied, followed by sequentially applying the process of forming a base material, the peeling process, the process of forming a first electrode pattern, the process of forming a counter electrode base material and the process of forming an electrolyte layer to produce a dye-sensitized solar cell.

(b) Case Where Process of Forming First Electrode Pattern is Firstly Applied to Laminated Body for Oxide Semiconductor Electrode

As a method of producing a dye-sensitized solar cell when a process of forming a first electrode pattern is firstly applied to a laminated body for an oxide semiconductor electrode, methods according to (v) to (xi) below can be cited.

(v) A method of producing a dye-sensitized solar cell, in which, to the laminated body for an oxide semiconductor electrode, the process of forming a first electrode pattern is applied, followed by sequentially applying the process of supporting a dye sensitizer, the process of forming a base material, the peeling process, the process of forming an electrolyte layer and the process of forming a counter electrode base material to produce a dye-sensitized solar cell.

(vi) A method of producing a dye-sensitized solar cell, in which, to the laminated body for an oxide semiconductor electrode, the process of forming a first electrode pattern is applied, followed by sequentially applying the process of forming a base material, the process of supporting a dye sensitizer, the peeling process, the process of forming an electrolyte layer and the process of forming a counter electrode base material to produce a dye-sensitized solar cell.

(vii) A method of producing a dye-sensitized solar cell, in which, to the laminated body for an oxide semiconductor electrode, the process of forming a first electrode pattern is applied, followed by sequentially applying the process of forming a base material, the peeling process, the process of supporting a dye sensitizer, the process of forming an electrolyte layer and the process of forming a counter electrode base material to produce a dye-sensitized solar cell.

(viii) A method of producing a dye-sensitized solar cell, in which, to the laminated body for an oxide semiconductor electrode, the process of forming a first electrode pattern is applied, followed by sequentially applying the process of supporting a dye sensitizer, the process of forming a base material, the peeling process, the process of forming a counter electrode base material and the process of forming an electrolyte layer to produce a dye-sensitized solar cell.

(ix) A method of producing a dye-sensitized solar cell, in which, to the laminated body for an oxide semiconductor electrode, the process of forming a first electrode pattern is applied, followed by sequentially applying the process of forming a base material, the process of supporting a dye sensitizer, the peeling process, the process of forming a counter electrode base material and the process of forming an electrolyte layer to produce a dye-sensitized solar cell.

(x) A method of producing a dye-sensitized solar cell, in which, to the laminated body for an oxide semiconductor electrode, the process of forming a first electrode pattern is applied, followed by sequentially applying the process of forming a base material, the peeling process, the process of supporting a dye sensitizer, the process of forming a counter electrode base material and the process of forming an electrolyte layer to produce a dye-sensitized solar cell.

(xi) A method of producing a dye-sensitized solar cell, in which, to the laminated body for an oxide semiconductor electrode, the process of forming a first electrode pattern is applied, followed by sequentially applying the process of forming a base material, the peeling process, the process of forming a counter electrode base material, the process of supporting a dye sensitizer and the process of forming an electrolyte layer to produce a dye-sensitized solar cell.

(c) Case Where Process of Supporting Dye Sensitizer is Firstly Applied to Oxide Semiconductor Electrode With Heat-resistant Substrate

As a method of producing a dye-sensitized solar cell when a process of supporting a dye sensitizer is firstly applied to an oxide semiconductor electrode with a heat-resistant substrate, methods according to (xii) and (xiii) below can be cited.

(xii) A method of producing a dye-sensitized solar cell, in which, to the oxide semiconductor electrode with a heat-resistant substrate, the process of supporting a dye sensitizer is applied, followed by sequentially applying the peeling process, the process of forming a first electrode pattern, the process of forming an electrolyte layer and the process of forming a counter electrode base material to produce a dye-sensitized solar cell.

(xiii) A method of producing a dye-sensitized solar cell, in which, to the oxide semiconductor electrode with a heat-resistant substrate, the process of supporting a dye sensitizer is applied, followed by sequentially applying the peeling process, the process of forming a first electrode pattern, the process of forming a counter electrode base material and the process of forming an electrolyte layer to produce a dye-sensitized solar cell.

(d) Case Where Process of Supporting Dye Sensitizer is Firstly Applied to Oxide Semiconductor Electrode

As a method of producing a dye-sensitized solar cell when a process of supporting a dye sensitizer is firstly applied to an oxide semiconductor electrode, methods according to (xiv) and (xv) below can be cited.

(xiv) A method of producing a dye-sensitized solar cell, in which, to the oxide semiconductor electrode, the process of supporting a dye sensitizer is applied, followed by sequentially applying the process of forming a first electrode pattern, the process of forming an electrolyte layer and the process of forming a counter electrode base material to produce a dye-sensitized solar cell.

(xv) A method of producing a dye-sensitized solar cell, in which, to the oxide semiconductor electrode, the process of supporting a dye sensitizer is applied, followed by sequentially applying the process of forming a first electrode pattern, the process of forming a counter electrode base material and the process of forming an electrolyte layer to produce a dye-sensitized solar cell.

(e) Case Where Process of Forming First Electrode Pattern is Firstly Applied to Oxide Semiconductor Electrode

As a method of producing a dye-sensitized solar cell when a process of forming a first electrode pattern is firstly applied to an oxide semiconductor electrode, methods according to (xvi) and (xvii) below can be cited.

(xvi) A method of producing a dye-sensitized solar cell, in which, to the oxide semiconductor electrode, the process of forming a first electrode layer is applied, followed by sequentially applying the process of supporting a dye sensitizer, the process of forming an electrolyte layer and the process of forming a counter electrode base material to produce a dye-sensitized solar cell.

(xvii) A method of producing a dye-sensitized solar cell, in which, to the oxide semiconductor electrode, the process of forming a first electrode pattern is applied, followed by sequentially applying the process of supporting a dye sensitizer, the process of forming a counter electrode base material and the process of forming an electrolyte layer to produce a dye-sensitized solar cell.

In the invention, among the (i) to (xvii), methods of producing a dye-sensitized solar cell shown in (vii), (x), (xi), (xiv), (xv) and (xvii) are preferable, and a method of producing a dye-sensitized solar cell shown in (xvii) is particularly preferable.

5. Dye-sensitized Solar Cell

Next, a dye-sensitized solar cell obtained by the invention will be described. The dye-sensitized solar cell obtained by the invention includes, as shown in, for example, FIG. 19D, an oxide semiconductor electrode provided with a first electrode pattern 64′, a patterned oxide semiconductor layer 63′ and a patterned intermediate layer 62′ sequentially formed on a base material 65, a counter electrode base material that faces the intermediate layer 62′ and is provided with a second electrode pattern 66 and a counter base material 67, and an electrolyte layer 69 formed between the intermediate layer 62′ and the second electrode pattern 66. The respective configuration of a dye-sensitized solar cell of the invention is same as that described in a section of the “C. Dye-sensitized Solar Cell”; accordingly, descriptions thereof will be omitted here.

In a dye-sensitized solar cell of the invention, charges generated from a dye sensitizer are made use of to obtain a photocurrent. In general, as the charges generated from a dye sensitizer, electrons can be cited. Under the photoirradiation, a dye sensitizer supported by the intermediate layer and the oxide semiconductor layer absorbs light to transit to an excited state. A dye sensitizer in an excited state generates an electron and the generated electron is delivered to the intermediate layer and the like. Furthermore, the electron is transferred through a lead wire connected to the first electrode layer to a counter electrode. Thereby, the photocurrent can be obtained. At this time, by transferring the generated electron to the intermediate layer and the like, the dye sensitizer is to be oxidized. Still furthermore, the generated electron, after moving to the counter electrode, reduces I₃⁻ of I⁻/I₃⁻ that is a redox couple present in the electrolyte layer to I⁻. Furthermore, the I⁻ can reduce an oxidized dye sensitizer to return to a ground state.

The invention is not restricted to the above-mentioned embodiments. The embodiments are only exemplifications and one that has a configuration and exerts an effect substantially same as a technical idea described in the range of claims of the invention is contained in the technical range of the invention.

### EXAMPLES

Hereinafter, the invention will be further detailed with reference to examples.

### Example 1

1. Formation of Porous Layer

(1) Formation of Oxide Semiconductor Layer-forming Layer

As an oxide semiconductor layer-forming coating material, a titanium oxide paste having a particle diameter of substantially 13 nm (trade name: Ti-Nanoxide D, manufactured by Solaronix SA) was used. The titanium oxide paste was coated by use of a doctor blade method, followed by leaving at room temperature for 20 minutes, further followed by drying at 100° C. for 30 minutes.

(2) Sintering

The oxide semiconductor layer-forming layer was sintered at 500° C. for 30 minutes in an electric muffle furnace (tradename: P90, manufactured by DENKEN CO., LTD.) under an atmospheric pressure atmosphere. Thereby, a porous layer formed as a porous body was obtained.

2. Formation of First Electrode Layer

As a first electrode layer-forming composition, a composition where 0.1 mol/l of indium chloride and 0.005 mol/l of tin chloride were dissolved in ethanol was prepared. Thereafter, the sintered heat-resistant substrate was disposed on a hot plate (400° C.) with a porous layer directed upward; and on the heated porous layer, the first electrode layer-forming composition was sprayed by use of a ultrasonic atomizer to form an ITO film that is a transparent film at 500 nm, and thereby a base material for a dye-sensitized solar cell was formed.

3. Addition of Bonding Layer and Base Material

Subsequently, as a bonding layer, a thermoplastic resin film below was prepared. To 98 parts by weight of linear low density polyethylene (LLDPE) having the density of 0.898 g/cm³, 2 parts by weight of vinylmethoxysilane and 0.1 parts by weight of a radical initiator were blended and graft-polymerized, and thereby a silane-modified polyethylene resin was obtained. The resin was blended with pellets of a weather resistant agent made of an antioxidant, a UV absorber and a light stabilizer, followed by applying the melt-extrusion with a T dice, and thereby a thermoplastic resin film having a thickness of 50 μm was obtained.

Subsequently, a transparent resin film base material was formed according to a method where the previously formed thermoplastic resin film was interposed between a corona-processed surface of a PET film (trade name: E5100, manufactured by TOYOBO., LTD., 125 μm) and a surface of the previously formed ITO film of a base material for a dye-sensitized solar cell, followed by adhering at 130° C. by use of a roll laminator.

4. Peeling of Heat-resistant Substrate

Thereafter, an alkali-free glass substrate was peeled and thereby a porous layer and a first electrode layer were transferred on a base material.

5. Patterning of Porous Layer

Further thereafter, the porous layer was trimmed to form a 0.8 mm□ porous layer.

6. Addition of Dye Sensitizer

The porous layer was dipped in a previously-prepared absorbing dye solution (obtained by dissolving a ruthenium complex (RuL₂(NCS)₂ manufactured by Kojima Chemicals Co., LTD.) in an anhydrous ethanol solution so as to be a concentration of 3×10⁻⁴ mol/l), and thereby a base material for a dye-sensitized solar cell of which porous layer supports a dye sensitizer was obtained.

7. Preparation of Dye-sensitized Solar Cell

With the obtained base material for a dye-sensitized solar cell, a dye-sensitized solar cell was prepared as follows. An electrolyte layer-forming composition that forms an electrolyte layer was prepared as follows. With methoxyacetonitrile as a solvent, lithium iodide, iodine, dimethylpropylimidazoliumiodide and tert-butyl pyridine, were dissolved at respective concentrations of 0.1 mol/l, 0.05 mol/l, 0.3 mol/l and 0.5 mol/l and thereby an electrolyte solution was obtained.

The electrode for a dye-sensitized solar cell and a counter base material were adhered with a Surlyn film having a thickness of 20 μm, therebetween an electrolyte layer-forming coating material was impregnated and thereby a dye-sensitized solar cell was prepared. As a counter base material, one in which a platinum film having a film thickness of 50 nm was sputtered on a counter film base material that has an ITO sputtered layer with a film thickness of 150 nm and the surface resistance of 7 Ω/□ was used.

(Evaluation)

Of the prepared dye-sensitized solar cell, the current-voltage characteristics were measured by a method described below, and thereby the short-circuit current, the open voltage and the conversion efficiency, were found to be 14.8 mA/cm², 683 mV and 6.1% respectively.

### Example 2

Except that a porous layer was formed by a method below, a dye-sensitized solar cell was prepared by a method similar to that of example 1.

<Method of Forming Porous Layer (Example 2)>

(1) Formation of Intermediate Layer-Forming Layer

An intermediate layer-forming coating material was prepared as follows. That is, an acrylic resin (trade name: BR87, manufactured by Mitsubishi Rayon Co., Ltd., molecular weight: 25000 and glass transition temperature: 105° C.) was dissolved in methyl ethyl ketone and toluene, followed by dispersing TiO₂ fine particles having a primary particle diameter of 20 nm (trade name: P25, manufactured by NIPPON AEROSIL CO., LTD.) therein by use of a paint shaker so that the TiO₂ fine particles and the acrylic resin, respectively, may be 1 mass percent and 10 mass percents, and thereby an intermediate layer-forming coating material was prepared. The intermediate layer-forming coating material was coated by use of a wire bar on an alkali-free glass substrate (thickness: 0.7 mm) prepared as a heat-resistant substrate and dried.

(2) Formation of Oxide Semiconductor Layer-Forming Layer

An oxide semiconductor layer-forming coating material was prepared as follows. That is, TiO₂ fine particles (trade name: P25, manufactured by NIPPON AEROSIL CO., LTD.) having a primary particle diameter of 20 nm, acetyl acetone and polyethylene glycol (average molecular weight: 3000), respectively, were dissolved and dispersed by use of a homogenizer in water and isopropyl alcohol so as to be 37.5 mass percents, 1.25 mass percents and 1.88 mass percents respectively, and thereby an oxide semiconductor layer-forming coating material was prepared. The oxide semiconductor layer-forming coating material was coated by use of a doctor blade method on the heat-resistant substrate on which the intermediate layer-forming layer was formed, followed by leaving under room temperature for 20 minutes, further followed by drying at 100° C. for 30 minutes.

(3) Sintering

The intermediate layer-forming layer and the oxide semiconductor layer-forming layer was sintered at 500° C. for 30 minutes in an electric muffle furnace (trade name: P90, manufactured by DENKEN CO., LTD.) under an atmospheric pressure atmosphere. Thereby, a porous layer formed as a porous body was obtained.

(Evaluation)

Of the prepared dye-sensitized solar cell, the current-voltage characteristics were measured by a method described below, and thereby the short-circuit current, the open voltage and the conversion efficiency, were found to be 13.2 mA/cm², 680 mV and 5.5% respectively.

### Comparative Example 1

Except that LLDPE having the density of 0.898 g/cm³ was used as a bonding layer and a thermoplastic film having a thickness of 50 μm was used in a method similar to that of example 2, a dye-sensitized solar cell was attempted to prepare similarly to a method of example 2.

However, when the alkali-free glass substrate was peeled in the “4. Peeling of Heat-Resistant Substrate”, the transferability failure was caused, resulting in being incapable of forming a dye-sensitized solar cell.

### Comparative Example 2

Except that EVA (ethylene-vinyl acetate copolymer) (trade name: SB-10 manufactured by TAMAPOLY Co., Ltd.) having a thickness of 50 μm was used as a bonding layer, a dye-sensitized solar cell was prepared similarly to a method of example 2.

Evaluation

Of the prepared dye-sensitized solar cell, the current-voltage characteristics were measured by a method described below, and thereby the short-circuit current, the open voltage and the conversion efficiency, were found to be 13.2 mA/cm², 678 mV and 5.4% respectively.

### Example 3

An intermediate layer-forming coating material was prepared as follows. That is, an acrylic resin (trade name: BR87, manufactured by Mitsubishi Rayon Co., Ltd., molecular weight: 25000 and glass transition temperature: 105° C.) mainly made of polymethyl methacrylate was dissolved in methyl ethyl ketone and toluene, followed by dispersing TiO₂ fine particles having a primary particle diameter of 20 nm (trade name: P25, manufactured by NIPPON AEROSIL CO., LTD.) therein by use of a homogenizer so that the TiO₂ fine particles and the acrylic resin, may be 1 mass percent and 10 mass percents respectively, and thereby an intermediate layer-forming coating material was prepared. The coating material was coated by use of a wire bar on an alkali-free glass substrate (thickness: 0.7 mm) prepared as a heat-resistant substrate and dried. Thereafter, an area of 1 cm×1 cm was masked, an area other than the above was dissolved and removed by use of methyl ethyl ketone and thereby an intermediate layer-forming pattern having an area of 1 cm×1 cm was obtained.

An oxide semiconductor layer-forming coating material was prepared as follows. That is, TiO₂ fine particles (trade name: P25, manufactured by NIPPON AEROSIL CO., LTD.) having a primary particle diameter of 20 nm, acetyl acetone and polyethylene glycol (average molecular weight: 3000), were dissolved and dispersed by use of a homogenizer in water and isopropyl alcohol so as to be 37.5 mass percents, 1.25 mass percents and 1.88 mass percents respectively, and a slurry was prepared. On the heat-resistant substrate and the intermediate layer-forming pattern, the slurry was coated by use of the doctor blade method, followed by leaving under room temperature for 20 minutes, further followed by drying at 100° C. for 30 minutes, still further followed by sintering in an electric muffle furnace (trade name: P90, manufactured by DENKEN CO., LTD.) at 500° C. for 30 minutes under an atmospheric pressure atmosphere. Thereby, an intermediate layer and an oxide semiconductor layer that were obtained as a porous body were obtained.

Thereafter, as a first electrode layer-forming coating material, a coating material where 0.1 mol/l of indium chloride and 0.005 mol/l of tin chloride were dissolved in ethanol was prepared. Thereafter, the sintering process was applied, and the heat-resistant substrate provided with an intermediate layer and an oxide semiconductor layer was disposed on a hot plate (400° C.) with the oxide semiconductor membrane directed upward, the first electrode layer-forming coating material was sprayed by use of a ultrasonic atomizer on the heated oxide semiconductor membrane to form an ITO film that is a transparent film at 500 nm, and thereby a laminated body for an oxide semiconductor electrode was obtained.

Thereafter, with a PET film (trade name: A5100, manufactured by TOYOBO., LTD., 125 μm) as a base material, the base material was masked, followed by coating a heat seal agent (trade name: MD1985, manufactured by TOYOBO., LTD.), further followed by drying in air, and thereby a bonding layer having an area of 2.5 cm×2.5 cm was formed. The bonding layer and an ITO surface of the laminated body for an oxide semiconductor electrode were adhered at 120° C. so that an area of the bonding layer may be above an area of the intermediate layer-forming pattern, and thereby an oxide semiconductor electrode with a heat-resistant substrate was obtained.

Further thereafter, the heat-resistant substrate was peeled off from the oxide semiconductor electrode with a heat-resistant substrate and thereby an oxide semiconductor electrode having a patterned oxide semiconductor layer or the like was obtained.

Thereafter, as a dye sensitizer, a ruthenium complex (RuL₂(NCS)₂), manufactured by Kojima Chemicals Co., LTD) was dissolved in an anhydrous ethanol solution so that a concentration thereof may be 3×10⁻⁴ mol/l, and thereby an absorbing dye solution was prepared. The oxide semiconductor layer or the like was dipped in the absorbing dye solution to support the dye sensitizer.

With thus obtained oxide semiconductor electrode, a dye-sensitized solar cell was prepared as follows. First, an electrolyte layer-forming coating material that forms an electrolyte layer was prepared as follows. Lithium iodide, iodine, dimethylpropylimidazolium iodide and tert-butyl pyridine, were dissolved in methoxyacetonitrile as a solvent at concentrations of 0.1 mol/l, 0.05 mol/l, 0.3 mol/l and 0.5 mol/l respectively, and thereby an electrolyte solution was obtained.

The oxide semiconductor electrode and a counter electrode base material were adhered with a Surlyn film having a thickness of 20 μm, therebetween an electrolyte layer-forming coating material was impregnated, and thereby element was prepared. As a counter electrode base material, one in which a platinum film having a film thickness of 50 nm was sputtered on a counter base material that has an ITO sputtered film with a film thickness of 150 nm and the surface resistance of 7 Ω/□ was used.

Of the prepared dye-sensitized solar cell, the current-voltage characteristics were measured by a method described below. As a result, as the battery characteristics of a single cell, the short-circuit current, the open voltage and the conversion efficiency, were found to be 13.8 mA/cm², 680 mV and 5.9% respectively.

### Example 4

Next, 3 parts by weight of isopropyl alcohol as a dispersion solvent and 2 parts by weight of a dispersion (trade name: ST-K01, manufactured by ISHIHARA SANGYO KAISHA, LTD.) that contains titanium oxide fine particles having an average particle diameter of 7 nm as a photocatalyst were blended and agitated at 90° C. for 10 minutes, followed by further adding 0.14 part by weight of fluoroalkoxysilane (trade name: MF-160E, manufactured by Tohkem Co., Ltd.) as a binder, further followed by blending and agitating. Thereafter, the solution was diluted with isopropyl alcohol to 4 times, and thereby a coating material for obtaining a wettability-variable layer was obtained.

On an alkali-free glass substrate (thickness: 0.7 mm) prepared as a heat-resistant substrate, the coating material was coated by means of the spin coat method, the obtained coated film was dried at 150° C. for 10 minutes, and thereby a wettability-variable layer having a film thickness of 10 nm was obtained.

Thereafter, a photomask (UV mask) on which a 1 cm×1 cm square opening is formed was prepared and the photomask was disposed on the wettability-variable layer. Next, by use of a mercury lamp as a light source, the wettability-variable layer was exposed under the conditions of an irradiation intensity of 70 mW/cm² and an irradiation period of 50 seconds. By the exposure, an exposed predetermined area of a top surface of the wettability-variable layer was rendered hydrophilic, and thereby a wettability-varying pattern was obtained. Water was dropped on an area that was rendered hydrophilic by the selective exposure, and a contact angle thereof was measured with a contact angle meter (trade name: CA-Z, manufactured by Kyowa Interface Science Co., Ltd.) and found to be 8°. On the other hand, a contact angle of water of a non-exposed portion in the wettability-variable layer was 142° and therefrom it was confirmed that an exposed area was rendered hydrophilic.

An intermediate layer-forming coating material was prepared as follows. That is, an acrylic resin (trade name: BR87, manufactured by Mitsubishi Rayon Co., Ltd., molecular weight: 25000 and glass transition temperature: 105° C.) mainly made of polymethyl methacrylate was dissolved in methyl ethyl ketone and toluene, followed by dispersing TiO₂ fine particles having a primary particle diameter of 20 nm (trade name: P25, manufactured by NIPPON AEROSIL CO., LTD.) therein by use of a homogenizer so that the TiO₂ fine particles and the acrylic resin, may be 1 mass percent and 10 mass percents respectively, and thereby an intermediate layer-forming coating material was prepared. The coating material was coated by use of a wire bar on the wettability-variable layer. The coated film was formed substantially only on a hydrophilic area, that is, an exposed portion of 1 cm×1 cm, of a top surface of a photocatalyst layer-forming layer. The shape retention capability of the coated film was high, and a film was not formed in a portion that was not rendered hydrophilic. Thereafter, over an entire area of the wettability-variable layer and the intermediate layer-forming pattern, by use of a mercury lamp as a light source, the exposure was applied under the conditions of the irradiation intensity of 70 mW/cm² and an irradiation period of 50 seconds. By the exposure, an area other than an area where the intermediate pattern was formed was rendered hydrophilic. The contact angles before and after the hydrophilicization, were 143° and 8° respectively.

Thereafter, similarly as mentioned in example 1, a dye-sensitized solar cell was prepared.

Of the prepared dye-sensitized solar cell, the current-voltage characteristics were measured by a method described below.

Furthermore, similar to example 1, the performance evaluation was carried out. As a result, as the battery characteristics of a single cell, the short-circuit current, the open voltage and the conversion efficiency, were found to be 13.8 mA/cm², 680 mV and 5.9% respectively.

(Method of Evaluation)

a. Evaluation of Stability with Time

Dye-sensitized solar cells prepared in example 1, example 2 and comparative example 2 were measured of the current-voltage characteristics again at one-month time after the preparation. The retention rates of the conversion efficiencies of examples 1 and 2 were 95% and 96% respectively, and that of comparative example 2 was 82%. The deterioration of the performance was remarkable in the comparative example 2. The dye-sensitized solar cell that was prepared in comparative example 2 and where the performance deterioration was observed was visually observed and found that the peeling was caused between the PET base material and the first electrode layer.

b. Method of Evaluating Current-Voltage Characteristics

A prepared element was evaluated in such a manner that with a pseudo-sunlight (AM: 1.5 and incident light intensity: 100 mW/cm²) as a light source, light, was irradiated from a side of a base material that has a dye-absorbed porous layer, and a voltage was applied by use of a source measure unit (trade name: Keithley 2400) to measure.

What is claimed is:

1. An oxide semiconductor electrode comprising: a base material; a bonding layer formed on the base material and made of a thermoplastic resin; a first electrode layer formed on the bonding layer and made of a metal oxide; and a porous layer formed on the first electrode layer and containing a fine particle of a metal oxide semiconductor,
wherein the thermoplastic resin includes a silane-modified resin.

2. An oxide semiconductor electrode comprising: a base material; a bonding layer formed on the base material and made of a thermoplastic resin; a first electrode layer formed on the bonding layer and made of a metal oxide; and a porous layer formed on the first electrode layer and containing a fine particle of a metal oxide semiconductor,
wherein the porous layer is constituted of an oxide semiconductor layer in contact with the first electrode layer and an intermediate layer formed on the oxide semiconductor layer with a higher porosity than that of the oxide semiconductor layer.

3. The oxide semiconductor electrode according to claim 2, wherein the thermoplastic resin contains an adhesive resin.

4. The oxide semiconductor electrode according to claim 1, wherein the base material is a resinous film base material.

5. The oxide semiconductor electrode according to claim 2, wherein the base material is a resinous film base material.

6. The oxide semiconductor electrode according to claim 1, wherein the porous layer contains a metal element same as the metal element which the metal oxide constituting the first electrode layer has.

7. The oxide semiconductor electrode according to claim 2, wherein the porous layer contains a metal element same as the metal element which the metal oxide constituting the first electrode layer has.

8. The oxide semiconductor electrode according to claim 1, wherein the porous layer is patterned.

9. The oxide semiconductor electrode according to claim 2, wherein the porous layer is patterned.

10. The oxide semiconductor electrode according to claim 1, wherein a dye sensitizer is absorbed on a surface of the fine particle of a metal oxide semiconductor contained in the porous layer.

11. The oxide semiconductor electrode according to claim 2, wherein a dye sensitizer is absorbed on a surface of the fine particle of a metal oxide semiconductor contained in the porous layer.

12. An oxide semiconductor electrode with a heat-resistant substrate, comprising a heat-resistant substrate on the porous layer which the oxide semiconductor electrode according to claim 1 has.

13. An oxide semiconductor electrode with a heat-resistant substrate, comprising a heat-resistant substrate on the porous layer which the oxide semiconductor electrode according to claim 2 has.

14. A dye-sensitized solar cell, wherein the porous layer of the oxide semiconductor electrode according to claim 1 in which a dye sensitizer is absorbed on a surface of the fine particle of a metal oxide semiconductor contained in the porous layer, and a second electrode layer of a counter electrode base material constituted of the second electrode layer and a counter base material, are disposed to face each other through an electrolyte layer containing a redox couple.

15. A dye-sensitized solar cell, wherein the porous layer of the oxide semiconductor electrode according to claim 2 in which a dye sensitizer is absorbed on a surface of the fine particle of a metal oxide semiconductor contained in the porous layer, and a second electrode layer of a counter electrode base material constituted of the second electrode layer and a counter base material, are disposed to face each other through an electrolyte layer containing a redox couple.

16. A method of producing a laminated body for an oxide semiconductor electrode, comprising processes of: a process of forming an intermediate layer-forming pattern, wherein an intermediate layer-forming coating material containing an organic material and a fine particle of a metal oxide semiconductor is applied to a heat-resistant substrate in a pattern and set to form an intermediate layer-forming pattern; a process of forming an oxide semiconductor layer-forming layer, wherein an oxide semiconductor layer-forming coating material, a solid of which has a higher concentration of the fine particle of a metal oxide semiconductor than that of a fine particle of a metal oxide semiconductor in a solid of the intermediate layer-forming coating material, is applied to the heat-resistant substrate and the intermediate layer-forming pattern and set to form an oxide semiconductor layer-forming layer; a sintering process, wherein the intermediate layer-forming pattern and the oxide semiconductor layer-forming layer are sintered to be a porous body respectively to form a porous intermediate layer and a porous oxide semiconductor layer; and a process of forming a first electrode layer, wherein a first electrode layer is formed on the oxide semiconductor layer.

17. The method of producing a laminated body for an oxide semiconductor electrode according to claim 16, wherein the heat-resistant substrate has, on a surface thereof, a wettability-variable layer of which a wettability is varied under an action of a photocatalyst accompanied by an energy irradiation, and an energy is irradiated on the wettability-variable layer, before the process of forming an intermediate layer-forming pattern is carried out, to form a wettability-varying pattern.

18. A method of producing an oxide semiconductor electrode with a heat-resistant substrate, comprising a process of forming a base material, wherein a base material is disposed on the first electrode layer of the laminated body for an oxide semiconductor electrode obtained by the method of producing a laminated body for an oxide semiconductor electrode according to claim 16.

19. A method of producing an oxide semiconductor electrode with a heat-resistant substrate, comprising processes of: a process of forming an intermediate layer-forming pattern, wherein an intermediate layer-forming coating material containing an organic material and a fine particle of a metal oxide semiconductor is applied to a heat-resistant substrate in a pattern and set to form an intermediate layer-forming pattern; a process of forming an oxide semiconductor layer-forming layer, wherein an oxide semiconductor layer-forming coating material, a solid of which has a higher concentration of a fine particle of a metal oxide semiconductor than that of a fine particle of a metal oxide semiconductor in a solid of the intermediate layer-forming coating material, is applied to the heat-resistant substrate and the intermediate layer-forming pattern, and set to form an oxide semiconductor layer-forming layer; a sintering process, wherein the intermediate layer-forming pattern and the oxide semiconductor layer-forming layer are sintered to be a porous body respectively to form a porous intermediate layer and a porous oxide semiconductor layer,
wherein the processes are carried out to form an oxide semiconductor substrate, and to superpose the oxide semiconductor layer and the first electrode layer by using the oxide semiconductor substrate and an electrode base material provided with a base material and a first electrode layer.

20. A method of producing an oxide semiconductor electrode, comprising a peeling process of peeling the heat-resistant substrate off from an oxide semiconductor electrode with a heat-resistant substrate obtained by the method of producing an oxide semiconductor electrode with a heat-resistant substrate according to claim 18.

21. A method of producing an oxide semiconductor electrode, comprising a peeling process of peeling the heat-resistant substrate off from an oxide semiconductor electrode with a heat-resistant substrate obtained by the method of producing an oxide semiconductor electrode with a heat-resistant substrate according to claim 19.

22. A method of producing a dye-sensitized solar cell, comprising a process of forming a counter electrode base material by facing, with an oxide semiconductor electrode obtained by the method of producing an oxide semiconductor electrode according to claim 20 and a counter electrode base material provided with a second electrode pattern and a counter base material, the intermediate layer and the second electrode pattern to form a base material pair for a dye-sensitized solar cell, wherein a filling process, in which a process of supporting a dye sensitizer on a pore surface of the intermediate layer and the oxide semiconductor layer, and a process of forming an electrolyte layer between the second electrode pattern and the intermediate layer and inside of a pore of the porous body of the oxide semiconductor layer and the intermediate layer after the process of supporting a dye sensitizer are carried out to the laminated body for an oxide semiconductor electrode, the oxide semiconductor electrode with a heat-resistant substrate, the oxide semiconductor electrode or the base material pair of a dye-sensitized solar cell.

23. A method of producing a dye-sensitized solar cell, comprising a process of forming a counter electrode base material by facing, with an oxide semiconductor electrode obtained by the method of producing an oxide semiconductor electrode according to claim 21 and a counter electrode base material provided with a second electrode pattern and a counter base material, the intermediate layer and the second electrode pattern to form a base material pair for a dye-sensitized solar cell,
wherein a filling process, in which a process of supporting a dye sensitizer on a pore surface of the intermediate layer and the oxide semiconductor layer, and a process of forming an electrolyte layer between the second electrode pattern and the intermediate layer and inside of a pore of the porous body of the oxide semiconductor layer and the intermediate layer after the supporting a dye sensitizer are carried out to the laminated body for an oxide semiconductor electrode, the oxide semiconductor electrode with a heat-resistant substrate, the oxide semiconductor electrode or the base material pair of a dye-sensitized solar cell.

24. The method of producing a dye-sensitized solar cell according to claim 22, comprising a process of forming a first electrode pattern, wherein the first electrode layer is formed in a pattern to form a first electrode pattern is applied to the Laminated body for an oxide semiconductor electrode or the oxide semiconductor electrode.

25. The method of producing a dye-sensitized solar cell according to claim 23, comprising a process of forming a first electrode pattern, wherein the first electrode layer is formed in a pattern to form a first electrode pattern is applied to the laminated body for an oxide semiconductor electrode or the oxide semiconductor electrode.
